(19) United States
(12) Patent Application Publication
(10) Pub. No.: US 2024/0379636 A1
(43) Pub. Date: Nov. 14, 2024

(54) SEMICONDUCTOR DEVICE PACKAGE AND METHOD OF MANUFACTURING THE SAME

(71) Applicants: ND-HI TECHNOLOGIES LAB, INC., TAIPEI CITY (TW); ETRON TECHNOLOGY, INC., HSINCHU (TW)

(72) Inventors: HO-MING TONG, TAIPEI CITY (TW); CHAO-CHUN LU, HSINCHU (TW); CHUN SHIAH, HSINCHU (TW)

(21) Appl. No.: 18/634,481

(22) Filed: Apr. 12, 2024

Related U.S. Application Data
(60) Provisional application No. 63/458,969, filed on Apr. 13, 2023.
(60) Provisional application No. 63/465,911, filed on May 12, 2023.
(60) Provisional application No. 63/603,650, filed on Nov. 29, 2023.

(51) Int. Cl. H01L 25/10; H01L 21/66; H01L 23/00; H01L 23/28; H01L 23/538

(52) U.S. Cl. CPC H01L 25/105; H01L 22/10; H01L 23/28; H01L 23/538; H01L 24/16; H01L 24/32; H01L 24/73; H01L 2224/16145; H01L 2224/16225; H01L 2224/32145; H01L 2224/73204

(57) ABSTRACT

A semiconductor device package is provided. The semiconductor device package comprises a first electronic component, a second electronic component above the first electronic component and an interconnection structure disposed external to both the first electronic component and the second electronic component and configured to electrically connect the first electronic component to the second electronic component, a package material configured to hold the first electronic component and the second electronic component together and an external connector configured to electrically connect the first and second electronic components to an external device. The first electronic component has a portion free from being covered by the second electronic component. The external connector is positioned directly above the portion of the first electronic component.

### PRIORITY CLAIM AND CROSS-REFERENCE

This application claims the benefit of prior-filed U.S. provisional application No. 63/458,969, filed on Apr. 13, 2023, U.S. provisional application No. 63/465,911, filed on May 12, 2023, U.S. provisional application No. 63/603,650, filed on Nov. 29, 2023, and incorporates by reference herein in its entirety.

### FIELD

The present disclosure relates to, amongst other things, a semiconductor device package.

### BACKGROUND

In modern electronic systems, data typically moves back and forth between the processor and DRAM which is the main memory for most chips. At times, this exchange runs into the memory wall issue resulting from (a) an outdating computing architecture (which has been dominating the semiconductor industry for decades since its inception) with a physical separation between computer processors and memory; and (b) the fact that a processor can run much faster than the speed at which memory chips can provide data. The performance gap created by the memory wall leads to a situation where processors such as CPUs and GPUs spend a significant amount of time waiting and idling for data to be delivered from the memory, thereby significantly impacting system performance, especially for tasks that require large amounts of data to be processed quickly and simultaneously, such as running complex AI algorithms. In fact, the memory wall is quickly becoming a large issue for AI applications since AI accelerators such as today's state-of-the-art Nvidia GPUs (e.g., H100) are specially designed for efficient, high-speed parallel processing of massive amounts of data.

The memory wall issue involves the limited memory capacity and clock speed, and the interconnect bandwidth or bus width of memory transfer. Lack of bandwidth has become a growing limitation for the efficiency and scalability of AI technologies even as DRAM technologies continue to advance towards higher capacities and higher clock speeds. In fact, for AI applications, bandwidth is quickly becoming a limiting factors not only for memory but also at many levels covering the compute level, the network level, and the socket level.

For high-end applications such as high-performance computing (HPC), data centers and artificial intelligence (AI), the industry's solution to address the aforementioned challenges is (a) the expensive high-bandwidth-memory DRAM stack (HBM) which allows for a much higher bandwidth and better efficiency compared to traditional DRAM designs by providing a wider interface at a higher clock speed in combination with (b) 2.5D IC packaging of HBMs and the processor (e.g., the GPU) on a silicon interposer. HBM is more expensive compared to traditional DRAM due to the need for 3D stacking (in the vertical or package thickness direction) that involves a multiplicity of fast DRAM dies (and oftentimes also a control IC), expensive through silicon vias (TSVs) and the fact that HBM contains a multiplicity of dies (DRAM dies and control IC) with a die size that is roughly twice as large as that of traditional DDR5 DRAM. 2.5D IC packaging is also expensive as it involves creating a large number of TSVs in the typically large silicon interposer that accommodates both the processor and the HBMs. In a 2.5D IC package, the HBMs are placed within a few millimeters of the processor to reduce the distances of data transfer and speed up the data transfer process. All the above combined helps alleviate the memory wall issue.

It is the focus of the present invention to disclose alternative, low-cost 3D IC packaging solutions involving stacking dies in the vertical (i.e., package thickness) direction and interconnecting the dies without evoking the expensive TSVs and silicon interposers for more cost—sensitive applications such as edge AI in comparison with the aforementioned high-end applications. As in the case of HBM, stacking memory dies in the vertical direction increases memory capacity using 3D IC packaging. It greatly shortens the distances of and speeds up data transfer between the processor and the memory, and significantly reduces energy consumption. 3D packaging also enables a far higher bus width and interconnect bandwidth due to a far higher number of data paths that can be created between the processor and the memory which is mounted in the vertical direction with the processor (one on top of the other), compared to its 2D or 2.5D counterparts. It is also an intention of the present invention to integrate in lower-cost 3D IC packaging not only the memory dies (and the control IC) but also the processor in close proximity to the memory dies to speed up data transfer between the processor and the memory and to minimize the accompanying energy consumption. When needed, other types of active and passive devices such as interconnect bridges, voltage regulators, inductors and capacitors can also be co-packaged in the disclosed 3D packages. Previous studies have shown that every time data is transferred back and forth across the memory bus, accessing DRAM requires approximately 60 pico-joules for each byte, which is a thousand-fold more energy than processing the data that requires 50-60 femto-joules per computational operation. 3D IC stacking helps speed up data transfer and minimize the required energy consumption due to the short distances data has to travel. It is also worth noting that HBM can provide better pico-joule per bit compared to 2D memory package options for AI accelerators. The 3D IC packages disclosed herein can also be designed (e.g., through IC design and IC package co-design) to maximize this benefit. Even though DRAM is cited herein for demonstration, other types of memory, combinations thereof or other die combinations can also be applied to the structures, processes and methodologies disclosed herein. Moreover, because the 3D IC packages disclosed herein do not require creating TSVs in active dies (which often takes a long time to qualify from IC design), they can be more readily implemented with existing dies in a mix and match fashion for fast time-to-market.

### SUMMARY

According to one example embodiment of the present disclosure, a semiconductor device package comprises a first electronic component, a second electronic component above the first electronic component and an interconnection structure disposed external to both the first electronic component and the second electronic component and configured to electrically connect the first electronic component to the second electronic component, a package material configured to hold the first electronic component and the second electronic component together and an external connector configured to electrically connect the first and second electronic components to an external device. The first electronic component has a portion free from being covered by the second electronic component. The external connector is positioned directly above the portion of the first electronic component.

According to one example embodiment of the present disclosure, a semiconductor device package comprises a first electronic component, a second electronic component disposed above the first electronic component, an interconnection structure configured to electrically connect the first electronic component to the second electronic component and a package material configured to encapsulate the first electronic component, the second electronic component and the interconnection structure. The interconnection structure is arranged outside the first electronic component and the second electronic component and surrounded by the package material.

According to another example embodiment of the present disclosure, a method of manufacturing a semiconductor device package comprises: providing a first redistribution layer on a first carrier, wherein the first redistribution layer can be tested; providing an interconnection on the first redistribution layer; providing a first electronic component on the first redistribution layer, wherein the first electronic component can be tested; providing a first package material to encapsulate the first redistribution layer, the interconnection and the first electronic component so as to form a sub-assembly; providing a second redistribution layer on the sub-assembly, wherein the second redistribution layer can be tested; providing a second electronic component on the second redistribution layer, wherein the second electronic component comprises a portion overlapping the interconnection in a vertical direction; providing a second package material to encapsulate the second redistribution layer and the second electronic component; and removing the first carrier from the first redistribution layer.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 is a cross-sectional view of a semiconductor device package in accordance with an embodiment of the instant disclosure.

FIG. 2 is a cross-sectional view of a semiconductor device package in accordance with an embodiment of the instant disclosure.

FIG. 3 is a cross-sectional view of a semiconductor device package in accordance with an embodiment of the instant disclosure.

FIG. 4 is a cross-sectional view of a semiconductor device package in accordance with an embodiment of the instant disclosure.

FIG. 5 is a cross-sectional view of a semiconductor device package in accordance with an embodiment of the instant disclosure.

FIG. 6 is a cross-sectional view of a semiconductor device package in accordance with an embodiment of the instant disclosure.

FIG. 7A, FIG. 7B, FIG. 7C, FIG. 7D, FIG. 7E and FIG. 7F illustrate one or more stages of an example of a method for manufacturing a semiconductor device package in accordance with some embodiments of the present disclosure.

FIG. 8 is a cross-sectional view of a semiconductor device package in accordance with an embodiment of the present disclosure.

FIG. 9 is a cross-sectional view of a semiconductor device package in accordance with an embodiment of the present disclosure.

FIG. 10 is a cross-sectional view of a semiconductor device package in accordance with an embodiment of the present disclosure.

FIG. 11 is a cross-sectional view of a semiconductor device package in accordance with an embodiment of the present disclosure.

FIG. 12A is a cross-sectional view of a semiconductor device package in accordance with an embodiment of the present disclosure.

FIG. 12B is an enlarged top view of portion “A” in FIG. 12A.

FIG. 12C is another enlarged top view of portion “A” in FIG. 12A.

FIG. 13 is a cross-sectional view of a semiconductor device package in accordance with an embodiment of the present disclosure.

FIG. 14A is a cross-sectional view of a conductive spacer in accordance with an embodiment of the present disclosure.

FIG. 14B is a cross-sectional view of a conductive spacer in accordance with an embodiment of the present disclosure.

FIG. 14C is a cross-sectional view of a conductive spacer in accordance with an embodiment of the present disclosure.

FIG. 15A is a top view of a conductive spacer in accordance with an embodiment of the present disclosure.

FIG. 15B is a cross-sectional view of a conductive spacer in accordance with an embodiment of the present disclosure.

FIG. 16A, FIG. 16B, FIG. 16C, FIG. 16D, FIG. 16E, FIG. 16F, FIG. 16G and FIG. 16H illustrate one or more stages of an example of a method for manufacturing a conductive spacer in accordance with some embodiments of the present disclosure.

FIG. 17 is a cross-sectional view of a semiconductor device package in accordance with an embodiment of the present disclosure.

FIG. 18A, FIG. 18B, FIG. 18C, FIG. 18D, FIG. 18E, FIG. 18F, FIG. 18G, FIG. 18H and FIG. 18I illustrate one or more stages of an example of a method for manufacturing a semiconductor device package in accordance with some embodiments of the present disclosure.

FIG. 19A is a cross-sectional view along line A′-A′ of FIG. 18I.

FIG. 19B is a cross-sectional view along line A′-A′ of FIG. 18I.

FIG. 19C is a cross-sectional view along line A′-A′ of FIG. 18I.

FIG. 19D is a cross-sectional view along line A′-A′ of FIG. 18I.

FIG. 19E is a cross-sectional view along line A′-A′ of FIG. 18I.

FIG. 19F is a cross-sectional view along line A′-A′ of FIG. 18I.

FIG. 20 is a cross-sectional view of a semiconductor device package in accordance with an embodiment of the instant disclosure.

FIG. 21 is a cross-sectional view of a semiconductor device package in accordance with an embodiment of the present disclosure.

FIG. 22 is a cross-sectional view of a semiconductor device package in accordance with an embodiment of the present disclosure.

FIG. 23A, FIG. 23B, FIG. 23C, FIG. 23D, FIG. 23E, FIG. 23F, FIG. 23G, FIG. 23H. FIG. 23I and FIG. 23J illustrate one or more stages of an example of a method for manufacturing a semiconductor device package in accordance with some embodiments of the present disclosure.

FIG. 24 is a cross-sectional view of a semiconductor device package in accordance with an embodiment of the present disclosure.

FIG. 25 is a cross-sectional view of a semiconductor device package in accordance with an embodiment of the present disclosure.

FIG. 26 is a cross-sectional view of a semiconductor device package in accordance with an embodiment of the present disclosure.

FIG. 27 is a cross-sectional view of a semiconductor device package in accordance with an embodiment of the present disclosure.

FIG. 28 is a cross-sectional view of a semiconductor device package in accordance with an embodiment of the present disclosure.

FIG. 29 is a cross-sectional view of a semiconductor device package structure in accordance with an embodiment of the present disclosure.

FIG. 30 is a cross-sectional view of a semiconductor device package structure in accordance with an embodiment of the present disclosure.

FIG. 31 is a cross-sectional view of a semiconductor device package structure in accordance with an embodiment of the present disclosure.

FIG. 32 is a cross-sectional view of a semiconductor device package in accordance with an embodiment of the present disclosure.

FIG. 33 is a cross-sectional view of a semiconductor device package in accordance with an embodiment of the present disclosure.

FIG. 34 is a cross-sectional view of a semiconductor device package structure in accordance with an embodiment of the instant disclosure.

FIG. 35 is a cross-sectional view of a semiconductor device package structure in accordance with an embodiment of the present disclosure.

FIG. 36 is a cross-sectional view of a semiconductor device package structure in accordance with an embodiment of the present disclosure.

FIG. 37A is a cross-sectional view of a semiconductor device package in accordance with an embodiment of the present disclosure.

FIG. 37B is a top view of the conductive spacer in accordance with an embodiment of the present disclosure.

FIG. 38 is a cross-sectional view of a semiconductor device package in accordance with an embodiment of the present disclosure.

FIG. 39 is a cross-sectional view of a semiconductor device package in accordance with an embodiment of the present disclosure.

FIG. 40 is a cross-sectional view of a semiconductor device package in accordance with an embodiment of the present disclosure.

FIG. 41A, FIG. 41B, FIG. 41C, FIG. 41D, FIG. 41E, illustrate one or more stages of an example of a method for manufacturing a semiconductor device package in accordance with some embodiments of the present disclosure.

FIG. 42A, FIG. 42B, FIG. 42C, FIG. 42D, FIG. 42E, illustrate one or more stages of an example of a method for manufacturing a semiconductor device package in accordance with some embodiments of the present disclosure.

FIG. 43A, FIG. 43B, FIG. 43C, FIG. 43D, FIG. 43E, illustrate one or more stages of an example of a method for manufacturing a semiconductor device package in accordance with some embodiments of the present disclosure.

FIG. 44A, FIG. 44B, FIG. 44C illustrate one or more stages of an example of a method for manufacturing a semiconductor device package in accordance with some embodiments of the present disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

This present disclosure was undertaken to enable package-level extensions of known-good-die (KGD) and two-die stack (“doubler”) technologies, while paying attention to devise approaches to expand the doubler technology to covering multiple-die-in-1 DRAM KGDs and multiple-die-in-1 DRAM/processor (logic) combos.

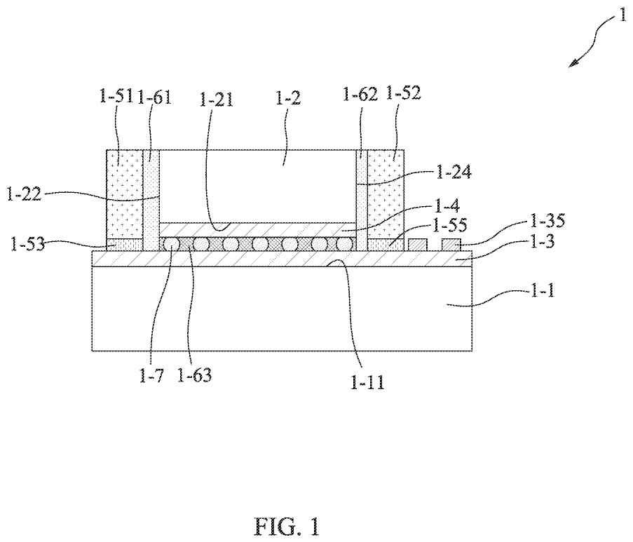

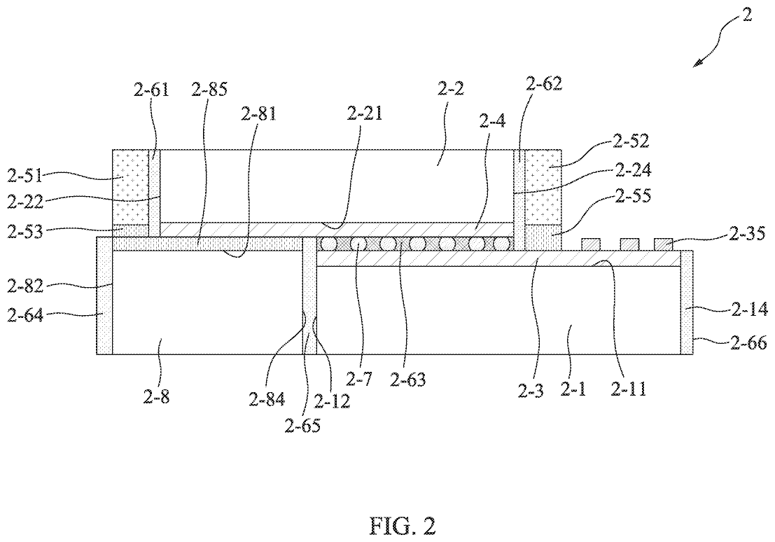

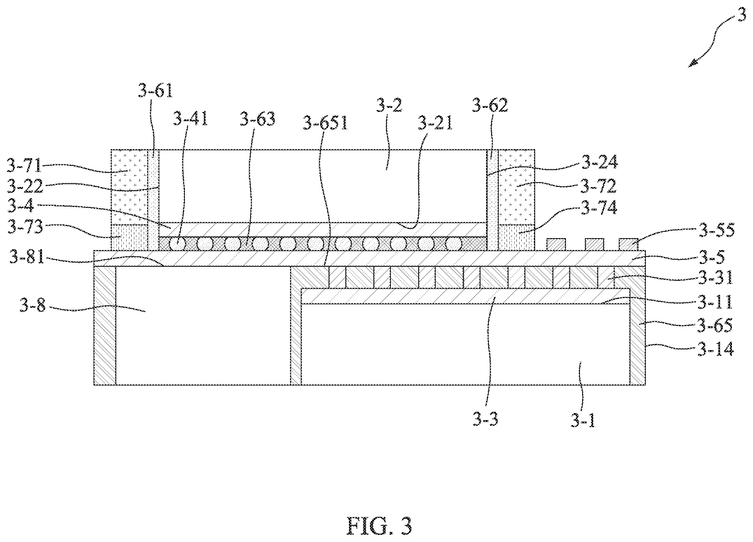

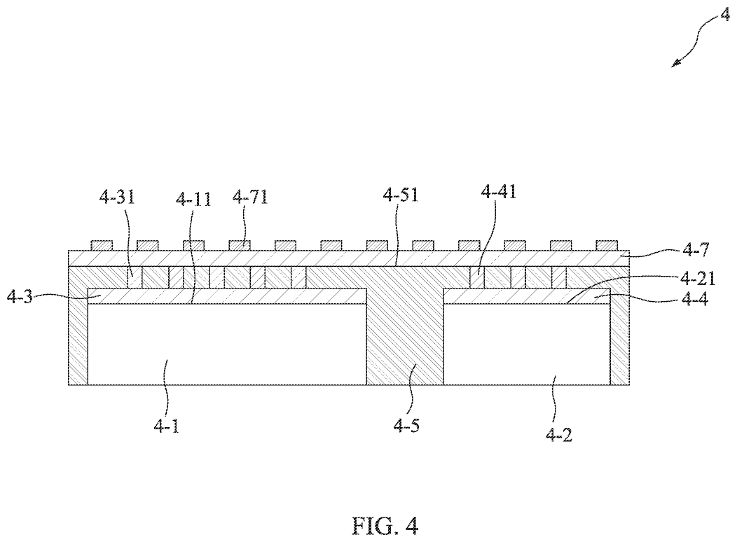

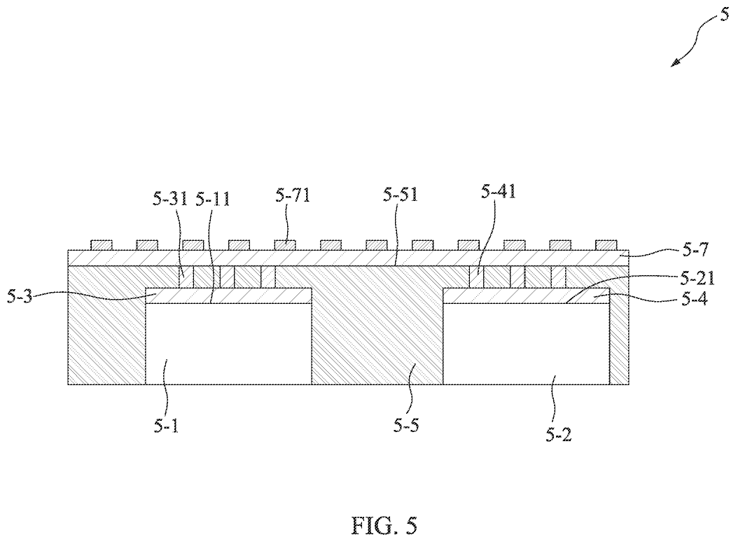

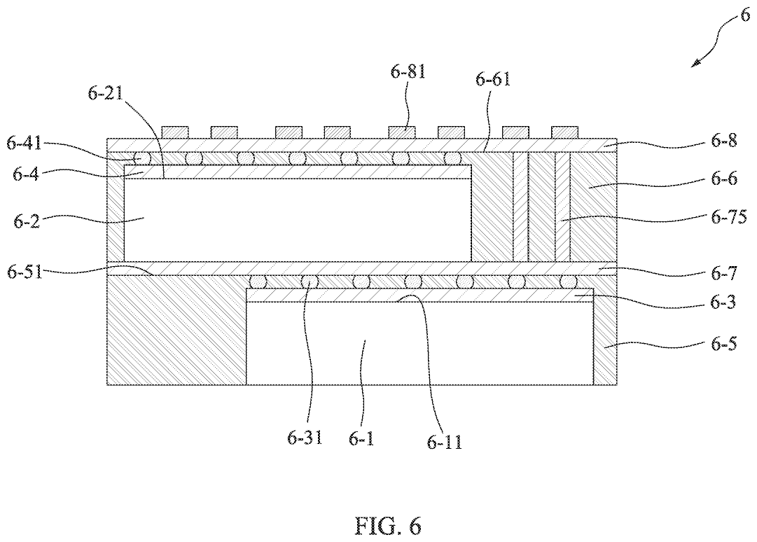

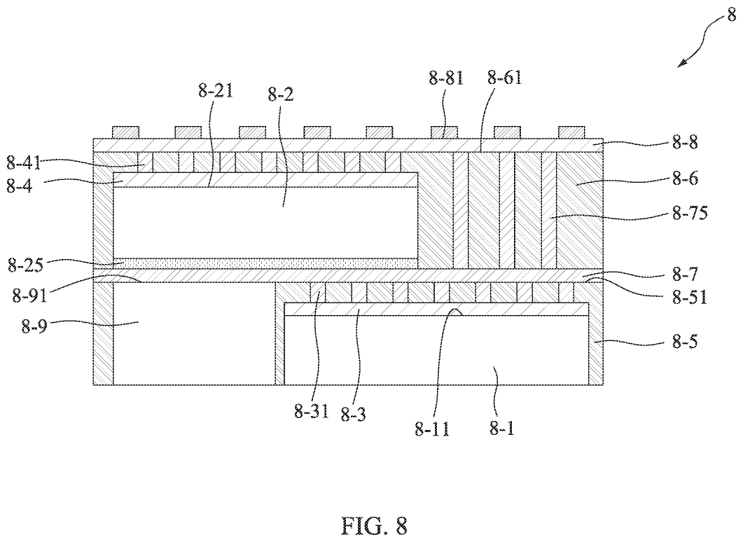

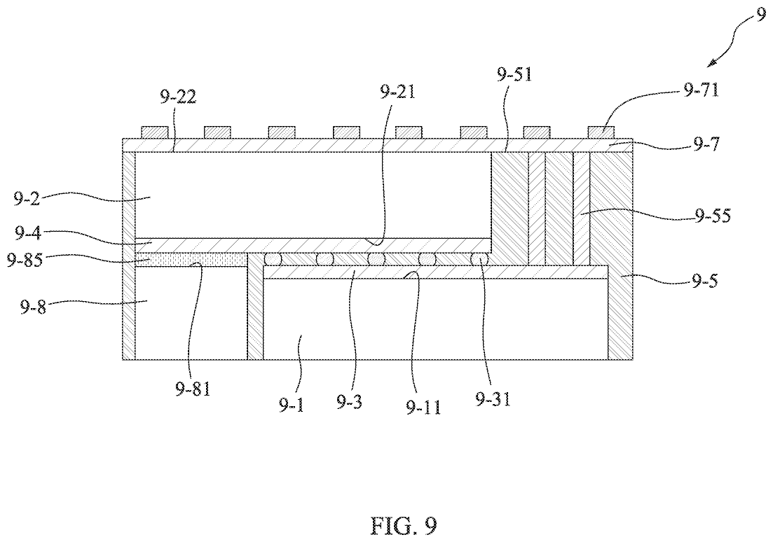

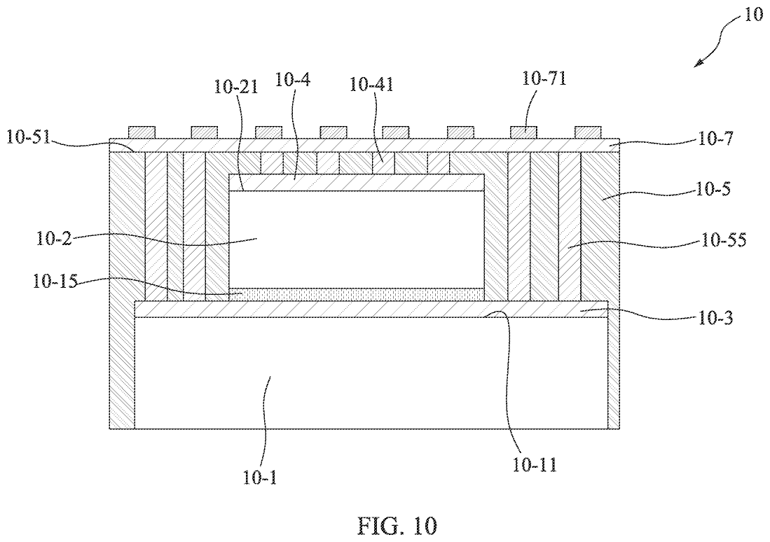

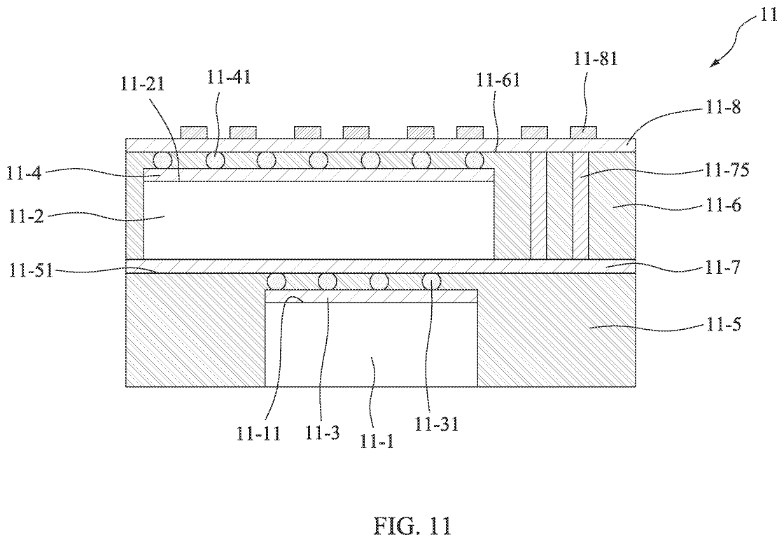

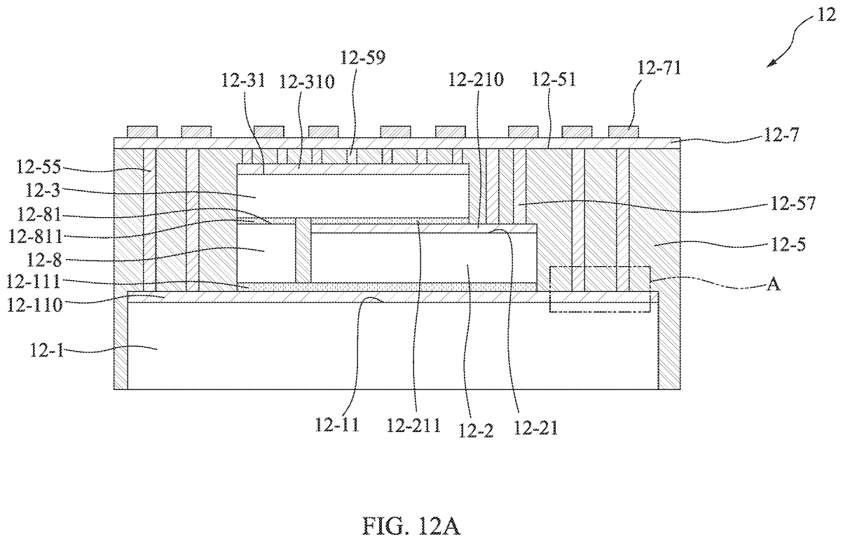

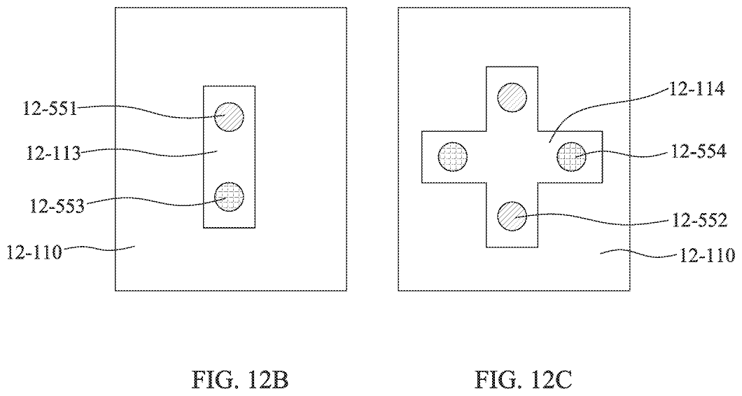

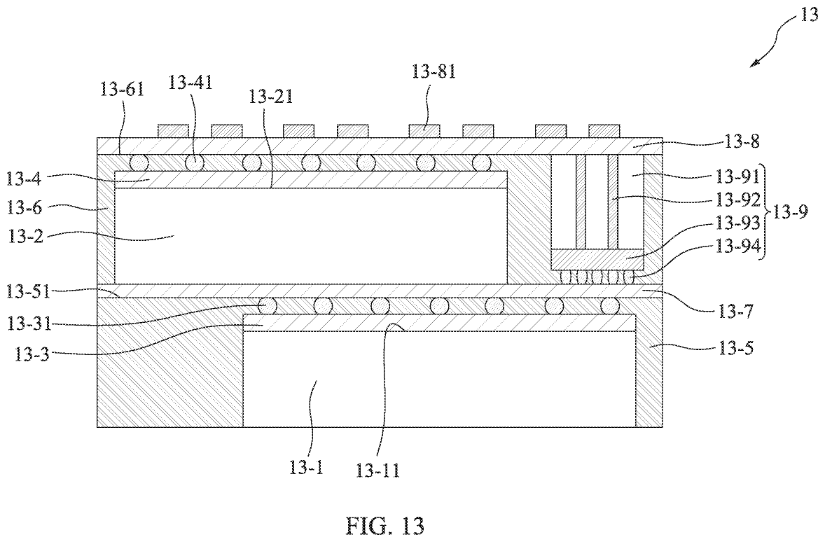

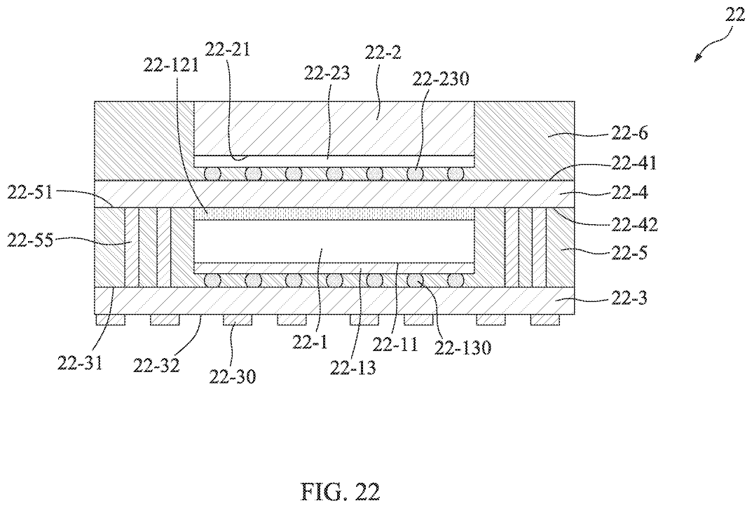

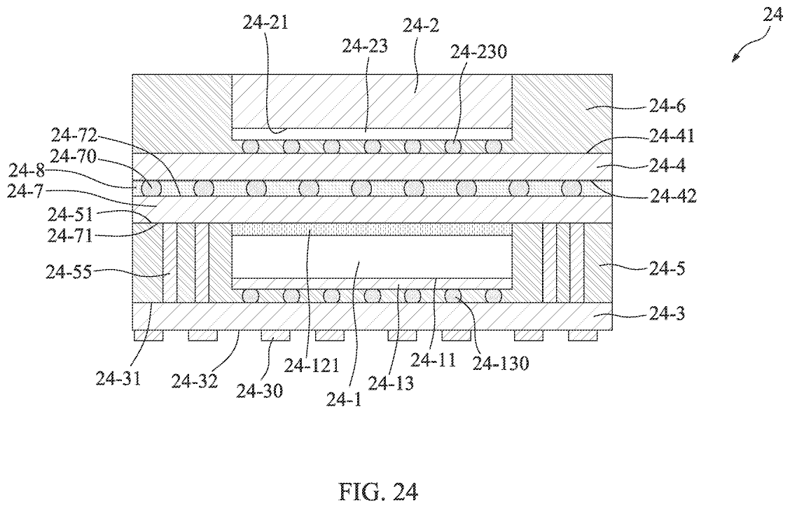

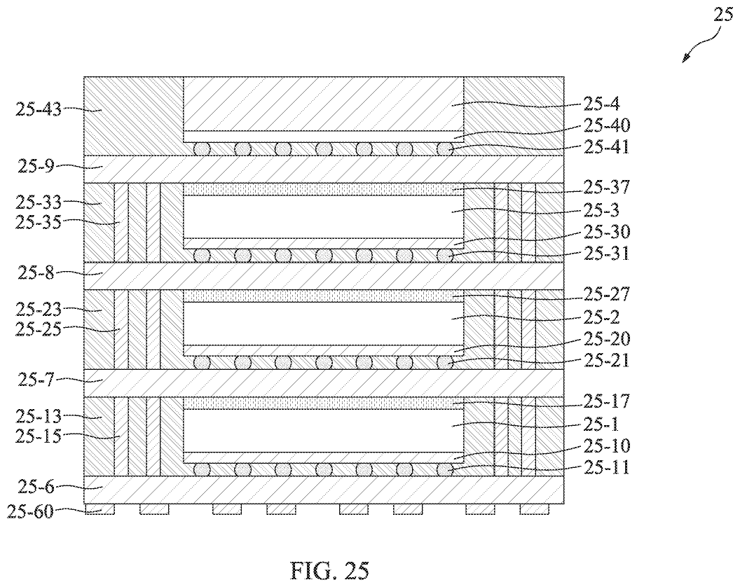

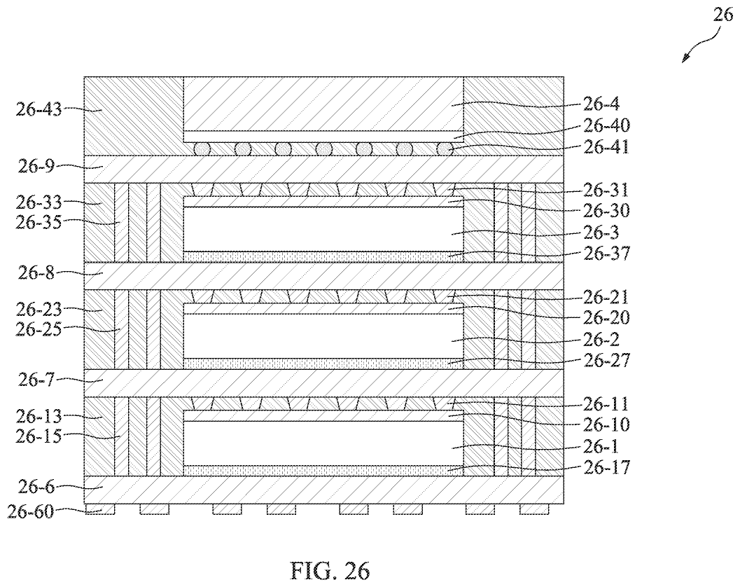

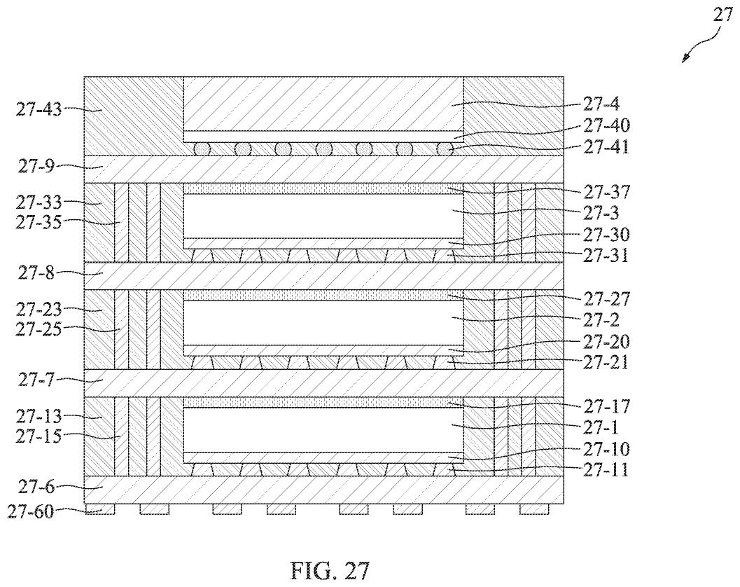

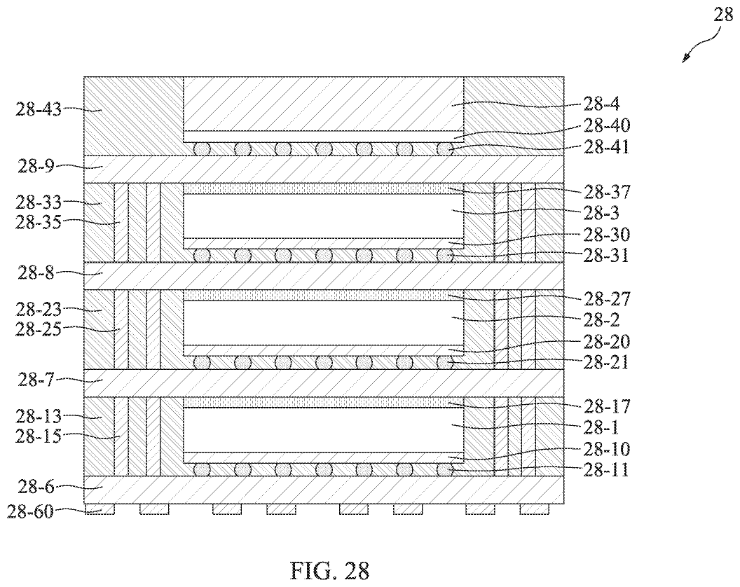

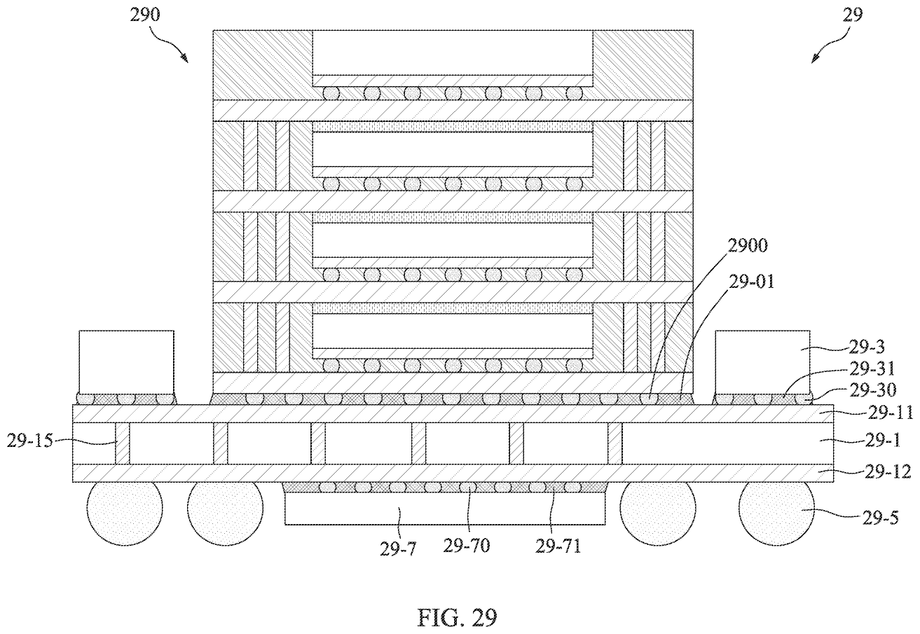

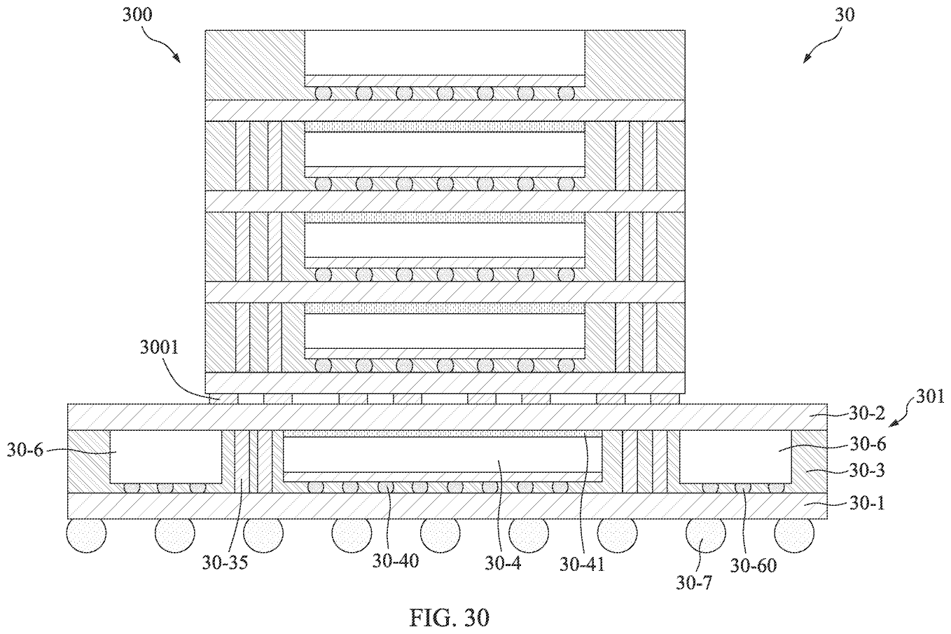

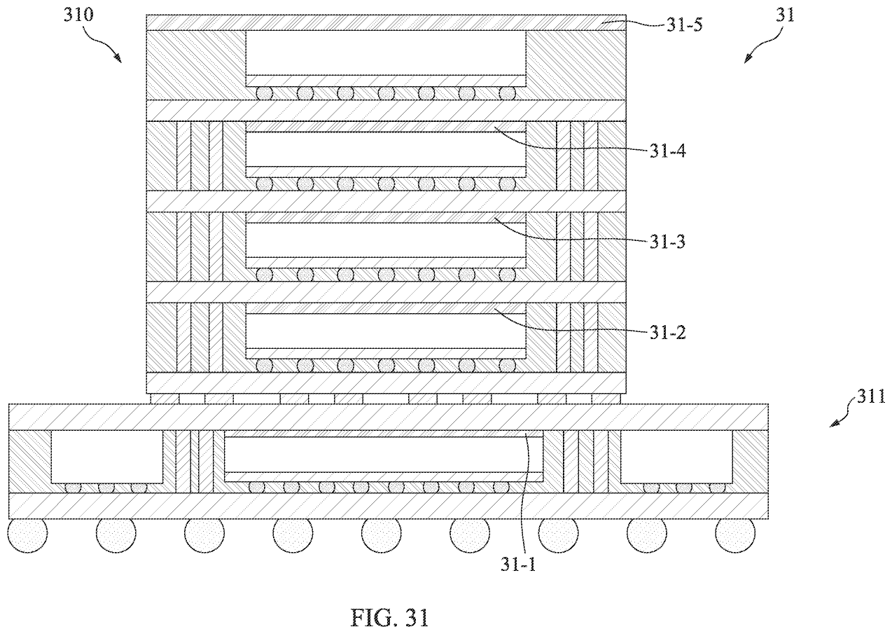

The present disclosure includes the following sections: fast implementation based on flip chip (see FIG. 1, FIG. 2, FIG. 3, FIG. 4 and FIG. 5), doubler extensions (see FIG. 6, FIG. 8, FIG. 9, FIG. 10, FIG. 11, FIG. 12A, FIG. 13) and scalable multiple-die-in-1 DRAM KGDs (see FIG. 22, FIG. 24, FIG. 25, FIG. 26, FIG. 27, FIG. 28, FIG. 29, FIG. 30 and FIG. 31). Note that although redistribution layers (RDL) on the DRAM die is optional, it is shown in practically all drawings (and can be omitted as needed to reduce cost) and also that an underfill (or a non-conductive paste or film, NCP) needs to be applied following flip chip bonding though not shown.

Possible structures (and related processes) to implement doublers can be seen in fast implementation (FIG. 6, FIG. 8, FIG. 9, FIG. 10, FIG. 11, FIG. 12A, FIG. 13), in doubler extensions involving shifted DRAM dies (when viewed from top in the x-y plane) and in scalable multiple-die-in-1 DRAM KGDs involving aligned DRAM dies (when viewed from top in the x-y plane).

With a few exceptions (e.g., flip chip), wafer-level (/panel-level) fan-out processes are used in creating the structures shown in this disclosure. There exist three primary types of fan-out processes: chip-last/(die) face-down, chip-first/(die) face-up and chip-first/(die) face-down, each of which comes with its pros and cons in route-ability, cost, yield, testability, reliability and time-to-market (that are highly dependent upon application requirements, package design/architecture and OSATs process readiness or capabilities). Fan-out processes create structures with die(s) embedded in a molding compound in a way somewhat similar to the processes to embed die(s) in a laminate substrate, both can come with RDL on one side (top or bottom) or both sides (top and bottom). For complex structures involving more than one RDL for die-to-die interconnection (e.g., doubler structures), chip-last/face-down is favored over the other two types of structures as the former allows for easier decoupling of RDL and assembled chip yields and assurance of known-good RDLs prior to chip assembly for high yields. This, however, does not imply chip-first/(die) face-up and chip-first/(die) face-down are out of the question as they may find sweet spots in certain applications.

Under fast implementation, the doubler structures shown in FIGS. 1 to 3 are based primarily on flip chip, all of which incorporate structural silicon pieces to ensure structural integrity during handling and subsequent processing. In these structures, die-to-die interconnection is achieved using a combination of flip chip, redistribution layers (as needed), copper pillar bumping and fan-out processes. The through-mold vias (TMVs) in FIG. 3, for instance, can be formed using a through-mold via process commonly used in fan-out processing or can be pre-formed in the form of metal pillars (e.g., copper pillars) on the chips.

Besides stacking dies in the vertical or package thickness direction, interconnection between two dies can also be achieved laterally when space is not a constraint as shown in FIGS. 4 and 5 wherein die-to-die interconnection is achieved using a fan-out process and the TMVs can be formed using a through-mold via process commonly used in fan-out processing or can be pre-formed in the form of metal pillars on the chips.

To package doublers beyond those shown (FIGS. 1 to 3) in the category of fast implementation, DRAMs of the same design or different designs can be stacked and packaged differently using different fan-out processes as shown in FIG. 6, FIG. 8, FIG. 9, FIG. 10, FIG. 11, FIG. 12A, and FIG. 13 (all of which fall under doubler extensions) where TMVs can be created by forming metal pillar bumps before molding, and/or a hole opening process (e.g., using an UV laser) commonly used in fan-out processing and metal hole filling after molding. In certain applications, thick film photoresists can also be deposited (e.g., laminated on) in place of the molding compound, in which case photolithography can be employed to open the through mold vias.

When needed, the doubler extension structures can be complemented with attachment of a high-thermal-conductivity (High-TC) heat spreader (and spacers as needed) and a High-TC thermal interface material (TIM) on the backside of the exposed die and spacer as applicable, for example, see 9-1 and 9-8 in FIG. 9.

The doubler extension structures (and processes) can be repeated for the stacking of more than two dies in the thickness direction. A case in point is the stacking of two 4 Gb DRAM dies on a 8 Gb DRAM die as shown in FIG. 12A.

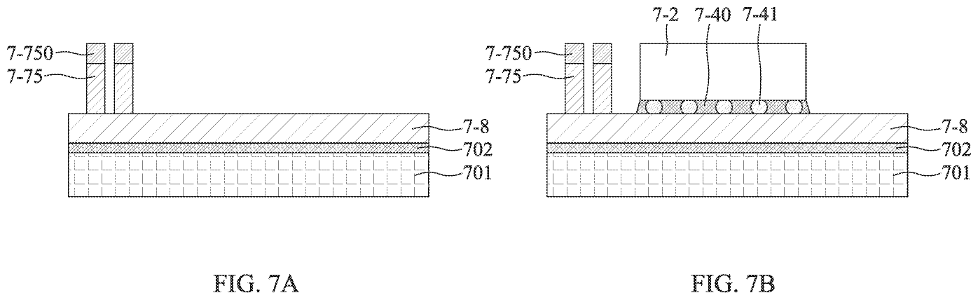

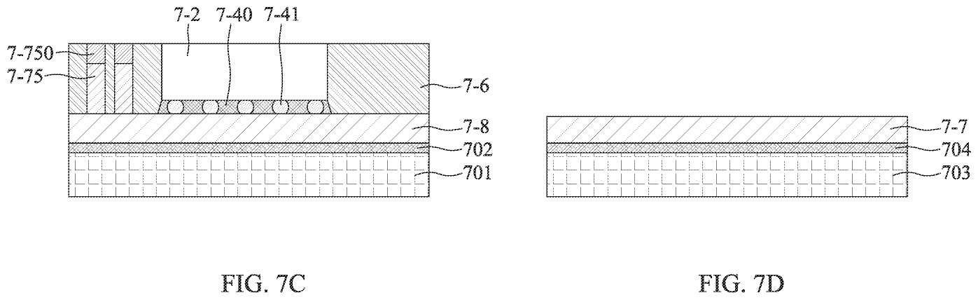

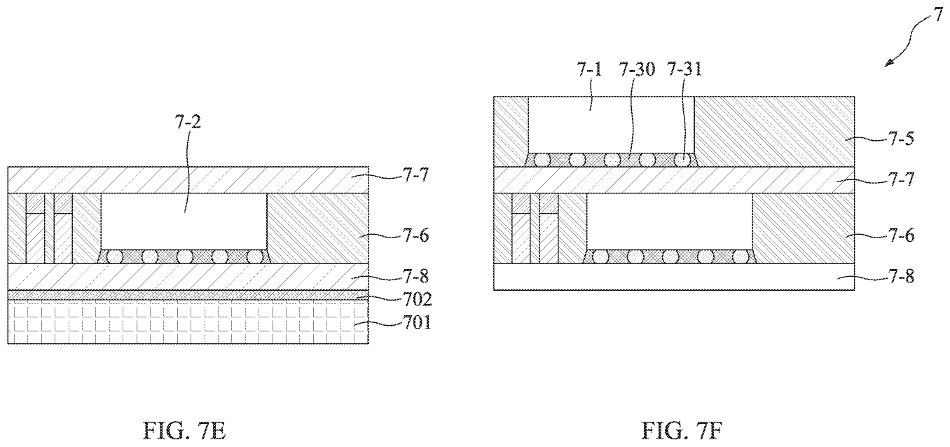

Instead of shifting the position of the top die relative to the bottom die in the lateral direction in forming the shifted 3D stack structure (e.g., see FIG. 6 based on chip-last/face-down under doubler extensions), one can align the two dies laterally in the stack, i.e., the aligned stack structure, as shown in FIG. 22 (under scalable multiple-die-in-1 DRAM KGDs). The latter represents an easier, more scalable structure compared to the shifted 3D structure in terms of achieving stacking dies beyond two dies (see FIG. 25, FIG. 26, FIG. 27, FIG. 28, FIG. 29, FIG. 30 and FIG. 31). To achieve high yields for the structures in FIGS. 6 and 22, the process as shown in FIGS. 7A to 7F can be deployed where the metal pillars can be on known-good redistribution layers 1 (known-good RDL 1 or simply KGR 1) or KGR 2. This process involves building and testing for the two known-good RDLs (KGR 1 and KGR 2 in FIG. 6) separately to ensure only sub-structures involving known-good RDLs are assembled with the two known-good DRAM dies which can come with their own RDLs or without. In forming the 3D structure shown in FIG. 6, a chip-last/face-down fan-out process is assumed. Other types of fan-out processes can also apply here.

The “aligned” structure (and the related processes) in FIG. 22 is scalable with relative ease to stacking of more than two dies as shown in FIG. 25 based on chip-last/face-down), FIG. 26 (based on chip-first/face-up), FIG. 27 (based on chip-first/face-down) and FIG. 28 (based on embedded substrates). For lower-end applications, lower-cost panel-level embedded substrate processes may also be used in place of the wafer-level fan-out processes to achieve die embedding and formation of RDLs.

Following 3D DRAM die stacking, the 3D DRAM stack can be assembled with the processor on the opposite side of the substrates (FIG. 29) or on top of a fan-out embedded processor (or another logic chip such as a controller) as shown in FIG. 30 (without heat spreaders) and in FIG. 31 (with heat spreaders) using the chip-last/face-down multiple-die-in-1 DRAM stack as an example. These package architectures also allow for DRAM dies of different sizes/capacities, other types of dies and active devices, and/or passives (e.g., one capacitor or more and inductors) to be co-packaged in the same fan-out layer of the 3D stack or in the same 3D package.

In summary,
to form 2-in-1 DRAM KGDs (whether they be 8 Gb+8 Gb or 4 Gb+8 Gb), it is recommended that one focuses on the structures (and related processes) shown in FIG. 6 (shifted dies) and FIG. 22 (aligned dies) created using chip-last/face-down fan-out processes,
for 4 Gb+8 Gb and 8 Gb+8 Gb, the structures shown in FIG. 1 and FIG. 2 created using flip chip also merit some attention,
to scale up beyond two dies, it is advisable to use the aligned-die structure as shown in FIGS. 25 to 28.

To create the dual-die structure in FIG. 6, for instance, one can follow the process below:
1. Use a chip-last/face-down fan-out process to create the RDL with copper pillars, 7-75 in FIG. 7A, each of which containing a solder tip, 7-750 to facilitate subsequent joining to KGR 2 on a temporary glass carrier (the first glass carrier), 701, pre-coated with the release (or release/adhesive) layer, 702, followed by using a built-in test circuitry in KGR 1, 7-8, and quality inspection methodologies (e.g., optical inspection) to ensure KGR 1 is known good;
2.
Flip chip bond the first DRAM die on the KGR 1 using solder bumps or copper pillar micro-bumps, 7-41 (see FIG. 7B) and an underfill or a NCP, 7-40, and test using the test circuitry in KGR 1 to ensure the known-good KGR 1+DRAM chip sub-assembly (sub-assembly 1);
3. Overmold sub-assembly 1 (see FIG. 7C);
4. Planarize the mold as shown in FIG. 7C to reveal the TMVs and the chip (or alternatively, the TMVs while leaving a layer of molding compound on the backside of the first DRAM);
5. repeat step 1 to create KGR 2 on a second glass carrier and use the test circuitry in the KGR 2 to ensure KGR 2, 7-7 in FIG. 7D, is known good;
6. bond KGR 2 to KGR 1 in sub-assembly 1 and test the newly formed sub-assembly (sub-assembly 2) using the test circuitry in KGR 2 to ensure sub-assembly 2 is known good (alternatively, steps 5 and 6 can be replaced by forming the RDL 2 directly on the planarized mold embodying sub-assembly 1 at the expense of yield loss);
7. flip chip bond the second DRAM die onto the KGR 2—see FIG. 7F;
8. repeat steps 3 and 4 to reveal the second DRAM die and form sub-assembly 3 as shown in FIG. 7F with sub-assembly 3 still being supported by the first temporary glass carrier;
9. (Optional) attach a High-TC heat spreader using a High-TC thermal interface material, TIM, to the backside of the second DRAM die (note: this heat spreader can also serve as a stiffener for enhanced structural integrity during the subsequent assembly process);
10. attach sub-assembly 3 embodying the two dies to a third glass carrier with a release/adhesive layer;
11. release sub-assembly 3 from the first glass carrier and the release/adhesive layer;
12. create appropriate surface finishes (e.g., Ni/Au or Ni/Pd/Au) and bonding pads (and test pads as needed) for subsequent bonding;
13. test through the KGR 1 for known-good final assembly and release it from the third glass carrier;
14. Singulate the final assembly

FIG. 6 shows a 3D shifted-die stack that can be formed using a chip-last/face-down fan-out process as illustrated in FIG. 7A-7F.

A similar structure as shown in FIG. 8 can be created using a chip-first/face-up fan-out process involving the optional use of a spacer (e.g., a silicon spacer), 8-9.

The process to create the dual-die structure in FIG. 22 is similar to that FIGS. 7A to 7F to form the structure in FIG. 6.

Similar methodologies and processes can also be applied to create structures using the chip-first/face-down and chip-first/face-up approaches.

The processes described above can be repeated to create multiple-die-in-1 DRAM KGDs shown in FIG. 12A, FIG. 25, FIG. 26, FIG. 27 and FIG. 28.

Following KGD assembly, the 2-in-1 DRAM KGDs or the multiple-die-in-1 DRAM KGDs can then be interconnected to processors through wire bonding and/or flip chip through the use of a substrate such as a laminate substrate as shown in FIG. 29, FIG. 30 and FIG. 31, wherein the processor can be mounted on the opposite side of the laminate or fan-out substrate to the KGDs, or embedded in the substrate underneath the KGDs (with or without heat spreaders) along with companion active dies (e.g., voltage regulators) and/or passives such as decaps and inductors for power integrity.

The passives (e.g., capacitors and/or inductors) can be embedded in the fan-out layers containing the active dies (e.g., DRAM or other types of active dies), mounted on the substrate and/or embedded in the substrate (see FIG. 29 to FIG. 31).

The laminate substrates can be fine-line/space (L/S) (e.g., 6 μm/8 μm or finer) substrates built using a low-curing-temperature, fine-L/S dielectric such as a polyimide, ABF build-up layers and a BT core and a panel-level laminate substrate process. In contrast, the RDL created by wafer-level fan-out processing can achieve a finer L/S of 2 μm/2 μm and below compared to panel-level substrate processes.

For certain cost sensitive applications, the KGRs can be formed by coreless laminate substrate processes.

The structure shown in FIG. 2 can be created by the following process:
1. Use a chip-first/face-up fan-out process to reconstitute a 12″ glass carrier (pre-coated with a release/adhesive layer) with the first DRAM die, 2-1, and the spacer, 2-8;
2. Apply an encapsulant (e.g., epoxy based filler), 2-65, to fill the spaces between spacers and dies;
3. Flip chip bond the second die, 2-2, to the first die, 2-1;
4. Attach structural silicon pieces, 2-51 and 2-52, which can assume the same or different dimensions with a die attachment material, 2-53 and 2-55;
5. Apply an encapsulant, 2-61, to fill the intervals between structural silicon pieces and the second dies, 2-2;
6. Test to ensure known-good doubler or dual-die assembly; and
7. Release the final assembly from the glass carrier and singulate it.

Interim and final testing can be perform to ensure known-good sub-assemblies and final assembly, respectively.

An alternative to the structure shown in FIG. 2 is depicted in FIG. 3 which uses a chip-first/face-up fan-out process to create the die 1 and spacer combo sub-assembly with the die 1 RDL, 3-5, and micro-TMVs which interconnect the die 1 pads and the die 1 RDL, followed by steps 3 to 5 of the process above to form the structure in FIG. 2. Alternatively, the TMVs in FIG. 3 can be pre-formed on the first die, 3-1, prior to fan-out processing.

In contrast, the 3D stack structure shown in FIG. 1 can be more readily done compared to the structures in FIG. 2 and FIG. 3. The process consists of using the first die in full-wafer form as the substrate for flip chip bonding of the second die to the first die which is larger than the second die in the sense that the periphery of the first die can totally encompass the periphery of the second die, followed by attachment of structural silicon pieces, encapsulation, test and singulation. In the event the die 1 wafer is thin, the wafer can be pre-bonded to a glass carrier with a release/adhesive layer prior to bonding of the second die for structural integrity during subsequent assembly.

FIG. 1 is a cross-sectional view of a semiconductor device package 1 in accordance with an embodiment of the instant disclosure. As shown in FIG. 1, the semiconductor device package 1 may include an electronic component 1-1 and an electronic component 1-2 disposed above the electronic component 1-1. In some embodiments of the present disclosure, the electronic component 1-1 includes a known-good die (KGD) and, the electronic component 1-2 includes a known-good die (KGD). In some embodiments of the present disclosure, the electronic component 1-1 includes a memory die, and the electronic component 1-2 includes a memory die. In some embodiments of the present disclosure, the electronic component 1-1 includes an 8 GB memory die, and the electronic component 1-2 includes a 4 GB memory die. That is, a size of the electronic component 1-1 may be greater than a size of the electronic component 1-2. Referring to FIG. 1, a cross-sectional width of the electronic component 1-1 may be greater than a cross-sectional width of the electronic component 1-2, and thus the electronic component 1-1 has at least one portion that is not vertically covered by the electronic component 1-2 when the electronic component 1-2 is stacked on the electronic component 1-1.

As shown in FIG. 1, the electronic component 1-1 has a surface 1-11 (e.g., an upper surface) facing the electronic component 1-2. The surface 1-11 may include an active surface of the electronic component 1-1. Further, a redistribution layers (RDL) 1-3 may be disposed on the surface 1-11 of the electronic component 1-1. RDL 1-3 may be electrically connected to the active surface of the electronic component 1-1. Moreover, the electronic component 1-2 has a surface 1-21 (e.g., a lower surface) facing the electronic component 1-1. The surface 1-21 may include an active surface of the electronic component 1-2. Further, a RDL 1-4 may be disposed on the surface 1-21 of the electronic component 1-2. RDL 1-4 may be electrically connected to the active surface of the electronic component 1-2. The semiconductor device package 1 may include a plurality of electrical connections 1-7 disposed between RDL 1-3 and RDL 1-4. In some embodiments of the present disclosure, the electrical connection 1-7 includes a solder bump or a copper pillar micro-bump. The electrical connections 1-7 may serve to establish electrical connectivity between the redistribution layer 1-3 and RDL 1-4. That is, the electronic component 1-1 and the electronic components 1-2 may be electrically connected to each other by RDL 1-3, RDL 1-4 and the electrical connections 1-7. Moreover, RDL 1-3 may include a plurality of external electrical connections 1-35 configured to electrically connect to an external device. The external electrical connections 1-35 may be disposed on an upper surface of RDL 1-3. In some embodiments of the present disclosure, the external electrical connection 1-35 includes a bonding pad and/or a test pad. The external electrical connections 1-35 may be disposed directly above the portion of the electronic component 1-1 that is they are not vertically covered by the electronic component 1-2. The external electrical connections 1-35 may be electrically connected to RDL 1-3. That is, the external electrical connections 1-35 may be configured to transmit the signal from the electronic components 1-1 and/or 1-2 to the external device to which the external electrical connections 1-35 are connected aside from serving the purpose of power delivery

In addition, a package material 1-63 may be filled between the electronic component 1-1 and the electronic component 1-2. The package material 1-63 is configured to encapsulate part of RDL 1-3, part of RDL 1-4 and the electrical connections 1-7. That is, the electronic component 1-1 and the electronic components 1-2 may be held together by the package material 1-63 and the electrical connections 1-7. In some embodiments of the present disclosure, the package material 1-63 includes an underfill or a NCP.

Further, the semiconductor device package may include mechanical supports 1-51 and 1-52 disposed above the electronic component 1-1 and adjacent to the electronic component 1-2. In some embodiments of the present disclosure, the supports, 1-51 and 1-52, includes those made using silicon, or a low-coefficient-of-thermal expansion (LCTE) materials. Referring to FIG. 1, the support 1-51 may be disposed on RDL 1-3 and adjacent to a side 1-22 (e.g., a left side) of the electronic component 1-2. An adhesive 1-53 may be disposed between the support 1-51 and RDL 1-3, and a package material 1-61 disposed between the support 1-51 and the side 1-22 of the electronic component 1-2, and on top of RDL 1-3. That is, the support 1-51 may be fixed on RDL 1-3 through the adhesive 1-53 and be attached to the side 1-22 of the electronic component 1-2 and RDL 1-3 through the encapsulant 1-61. In some embodiments of the present disclosure, the package material 1-61 includes an encapsulant. In some embodiments of the present disclosure, the adhesive 1-53 includes a die attachment film. Moreover, the support 1-52 may be disposed on RDL 1-3 and adjacent to a side 1-24 (e.g., a right side) of the electronic component 1-2. An adhesive 1-55 may be disposed between the support 1-52 and RDL 1-3, and a package material 1-62 is disposed between the support 1-52 and the side 1-24 of the electronic component 1-2. That is, the support 1-52 may be fixed on RDL 1-3 through the adhesive 1-55 and be attached to the side 1-24 of the electronic component 1-2 and RDL 1-3 through the package material 1-62. In some embodiments of the present disclosure, the package material 1-62 includes an encapsulant. In some embodiments of the present disclosure, the adhesive 1-55 includes a die attachment film. The supports, 1-51 and 1-52, are used to protect the electronic component 1-2 during subsequent processing and operation. During the pick-and-place operation, for instance, a pick-and-place equipment may pick up the semiconductor device package 1 with the supports, 1-51 and 1-52, protecting the electronic components 1-1 and 1-2, thereby avoiding direct contact with and potential damage to these electronic components.

FIG. 2 is a cross-sectional view of a semiconductor device package 2 in accordance with an embodiment of the present disclosure. As shown in FIG. 2, the semiconductor device package 2 may include an electronic component 2-1 and an electronic component 2-2 disposed above the electronic component 2-1. In some embodiments of the present disclosure, the electronic component 2-1 includes a known-good die (KGD) and, the electronic component 2-2 includes a known-good die (KGD). In some embodiments of the present disclosure, the electronic component 2-1 includes a memory die, and the electronic component 2-2 includes a memory die. In some embodiments of the present disclosure, the electronic component 2-1 includes an 8 Gb memory die, and the electronic component 2-2 includes a 8 Gb memory die. That is, a size of the electronic component 2-1 may be substantially identical to a size of the electronic component 2-2. Referring to FIG. 2, a cross-sectional width of the electronic component 2-1 is substantially identical to a cross-sectional width of the electronic component 2-2, and the electronic components 2-1 and 2-2 are stacked vertically but are not aligned directly one above the other; instead, there is a lateral offset. The electronic component 2-2 is positioned slightly to the left relative to the electronic component 2-1. Thus, the electronic component 2-1 has at least one portion that is it is not vertically covered by the electronic component 2-2.

As shown in FIG. 2, the electronic component 2-1 has a surface 2-11 (e.g., an upper surface) facing the electronic component 2-2. The surface 2-11 may include an active surface of the electronic component 2-1. Further, a redistribution layers (RDL), RDL 2-3, may be disposed on the surface 2-11 of the electronic component 2-1. RDL 2-3 may be electrically connected to the active surface of the electronic component 2-1. Moreover, the electronic component 2-2 has a surface 2-21 (e.g., a lower surface) facing the electronic component 2-1. The surface 2-21 may include an active surface of the electronic component 2-2. Further, a redistribution layers 2-4 (RDL 2-4) may be disposed on the surface 2-21 of the electronic component 2-2. RDL 2-4 may be electrically connected to the active surface of the electronic component 2-2. The semiconductor device package 2 may include a plurality of electrical connections 2-7 disposed between RDL 2-3 and RDL 2-4. In some embodiments of the present disclosure, the electrical connection 2-7 includes a solder bump or a copper pillar micro-bump. The electrical connections 2-7 may serve to establish electrical connectivity between RDL 2-3 and RDL 2-4. That is, the electronic component 2-1 and the electronic components 2-2 may be electrically connected to each other by RDL 2-3, RDL 2-4 and the electrical connections 2-7. Moreover, RDL 2-3 may include a plurality of external electrical connections 2-35 configured to electrically connect to an external device. The external electrical connections 2-35 may be disposed on an upper surface of RDL 2-3. In some embodiments of the present disclosure, the external electrical connection 2-35 includes a bonding pad and/or a test pad. The external electrical connections 2-35 may be disposed directly above the portion of the electronic component 2-1 that is they are not vertically covered by the electronic component 2-2. The external electrical connections 2-35 may be electrically connected to RDL 2-3. That is, the external electrical connections 2-35 may be configured to transmit the signal from the electronic components 2-1 and/or 2-2 to the external device to which the external electrical connections 2-35 are connected aside from serving the purpose of power delivery.

In addition, a package material 2-63 may be filled between the electronic component 2-1 and the electronic component 2-2. The package material 2-63 is configured to encapsulate RDL 2-3, RDL 2-4 and the electrical connections 2-7. That is, the electronic component 2-1 and the electronic components 2-2 may be held together by the package material 2-63 and the electrical connections 2-7. In some embodiments of the present disclosure, the package material 2-63 includes an underfill or a NCP.

Referring to FIG. 2, the semiconductor device package 2 may further include a spacer 2-8. The spacer 2-8 may be disposed under the electronic component 2-2 and adjacent to the electronic component 2-1. Since the electronic components 2-1 and 2-2 are stacked vertically but are not aligned directly one above the other, the spacer 2-8 is configured to support the electronic component 2-2 which is disposed above the electronic component 2-1. An adhesive 2-85 may optionally be disposed between a surface 2-81 (e.g., an upper surface) of the spacer 2-8 and RDL 2-4. That is, the spacer 2-8 may be attached to the electronic component 2-2 through the adhesive 2-85. Furthermore, there is a package material 2-65 filling the spaces between the spacer 2-8 and the electronic component 2-1. The package material 2-65 may cover a surface 2-84 (e.g., a right surface) of the spacer 2-8 and a surface 2-12 (e.g., a left surface) of the electronic component 2-1. In some embodiments of the present disclosure, a package material 2-64 is disposed on and covers a surface 2-82 (e.g., a left surface) of the spacer 2-8, and a package material 2-66 is disposed on and covers a surface 2-14 (e.g., a right surface) of the electronic component 2-1. In some embodiments of the present disclosure, the adhesive 2-85 includes a die attachment film. In some embodiments of the present disclosure, the package materials, 2-64, 2-65 and 2-66, include an encapsulant.

Further, the semiconductor device package may include supports 2-51 and 2-52 disposed above the electronic component 2-1 and the spacer 2-8 and adjacent to the electronic component 2-2. In some embodiments of the present disclosure, the supports 2-51 and 2-52 includes silicon material or a LCTE material. Referring to FIG. 2, the support 2-51 may be disposed on the die attach film 2-85 and the spacer 2-8 and adjacent to a side 2-22 (e.g., a left side) of the electronic component 2-2. An adhesive 2-53 may be disposed between the support 2-51 and the die attach film 2-85, and a package material 2-61 is disposed between the support 2-51 and the side 2-22 of the electronic component 2-2. That is, the support 2-51 may be fixed on the spacer 2-8 through the adhesive 2-53 and be attached to the side 2-22 of the electronic component 2-2 through the package material 2-61. In some embodiments of the present disclosure, the package material 2-61 includes an encapsulant. In some embodiments of the present disclosure, the adhesive 2-53 includes a die attachment film. Moreover, the support 2-52 may be disposed on RDL 2-3 and adjacent to a side 2-24 (e.g., a right side) of the electronic component 2-2. An adhesive 2-55 may be disposed between the support 2-52 and RDL 2-3, and a package material 2-62 is disposed between the support 2-52 and the side 2-24 of the electronic component 2-2. That is, the support 2-52 may be fixed on RDL 2-3 through the adhesive 2-55 and be attached to the side 2-24 of the electronic component 2-2 through the package material 2-62. In some embodiments of the present disclosure, the package material 2-62 includes an encapsulant. In some embodiments of the present disclosure, the adhesive 2-55 includes a die attachment film. The supports 2-51 and 2-52 are used to protect the electronic component 2-2.

FIG. 3 is a cross-sectional view of a semiconductor device package 3 in accordance with an embodiment of the present disclosure. As shown in FIG. 3, the semiconductor device package 3 may include an electronic component 3-1 and an electronic component 3-2 disposed above the electronic component 3-1. In some embodiments of the present disclosure, the electronic component 3-1 includes a known-good die (KGD) and, the electronic component 3-2 includes a known-good die (KGD). In some embodiments of the present disclosure, the electronic component 3-1 includes a memory die, and the electronic component 3-2 includes a memory die. In some embodiments of the present disclosure, the electronic component 3-1 includes an 8 Gb memory die, and the electronic component 3-2 includes a 8 Gb memory die. That is, a size of the electronic component 3-1 may be substantially identical to a size of the electronic component 3-2. Referring to FIG. 3, a cross-sectional width of the electronic component 3-1 is substantially identical to a cross-sectional width of the electronic component 3-2, and the electronic components 3-1 and 3-2 are stacked vertically but are not aligned directly one above the other; instead, there is a lateral offset. The electronic component 3-2 is positioned slightly to the left relative to the electronic component 3-1. Thus, the electronic component 3-1 has at least one portion that is it is not vertically covered by the electronic component 3-2.

As shown in FIG. 3, the electronic component 3-1 has a surface 3-11 (e.g., an upper surface) facing the electronic component 3-2. The surface 3-11 may include an active surface of the electronic component 3-1. Further, a redistribution layers 3-3 (RDL 3-3) may be disposed on the surface 3-11 of the electronic component 3-1. RDL 3-3 may be electrically connected to the active surface of the electronic component 3-1. A spacer 3-8 may be positioned to be adjacent to the electronic component 3-1. Since the electronic components 3-1 and 3-2 are stacked vertically but are not aligned directly one above the other, the spacer 3-8 is configured to support the electronic component 3-2 disposed above the electronic component 3-1. Further, the semiconductor device package 3 may include a package material 3-65 encapsulating the spacer 3-8 and the electronic component 3-1. In some embodiments of the present disclosure, the package material 3-65 includes a molding compound. The package material 3-65 may cover RDL 3-3 as well. Moreover, a redistribution layers 3-5 (RDL 3-5) may be disposed on a surface 3-651 (e.g., an upper surface) of the package material 3-65. RDL 3-5 may be disposed on a surface 3-81 (e.g., an upper surface) of the spacer 3-8 as well. A plurality of conductive vias 3-31 may pass through the package material 3-65 and be connected to the redistribution layers 3-3 and 3-5. The conductive vias 3-31 may electrically connect RDL 3-3 and RDL 3-5. That is, the electronic component 3-1 may be electrically connected to RDL 3-5 through RDL 3-3 and the conductive vias 3-31. In some embodiments of the present disclosure, the conductive via 3-31 includes a micro-TMV created as a part of the fan-out process or a copper pillar created on the electronic component 3-1 prior to fan-out processing.

Moreover, the electronic component 3-2 has a surface 3-21 (e.g., a lower surface as shown in FIG. 3 facing the electronic component 3-1). The surface 3-21 may include an active surface of the electronic component 3-2. Further, a redistribution layers 3-4 (RDL 3-4) may be disposed on the surface 3-21 of the electronic component 3-2. RDL 3-4 may be electrically connected to the active surface of the electronic component 3-2. The semiconductor device package 3 may include a plurality of electrical connections 3-41 disposed between RDL 3-4 and RDL 3-5. In some embodiments of the present disclosure, the electrical connection 3-41 includes a solder bump or a copper pillar micro-bump. The electrical connections 3-41 may electrically connect RDL 3-4 and RDL 3-5. That is, the electronic component 3-1 and the electronic components 3-2 may be electrically connected to each other by the redistribution layers, 3-3, 3-4 and 3-5, the conductive vias 3-31 and the electrical connections 3-41. Moreover, RDL 3-5 may include a plurality of external electrical connections 3-55 configured to electrically connect to an external device. The external electrical connections 3-55 may be disposed on an upper surface of RDL 3-5. In some embodiments of the present disclosure, the external electrical connections 3-55 include a bonding pad and/or a test pad. The external electrical connections 3-55 may be disposed directly above the portion of the electronic component 3-1 that is they are not vertically covered by the electronic component 3-2. The external electrical connections 3-55 may be electrically connected to RDL 3-5. That is, the external electrical connections 3-55 may be configured to transmit the signal from the electronic components 3-1 and/or 3-2 to the external device to which the external electrical connections 3-55 are connected aside from serving the purpose of power delivery.

In addition, an underfill (or a NCP) 3-63 may be filled between the electronic component 3-2 and the package material 3-65. The underfill 3-63 is configured to encapsulate RDL 3-4, part of RDL 3-5 and the electrical connections 3-41. That is, the electronic component 3-1 and the electronic components 3-2 may be held together by the underfill 3-63, the package material 3-65, the RDLs, the micro-TMVs and the electrical connections 3-41. In some embodiments of the present disclosure, the underfill 3-63 includes a molded underfill (MUF) or a capillary underfill (CUF).

Further, the semiconductor device package 3 may include supports 3-71 and 3-72 disposed above the electronic component 3-1 and adjacent to the electronic component 3-2. In some embodiments of the present disclosure, the supports 3-71 and 3-72 include silicon or a LCTE material. Referring to FIG. 3, the support 3-71 may be disposed on RDL 3-5 and adjacent to a side 3-22 (e.g., a left side) of the electronic component 3-2. An adhesive 3-73 may be disposed between the support 3-71 and RDL 3-5, and a package material 3-61 is disposed between the support 3-71 and the side 3-22 of the electronic component 3-2. That is, the support 3-71 may be fixed on RDL 3-5 through the adhesive 3-73 and be attached to the side 3-22 of the electronic component 3-2 through the package material 3-61. In some embodiments of the present disclosure, the package material 3-61 includes an encapsulant. In some embodiments of the present disclosure, the adhesive 3-73 includes a die attachment film. Moreover, the support 3-72 may be disposed on RDL 3-5 and adjacent to a side 3-24 (e.g., a right side) of the electronic component 3-2. An adhesive 3-74 may be disposed between the support 3-72 and RDL 3-5, and an package material 3-62 is disposed between the support 3-72 and the side 3-24 of the electronic component 3-2. That is, the support 3-72 may be fixed on RDL 3-5 through the adhesive 3-74 and be attached to the side 3-24 of the electronic component 3-2 through the package material 3-62. In some embodiments of the present disclosure, the package material 3-62 includes an encapsulant. In some embodiments of the present disclosure, the adhesive 3-74 includes a die attachment film. The supports 3-71 and 3-72 are used to protect the electronic component 3-2.

Under fast implementation, the structures shown in FIGS. 1 to 3 based primarily on flip chip incorporate structural silicon pieces. The stacking and bonding can be done with the assistance of fan-out processes.

Besides stacking dies in the thickness direction, interconnection between two dies can also be achieved laterally (when space is not a constraint) as shown in FIG. 4 and FIG. 5 using fan-out processes.

FIG. 4 is a cross-sectional view of a semiconductor device package 4 in accordance with an embodiment of the present disclosure. As shown in FIG. 4, the semiconductor device package 4 may include an electronic component 4-1 and an electronic component 4-2, with both electronic components 4-1 and 4-2 arranged adjacently in a side-by-side configuration. In some embodiments of the present disclosure, the electronic component 4-1 includes a known-good die (KGD) and, the electronic component 4-2 includes a known-good die (KGD). In some embodiments of the present disclosure, the electronic component 4-1 includes a memory die, and the electronic component 4-2 includes a memory die. In some embodiments of the present disclosure, the electronic component 4-1 includes an 8 Gb memory die, and the electronic component 4-2 includes a 4 Gb memory die. That is, a size of the electronic component 4-1 may be greater than a size of the electronic component 4-2. Referring to FIG. 4, a cross-sectional width of the electronic component 4-1 may be greater than a cross-sectional width of the electronic component 4-2.

As shown in FIG. 4, the electronic component 4-1 has a surface 4-11 (e.g., an upper surface). The surface 4-11 may include an active surface of the electronic component 4-1. Further, a redistribution layers 4-3 (RDL 4-3) may be disposed on the surface 4-11 of the electronic component 4-1. RDL 4-3 may be electrically connected to the active surface of the electronic component 4-1. Moreover, the electronic component 4-2 has a surface 4-21 (e.g., an upper surface). The surface 4-21 may include an active surface of the electronic component 4-2. Further, a redistribution layers 4-4 (RDL 4-4) may be disposed on the surface 4-21 of the electronic component 4-2. RDL 4-4 may be electrically connected to the active surface of the electronic component 4-2.

The semiconductor device package 4 includes a package material 4-5 encapsulating the electronic components 4-1 and 4-2. That is, the electronic components 4-1 and 4-2 may be held together by the package material 4-5. Furthermore, the package material 4-5 also covers the two RDLs, 4-3 and 4-4. In some embodiments of the present disclosure, the package material 4-5 includes a molding compound. In some embodiments of the present disclosure, the package material 4-5 includes a photosensitive thick film.

Referring to FIG. 4, redistribution layers 4-7 (RDL 4-7) may be disposed on a surface 4-51 (e.g., an upper surface) of the package material 4-5. A plurality of conductive vias 4-31 may pass through the package material 4-5 and be connected to the two RDLs, 4-3 and 4-7. The conductive vias 4-31 may be electrically connected to RDL 4-3 and RDL 4-7. That is, the electronic component 4-1 may be electrically connected to RDL 4-7 through RDL 4-3 and the conductive vias 4-31. In some embodiments of the present disclosure, the conductive via 4-31 includes a TMV (Through Mold Via) or a copper pillar. Moreover, a plurality of conductive vias 4-41 may pass through the package material 4-5 and be connected to the redistribution layers 4-4 and 4-7. The conductive vias 4-41 may be electrically connected to RDL 4-4 and RDL 4-7. That is, the electronic component 4-2 may be electrically connected to RDL 4-7 through RDL 4-4 and the conductive vias 4-41. In some embodiments of the present disclosure, the conductive via 4-41 includes a micro-TMV (Through Mold Via) or a copper pillar. Furthermore, the electronic components 4-1 and 4-2 may be electrically connected to each other through the redistribution layers, 4-3, 4-4 and 4-7 and the conductive vias 4-31 and 4-41.

In addition, RDL 4-7 may include a plurality of external electrical connections 4-71 disposed its upper surface. The external electrical connections 4-71 may be electrically connected to an external device. In some embodiments of the present disclosure, the external electrical connection 4-71 includes a bonding pad and/or a test pad. The external electrical connections 4-71 may be configured to transmit the signal from the electronic components 4-1 and/or 4-2 to the external device to which the external electrical connections 4-71 are connected aside from serving the purpose of power delivery.

FIG. 5 is a cross-sectional view of a semiconductor device package 5 in accordance with an embodiment of the present disclosure. As shown in FIG. 5, the semiconductor device package 5 may include an electronic component 5-1 and an electronic component 5-2, with both electronic components 5-1 and 5-2 arranged adjacently in a side-by-side configuration. In some embodiments of the present disclosure, the electronic component 5-1 includes a known-good die (KGD) and, the electronic component 5-2 includes a known-good die (KGD). In some embodiments of the present disclosure, the electronic component 5-1 includes a memory die, and the electronic component 5-2 includes a memory die. In some embodiments of the present disclosure, the electronic component 5-1 includes an 4 Gb memory die, and the electronic component 5-2 includes a 4 Gb memory die. That is, a size of the electronic component 5-1 may be substantially identical to a size of the electronic component 5-2. Referring to FIG. 5, a cross-sectional width of the electronic component 5-1 may be substantially identical to a cross-sectional width of the electronic component 5-2.

As shown in FIG. 5, the electronic component 5-1 has a surface 5-11 (e.g., an upper surface). The surface 5-11 may include an active surface of the electronic component 5-1. Furthermore, a redistribution layers 5-3 (RDL 5-3) may be disposed on the surface 5-11 of the electronic component 5-1. RDL 5-3 may be electrically connected to the active surface of the electronic component 5-1. Moreover, the electronic component 5-2 has a surface 5-21 (e.g., an upper surface). The surface 5-21 may include an active surface of the electronic component 5-2. Further, a redistribution layers 5-4 (RDL 5-4) may be disposed on the surface 5-21 of the electronic component 5-2. RDL 5-4 may be electrically connected to the active surface of the electronic component 5-2.

The semiconductor device package 5 includes a package material 5-5 encapsulating the electronic components 5-1 and 5-2. That is, the electronic components 5-1 and 5-2 may be held together by the package material 5-5. Further, the package material 5-5 also covers the redistribution layers 5-3 and 5-4. In some embodiments of the present disclosure, the package material 5-5 includes a molding compound. In some embodiments of the present disclosure, the package material 5-5 includes a photosensitive thick film.

Referring to FIG. 5, a redistribution layers 5-7 (RDL 5-7) may be disposed on a surface 5-51 (e.g., an upper surface) of the package material 5-5. A plurality of conductive vias 5-31 may pass through the package material 5-5 and be connected to the redistribution layers 5-3 and 5-7. The conductive vias 5-31 may be electrically connected to RDL 5-3 and RDL 5-7. That is, the electronic component 5-1 may be electrically connected to RDL 5-7 through RDL 5-3 and the conductive vias 5-31. In some embodiments of the present disclosure, the conductive via 5-31 includes a TMV (Through Mold Via) or a copper pillar. Moreover, a plurality of conductive vias 5-41 may pass through the package material 5-5 and be connected to the redistribution layers 5-4 and 5-7. The conductive vias 5-41 be electrically connected to RDL 5-4 and RDL 5-7. That is, the electronic component 5-2 may be electrically connected to RDL 5-7 through RDL 5-4 and the conductive vias 5-41. In some embodiments of the present disclosure, the conductive via 5-41 includes a micro-TMV (Through Mold Via) or a copper pillar. Further, the electronic components 5-1 and 5-2 may be electrically connected to each other through the redistribution layers, 5-3, 5-4 and 5-7, and the conductive vias, 5-31 and 5-41.

In addition, RDL 5-7 may include a plurality of external electrical connections 5-71 disposed on its upper surface. The external electrical connections 5-71 may be electrically connected to an external device. In some embodiments of the present disclosure, the external electrical connection 5-71 includes a bonding pad and/or a test pad. The external electrical connections 5-71 may be configured to transmit the signal from the electronic components 5-1 and/or 5-2 to the external device to which the external electrical connections 5-71 are connected aside from serving the purpose of power delivery.

FIG. 6 is a cross-sectional view of a semiconductor device package 6 in accordance with an embodiment of the present disclosure. As shown in FIG. 6, the semiconductor device package 6 may include an electronic component 6-1 and an electronic component 6-2 disposed above the electronic component 6-1. In some embodiments of the present disclosure, the electronic component 6-1 includes a known-good die (KGD) and, the electronic component 6-2 includes a known-good die (KGD). In some embodiments of the present disclosure, the electronic component 6-1 includes a memory die, and the electronic component 6-2 includes a memory die. In some embodiments of the present disclosure, the electronic component 6-1 includes an 8 Gb memory die, and the electronic component 6-2 includes an 8 Gb memory die. That is, a size of the electronic component 6-1 may be substantially identical to a size of the electronic component 6-2. Referring to FIG. 6, a cross-sectional width of the electronic component 6-1 is substantially identical to a cross-sectional width of the electronic component 6-2, and the electronic components 6-1 and 6-2 are stacked vertically but are not aligned directly one above the other; instead, there is a lateral offset. The electronic component 6-2 is positioned slightly to the left relative to the electronic component 6-1. Thus, the electronic component 6-1 has at least one portion that is not vertically covered by the electronic component 6-2.

As shown in FIG. 6, the electronic component 6-1 has a surface 6-11 (e.g., an upper surface) facing the electronic component 6-2. The surface 6-11 may include an active surface of the electronic component 6-1. Further, redistribution layers 6-3 (RDL 6-3) may be disposed on the surface 6-11 of the electronic component 6-1. RDL 6-3 may be electrically connected to the active surface of the electronic component 6-1. Further, the semiconductor device package 6 may include a package material 6-5 encapsulating the electronic component 6-1. In some embodiments of the present disclosure, the package material 6-5 includes a molding compound. The package material 6-5 may cover RDL 6-3 as well. Moreover, a redistribution layers 6-7 (RDL 6-7) may be disposed on a surface 6-51 (e.g., an upper surface) of the package material 6-5. In some embodiments of the present disclosure, the redistribution layer 6-7 includes a known-good-redistribution layer (KGR). A plurality of electrical connections 6-31 may be disposed between the redistribution layers 6-3 and 6-7 and surrounded by the package material 6-5. The electrical connections 6-31 may electrically connect RDL 6-3 and RDL 6-7. That is, the electronic component 6-1 may be electrically connected to RDL 6-7 through RDL 6-3 and the electrical connections 6-31. In some embodiments of the present disclosure, the electrical connection 6-31 includes a solder bump or a copper pillar micro-bump. In some embodiments of the present disclosure, one of the solder bumps or micro-bumps includes a dummy bump.

Moreover, the electronic component 6-2 is disposed on the redistribution layers 6-7 (RDL 6-7) and has a surface 6-21 (e.g., an upper surface) facing away from the electronic component 6-1. The surface 6-21 may include an active surface of the electronic component 6-2. Further, a redistribution layers 6-4 (RDL 6-4) may be disposed on the surface 6-21 of the electronic component 6-2. RDL 6-4 may be electrically connected to the active surface of the electronic component 6-2. Further, the semiconductor device package 6 may include a package material 6-6 disposed on RDL 6-7 and encapsulating the electronic component 6-2. In some embodiments of the present disclosure, the package material 6-6 includes a molding compound. The package material 6-6 may cover RDL 6-4 and RDL 6-7 as well. Moreover, a redistribution layers 6-8 (RDL 6-8) may be disposed on a surface 6-61 (e.g., an upper surface) of the package material 6-6. In some embodiments of the present disclosure, RDL 6-8 includes a known-good-redistribution layer (KGR). A plurality of electrical connections 6-41 may be disposed between the redistribution layers 6-4 and 6-8 and surrounded by the package material 6-6. The electrical connections 6-41 may electrically connect RDL 6-4 and RDL 6-8. That is, the electronic component 6-2 may be electrically connected to RDL 6-8 through RDL 6-4 and the electrical connections 6-41. In some embodiments of the present disclosure, the electrical connection 6-41 includes a solder bump or a copper pillar micro-bump. In some embodiments of the present disclosure, one of the solder bumps or micro-bumps includes a dummy bump.

Given the above, the electronic components 6-1 and 6-2 may be held together by the package materials 6-5 and 6-6.

Referring to FIG. 6, the semiconductor device package 6 may include a plurality of conductive vias TMVs 6-75. The conductive vias 6-75 may pass through the package material 6-6 and be connected to the redistribution layers 6-7 and 6-8. The conductive vias 6-75 may serve the purpose of electrically connecting RDL 6-7 and RDL 6-8. That is, the electronic components 6-1 and 6-2 may be electrically connected to each other through the redistribution layers 6-3, 6-4, 6-7 and 6-8, the electrical connections 6-31 and 6-41 and the conductive vias 6-75. In some embodiments of the present disclosure, the conductive via 6-75 includes a TMV (Through Mold Via) or a copper pillar.

In addition, RDL 6-8 may include a plurality of external electrical connections 6-81 disposed on its upper surface. The external electrical connections 6-81 may be electrically connected to an external device. In some embodiments of the present disclosure, the external electrical connections 6-81 include a test/bonding pad. The external electrical connections 6-81 may be configured to transmit the signal from the electronic components 6-1 and/or 6-2 to the external device to which the external electrical connections 6-81 are connected aside from serving the purpose of power delivery. As shown in FIG. 6, some of the external electrical connections 6-81 may be disposed directly above the portion of the electronic component 6-1 that is they are not vertically covered by the electronic component 6-2.

The signaling and power/ground functions of the electronic component 6-2 may be connected to the electronic component 6-1 internally through RDL 6-8, the conductive vias 6-75 and RDL 6-7 and to an external device (e.g., a SoC) and the package substrate through the external connections 6-81. The electronic component 6-2 may be a 4 Gb or a 8 Gb DRAM, while the electronic component 6-1 may be a 4 Gb or a 8 Gb DRAM. The dual-die combinations (the electronic component 6-1 and the electronic component 6-2 combined) may include 4 Gb+4 Gb, 4 Gb+8 Gb, 8 Gb+4 Gb, 8 Gb+8 Gb and others higher-memory-capacity and faster memory combinations.

In some embodiments of the present disclosure, an underfill (or a NCP) may be disposed between RDL 6-8 and RDL 6-4 and surround the electrical connections 6-41. In some embodiments of the present disclosure, an underfill may be disposed between RDL 6-7 and RDL 6-3 and surround the electrical connections 6-31. In some embodiments of the present disclosure, the underfill or NCP can be replaced with molded underfill which can be carried out during overmolding to form the package materials 6-5 and 6-6.

FIG. 7A, FIG. 7B, FIG. 7C, FIG. 7D, FIG. 7E and FIG. 7F illustrate one or more stages of an example of a method for manufacturing a semiconductor device package shown in FIG. 6 in accordance with some embodiments of the present disclosure.

Referring to FIG. 7A, a redistribution layers 7-8 (RDL 7-8) with a plurality of copper pillars 7-75 is provided. RDL 7-8 may be formed on a temporary carrier 701 pre-coated with a release layer 702 disposed between RDL 7-8 and the carrier 701. After the formation of RDL 7-8 with copper pillars on the carrier 701, it undergoes testing to ensure that individual RDL 7-8 is a Known-Good-Redistribution layers (KGR). The copper pillars 7-75 may be arranged on RDL 7-8 and electrically connected to RDL 7-8. In some embodiments of the present disclosure, the copper pillar 7-75 has a solder tip 7-750 on top of it.

Referring to FIG. 7B, an electronic component 7-2 is provided. The electronic component 7-2 may be mounted on RDL using the electrical connections 7-41. That is, the electronic component 7-2 has an active surface facing RDL 7-8, and the active surface of the electronic component 7-2 may be electrically connected to RDL 7-8 through the electrical connections 7-41. In some embodiments of the present disclosure, the electrical connection 7-41 includes a solder bump or a copper pillar micro-bump. In some embodiments of the present disclosure, an underfill (or a NCP) 7-40 is provided between the electronic component 7-2 and RDL 7-8 and surrounds the electrical connections 7-41. Before the electronic component 7-2 is disposed on RDL 7-8, it undergoes testing to ensure that the electronic component 7-2 is a Known-Good Die (KGD). The electronic component 7-2 and RDL 7-8 with the plurality of copper pillars 7-75 may be assembled to form a sub-assembly. In some embodiments of the present disclosure, a testing process is performed on the sub-assembly so as to ensure that the sub-assembly is known good.

Referring to FIG. 7C, a package material 7-6 is provided. The package material 7-6 may be disposed on RDL 7-8 and encapsulate RDL 7-8, the copper pillars 7-75 and the electronic component 7-2. After the package material 7-6 is formed on RDL 7-8, a planarization or grinding process may be performed on an upper surface of the package material 7-6 until the solder tips 7-750 of the copper pillars 7-75 are exposed at the upper surface of the package material 7-6. Referring to FIG. 7D, a redistribution layers 7-7 (RDL 7-7) is provided. RDL 7-7 may be formed on a temporary carrier 703, and a release layer 704 may be disposed between the redistribution layer 7-7 and the carrier 703. After the redistribution layers 7-7 is formed on the carrier 703, it undergoes testing to ensure that the redistribution layers 7-7 is a Known-Good-Redistribution layers (KGR).

Referring to FIG. 7E, RDL 7-7 is provided on the sub-assembly comprising the electronic component 7-2, RDL 7-8 with the plurality of copper pillars 7-75. RDL 7-7 may be disposed on the upper surface of the package material 7-6 and electrically connected to the solder tips 7-750 of the copper pillars 7-75. Before RDL 7-7 is provided, it is removed from the carrier 703 and the release layer 7-7. In some embodiments of the present disclosure, before RDL 7-7 is released, it can undergo processes to create bond/test pad surface finishes (and bond pads as needed) for subsequent test and assembly. The electronic component 7-2, RDL 7-8 with the plurality of copper pillars 7-75, the package material 7-6 and RDL layer 7-7 combined constitute another sub-assembly. In some embodiments of the present disclosure, a testing process is performed on the newly formed sub-assembly so as to ensure that the sub-assembly is known good.

Referring to FIG. 7F, an electronic component 7-1 and a package material 7-5 are provided. The electronic component 7-1 may be mounted on RDL 7-7 using the electrical connections 7-31. That is, the electronic component 7-1 has an active surface facing RDL 7-7, and the active surface of the electronic component 7-1 may be electrically connected to RDL 7-7 through the electrical connections 7-31. In some embodiments of the present disclosure, the electrical connection 7-31 includes a solder bump or a copper pillar micro-bump. In some embodiments of the present disclosure, an underfill (or a NCP) 7-30 is provided between the electronic component 7-1 and RDL 7-3 and surrounds the electrical connections 7-31. Before the electronic component 7-1 is disposed on the redistribution layer 7-7, it undergoes testing to ensure that the electronic component 7-1 is a Known-Good Die (KGD).

Further, the package material 7-5 may be disposed on RDL 7-7 and encapsulate RDL 7-7 and the electronic component 7-1. After the package material 7-5 is formed on RDL 7-7, a planarization or a grinding process may be performed on an upper surface of the package material 7-5.

After proceeding through the manufacturing process steps as shown in FIGS. 7A, to 7F, the semiconductor device package 7 is formed (see FIG. 7F). In some embodiments of the present disclosure, the semiconductor device package 7 is the same as, or similar to, the semiconductor device package 6 shown in FIG. 6.

FIG. 8 is a cross-sectional view of a semiconductor device package 8 in accordance with an embodiment of the instant disclosure. As shown in FIG. 8, the semiconductor device package 8 may include an electronic component 8-1 and an electronic component 8-2 disposed above the electronic component 8-1. In some embodiments of the present disclosure, the electronic component 8-1 includes a known-good die (KGD) and, the electronic component 8-2 includes a known-good die (KGD). In some embodiments of the present disclosure, the electronic component 8-1 includes a memory die, and the electronic component 8-2 includes a memory die. In some embodiments of the present disclosure, the electronic component 8-1 includes an 8 Gb memory die, and the electronic component 8-2 includes an 8 Gb memory die. That is, a size of the electronic component 8-1 may be substantially identical to a size of the electronic component 8-2. Referring to FIG. 8, a cross-sectional width of the electronic component 8-1 is substantially identical to a cross-sectional width of the electronic component 8-2, and the electronic components 8-1 and 8-2 are stacked vertically but are not aligned directly one above the other; instead, there is a lateral offset. The electronic component 8-2 is positioned slightly to the left relative to the electronic component 8-1. Thus, the electronic component 8-1 has at least one portion that is not vertically covered by the electronic component 8-2.

As shown in FIG. 8, the electronic component 8-1 has a surface 8-11 (e.g., an upper surface) facing the electronic component 8-2. The surface 8-11 may include an active surface of the electronic component 8-1. Further, a redistribution layers 8-3 (RDL 8-3) may be disposed on the surface 8-11 of the electronic component 8-1. RDL 8-3 may be electrically connected to the active surface of the electronic component 8-1. A spacer 8-9 may be positioned to be adjacent to the electronic component 8-1. Since the electronic components 8-1 and 8-2 are stacked vertically but are not aligned directly one above the other, the spacer 8-9 is configured to support the electronic component 8-2 disposed above the electronic component 8-1. Further, the semiconductor device package 8 may include a package material 8-5 encapsulating the spacer 8-9 and the electronic component 8-1. In some embodiments of the present disclosure, the package material 8-5 includes a molding compound. In some embodiments of the present disclosure, the spacer 8-9 is not deployed and the space occupied by the spacer is filled by the packaging material 8-5. The package material 8-5 may cover RDL 8-3 as well. Moreover, a redistribution layers 8-7 (RDL 8-7) may be disposed on a surface 8-51 (e.g., an upper surface) of the package material 8-5. RDL 8-7 may be disposed on a surface 8-91 (e.g., an upper surface) of the spacer 8-9 when it is deployed. In some embodiments of the present disclosure, RDL 8-7 includes a known-good-redistribution layers (KGR). A plurality of conductive vias 8-31 may pass through the package material 8-5 and be connected to the redistribution layers 8-3 and 8-7. The conductive vias 8-31 may electrically connect RDL 8-3 and RDL 8-7. That is, the electronic component 8-1 may be electrically connected to RDL 8-7 through RDL 8-3 and the conductive vias 8-31. In some embodiments of the present disclosure, the conductive via 8-31 includes a TMV (Through Mold Via) or a copper pillar.

Moreover, the electronic component 8-2 is disposed on RDL 8-7. The electronic component 8-2 may be attached to RDL 8-7 through an adhesive 8-25. In some embodiments of the present disclosure, the adhesive 8-25 includes a die attachment film. Further, the electronic component 8-2 has a surface 8-21 (e.g., an upper surface) facing away from the electronic component 8-1. The surface 8-21 may include an active surface of the electronic component 8-2. Further, a redistribution layers 8-4 (RDL 8-4) may disposed be on the surface 8-21 of the electronic component 8-2. RDL 8-4 may be electrically connected to the active surface of the electronic component 8-2. Further, the semiconductor device package 8 may include a package material 8-6 disposed on RDL 8-7 which encapsulates the electronic component 8-2. In some embodiments of the present disclosure, the package material 8-6 includes a molding compound. The package material 8-6 may cover RDL 8-4 and RDL 8-7 as well. Moreover, a redistribution layers 8-8 (RDL 8-8) may be disposed on a surface 8-61 (e.g., an upper surface) of the package material 8-6. In some embodiments of the present disclosure, RDL 8-8 includes a known-good-redistribution layers (KGR). A plurality of conductive vias 8-41 may pass through the package material 8-6 and be connected to the redistribution layers 8-4 and 8-8. The conductive vias 8-41 may electrically connect RDL 8-4 and RDL 8-8. That is, the electronic component 8-2 may be electrically connected to RDL 8-8 through RDL 8-4 and the conductive vias 8-41. In some embodiments of the present disclosure, the conductive via 8-41 includes a TMV (Through Mold Via) or a copper pillar.

Given the above, the electronic components 8-1 and 8-2 may be held together by the package materials 8-5 and 8-6.

Referring to FIG. 8, the semiconductor device package 8 may include a plurality of conductive vias or TMVs 8-75. The conductive vias 8-75 may pass through the package material 8-6 and be connected to the redistribution layers 8-7 and 8-8. The conductive vias 8-75 may electrically connect RDL 8-7 and RDL 8-8. That is, the electronic components 8-1 and 8-2 may be electrically connected to each other through the redistribution layers, 8-3, 8-4, 8-7 and 8-8 and the conductive vias, 8-31, 8-41 and 8-75. In some embodiments of the present disclosure, the conductive via 8-75 includes a TMV (Through Mold Via) or a copper pillar.

In addition, RDL 8-8 may include a plurality of external electrical connections 8-81 on its surface. The external electrical connections 8-81 may be electrically connected to an external device. In some embodiments of the present disclosure, the external electrical connection 8-81 includes a test/bonding pad. The external electrical connections 8-81 may be configured to transmit the signal from the electronic components 8-1 and/or 8-2 to the external device to which the external electrical connections 8-81 are connected aside from serving the function of power delivery. As shown in FIG. 8, some of the external electrical connections 8-81 may be disposed directly above the portion of the electronic component 8-1 that is not vertically covered by the electronic component 8-2.

FIG. 9 is a cross-sectional view of a semiconductor device package 9 in accordance with an embodiment of the instant disclosure. As shown in FIG. 9, the semiconductor device package 9 may include an electronic component 9-1 and an electronic component 9-2 disposed above the electronic component 9-1. In some embodiments of the present disclosure, the electronic component 9-1 includes a known-good die (KGD) and, the electronic component 9-2 includes a known-good die (KGD). In some embodiments of the present disclosure, the electronic component 9-1 includes a memory die, and the electronic component 9-2 includes a memory die. In some embodiments of the present disclosure, the electronic component 9-1 includes an 8 Gb memory die, and the electronic component 9-2 includes an 8 Gb memory die. That is, a size of the electronic component 9-1 may be substantially identical to a size of the electronic component 9-2. Referring to FIG. 9, a cross-sectional width of the electronic component 9-1 is substantially identical to a cross-sectional width of the electronic component 9-2, and the electronic components 9-1 and 9-2 are stacked vertically but are not aligned directly one above the other; instead, there is a lateral offset. The electronic component 9-2 is positioned slightly to the left relative to the electronic component 9-1. Thus, the electronic component 9-1 has at least one portion that is not vertically covered by the electronic component 9-2.

As shown in FIG. 9, the electronic component 9-1 has a surface 9-11 (e.g., an upper surface) facing the electronic component 9-2. The surface 9-11 may include an active surface of the electronic component 9-1. Further, a redistribution layers 9-3 (RDL 9-3) may be disposed on the surface 9-11 of the electronic component 9-1. RDL 9-3 may be electrically connected to the active surface of the electronic component 9-1. Moreover, the electronic component 9-2 has a surface 9-21 (e.g., a lower surface) facing the electronic component 9-1. The surface 9-21 may include an active surface of the electronic component 9-2. Further, a redistribution layers 9-4 (RDL 9-4) may be disposed on the surface 9-21 of the electronic component 9-2. RDL 9-4 may be electrically connected to the active surface of the electronic component 9-2. The semiconductor device package 9 may include a plurality of electrical connections 9-31 disposed between RDL 9-3 and RDL 9-4. In some embodiments of the present disclosure, the electrical connection 9-31 includes a solder bump or a copper pillar micro-bump. In some embodiments of the present disclosure, the solder bump or the micro-bump includes a dummy bump. The electrical connections 9-31 may be electrically connected to RDL 9-3 and RDL 9-4. That is, the electronic component 9-1 and the electronic components 9-2 may be electrically connected to each other by RDL 9-3, RDL 9-4 and the electrical connections 9-31.

The semiconductor device package 9 may optionally include a spacer 9-8. The spacer 9-8 may be disposed under the electronic component 9-2 and adjacent to the electronic component 9-1. Since the electronic components 9-1 and 9-2 are stacked vertically but are not aligned directly one above the other, the spacer 9-8 is configured to support the electronic component 9-2 which is disposed above the electronic component 9-1. An adhesive 9-85 may be disposed between a surface 9-81 (e.g., an upper surface) of the spacer 9-8 and RDL 9-4. That is, the spacer 9-8 may be attached to the electronic component 9-2 through the adhesive 9-85. In some embodiments of the present disclosure, the adhesive 9-85 includes a die attachment film.

Referring to FIG. 9, the semiconductor device package 9 may include a package material 9-5 encapsulating the electronic component 9-1, the electronic component 9-2 and the spacer 9-8. The package material 9-5 may cover the redistribution layers 9-3 and 9-4 and surround the electrical connections 9-31. That is, the electronic components 9-1 and 9-2 may be held together by the package material 9-5. In some embodiments of the present disclosure, the package material 9-5 includes a molding compound.

Moreover, a redistribution layers 9-7 (RDL 9-7) may be disposed on a surface 9-51 (e.g., an upper surface) of the package material 9-5. In some embodiments of the present disclosure, RDL 9-7 includes a known-good-redistribution layers (KGR). Further, a plurality of conductive vias 9-55 may pass through the package material 9-5 and be connected to the redistribution layers 9-7 and 9-3. The conductive vias 9-75 may be electrically connected to RDL 9-7 and RDL 9-3. That is, the electronic components 9-1 and 9-2 may be electrically connected to each other through the redistribution layers 9-3, 9-4 and 9-7, the electrical connections 9-31 and the conductive vias 9-55. In some embodiments of the present disclosure, the conductive via 9-55 includes a TMV (Through Mold Via) or a copper pillar.

In addition, RDL 9-7 may include a plurality of external electrical connections 9-71 on its surface. The external electrical connections 9-71 may be electrically connected to an external device. In some embodiments of the present disclosure, the external electrical connection 9-71 includes a test/bonding pad The external electrical connections 9-71 may be configured to transmit the signal from the electronic components 9-1 and/or 9-2 to the external device to which the external electrical connections 9-71 are connected aside from serving the purpose of power delivery. As shown in FIG. 9, some of the external electrical connections 9-71 may be disposed directly above the portion of the electronic component 9-1 that is not vertically covered by the electronic component 9-2.

FIG. 10 is a cross-sectional view of a semiconductor device package 10 in accordance with an embodiment of the present disclosure. As shown in FIG. 10, the semiconductor device package 10 may include an electronic component 10-1 and an electronic component 10-2 disposed above the electronic component 10-1. In some embodiments of the present disclosure, the electronic component 10-1 includes a known-good die (KGD) and, the electronic component 10-2 includes a known-good die (KGD). In some embodiments of the present disclosure, the electronic component 10-1 includes a memory die, and the electronic component 10-2 includes a memory die. In some embodiments of the present disclosure, the electronic component 10-1 includes an 8 Gb memory die, and the electronic component 10-2 includes a 4 Gb memory die. That is, a size of the electronic component 10-1 may be greater than a size of the electronic component 10-2. Referring to FIG. 10, a cross-sectional width of the electronic component 10-1 may be greater than a cross-sectional width of the electronic component 10-2, and thus the electronic component 10-1 has at least one portion that is not vertically covered by the electronic component 10-2 when the electronic component 10-2 is stacked on the electronic component 10-1.

As shown in FIG. 10, the electronic component 10-2 may be disposed on the electronic component 10-1 through an adhesive 10-15. In some embodiments of the present disclosure, the adhesive 10-15 includes a die attachment film.

The electronic component 10-1 has a surface 10-11 (e.g., an upper surface) facing the electronic component 10-2. The surface 10-11 may include an active surface of the electronic component 10-1. Furthermore, a redistribution layers 10-3 (RDL 10-3) may be disposed on the surface 10-11 of the electronic component 10-1. RDL 10-3 may be electrically connected to the active surface of the electronic component 10-1. Moreover, the electronic component 10-2 has a surface 10-21 (e.g., an upper surface) facing away from the electronic component 10-1. The surface 10-21 may include an active surface of the electronic component 10-2. Further, a redistribution layers 10-4 (RDL 10-4) may be disposed on the surface 10-21 of the electronic component 10-2. RDL 10-4 may be electrically connected to the active surface of the electronic component 10-2.

The semiconductor device package 10 may include a package material 10-5 encapsulating the electronic components 10-1 and 10-2. Further, the package material 10-5 may cover the redistribution layers 10-3 and 10-4. That is, the electronic components 10-1 and 10-2 may be held together by the package material 10-5. In some embodiments of the present disclosure, the package material 10-5 includes a molding compound.

Moreover, a redistribution layers 10-7 (RDL 10-7) may be disposed on a surface 10-51 (e.g., an upper surface) of the package material 10-5. A plurality of conductive vias or TMVs 10-55 may pass through the package material 10-5 and be connected to the redistribution layers 10-3 and 10-7. The conductive vias 10-55 may be electrically connected to RDL 10-3 and RDL 10-7. That is, the electronic component 10-1 may be electrically connected to RDL 10-7 through RDL 10-3 and the conductive vias 10-55. In some embodiments of the present disclosure, the conductive vias 10-55 includes a TMV (Through Mold Via) or a copper pillar. Moreover, a plurality of conductive vias 10-41 may pass through the package material 10-5 and be connected to the redistribution layers 10-4 and 10-7. The conductive vias 10-41 may be electrically connected to RDL 10-4 and RDL 10-7. That is, the electronic component 10-2 may be electrically connected to RDL 10-7 through RDL 10-4 and the conductive vias 10-41. In some embodiments of the present disclosure, the conductive via 10-41 includes a micro-TMV (Through Mold Via) or a copper pillar. Furthermore the electronic components 10-1 and 10-2 may be electrically connected to each other through the redistribution layers 10-3, 10-4 and 10-7 and the conductive vias 10-55 and 10-41.

In addition, RDL 10-7 may include a plurality of external electrical connections 10-71 on its surface. The external electrical connections 10-71 may be electrically connected to an external device. In some embodiments of the present disclosure, the external electrical connection 10-71 includes a test/bonding pad. The external electrical connections 10-71 may be configured to transmit the signal from the electronic components 10-1 and/or 10-2 to the external device to which the external electrical connections 10-71 are connected aside from serving the functions of power delivery. As shown in FIG. 10, some of the external electrical connections 10-71 may be disposed directly above the portion of the electronic component 10-1 that is not vertically covered by the electronic component 10-2.

FIG. 11 is a cross-sectional view of a semiconductor device package 11 in accordance with an embodiment of the instant disclosure. As shown in FIG. 11, the semiconductor device package 11 may include an electronic component 11-1 and an electronic component 11-2 disposed above the electronic component 11-1. In some embodiments of the present disclosure, the electronic component 11-1 includes a known-good die (KGD) and, the electronic component 11-2 includes a known-good die (KGD). In some embodiments of the present disclosure, the electronic component 11-1 includes a memory die, and the electronic component 11-2 includes a memory die. In some embodiments of the present disclosure, the electronic component 11-1 includes a 4 Gb memory die, and the electronic component 11-2 includes an 8 Gb memory die. That is, a size of the electronic component 11-2 may be greater than a size of the electronic component 11-1. Referring to FIG. 11, a cross-sectional width of the electronic component 11-2 may be greater than a cross-sectional width of the electronic component 11-1, and thus the electronic component 11-2 has at least one portion that is not vertically overlapped with the electronic component 11-1 when the electronic component 11-2 is stacked on the electronic component 11-1.

As shown in FIG. 11, the electronic component 11-1 has a surface 11-11 (e.g., an upper surface) facing the electronic component 11-2. The surface 11-11 may include an active surface of the electronic component 11-1. Further, a redistribution layers 11-3 (RDL 11-3) may be disposed on the surface 11-11 of the electronic component 11-1. RDL 11-3 may be electrically connected to the active surface of the electronic component 11-1. Furthermore, the semiconductor device package 11 may include a package material 11-5 encapsulating the electronic component 11-1. In some embodiments of the present disclosure, the package material 11-5 includes a molding compound. The package material 11-5 may cover RDL 11-3 as well. Moreover, a redistribution layers 11-7 (RDL 11-7) may be disposed on a surface 11-51 (e.g., an upper surface) of the package material 11-5. In some embodiments of the present disclosure, the redistribution layers 11-7 (RDL 11-7) includes a known-good-redistribution layers (KGR). A plurality of electrical connections 11-31 may be disposed between the redistribution layers 11-3 and 11-7 and surrounded by the package material 11-5. The electrical connections 11-31 may be electrically connected to RDL 11-3 and RDL 11-7. That is, the electronic component 11-1 may be electrically connected to RDL 11-7 through RDL 11-3 and the electrical connections 11-31. In some embodiments of the present disclosure, the electrical connection 11-31 includes a solder bump or a copper pillar micro-bump. In some embodiments of the present disclosure, one of the solder bumps or micro-bumps includes a dummy bump.

Moreover, the electronic component 11-2 is disposed on RDL 11-7 and has a surface 11-21 (e.g., an upper surface) facing away from the electronic component 11-1. The surface 11-21 may include an active surface of the electronic component 11-2. Furthermore, a redistribution layers 11-4 (RDL 11-4) may be disposed on the surface 11-21 of the electronic component 11-2. RDL 11-4 may be electrically connected to the active surface of the electronic component 11-2. Further, the semiconductor device package 11 may include a package material 11-6 disposed on RDL 11-7 and encapsulating the electronic component 11-2. In some embodiments of the present disclosure, the package material 11-6 includes a molding compound. The package material 11-6 may cover RDL 11-4 and RDL 11-7 as well. Moreover, a redistribution layers 11-8 (RDL 11-8) of the package material 11-6. In some embodiments of the present disclosure, RDL 11-8 includes a known-good-redistribution layers (KGR). A plurality of electrical connections 11-41 may be disposed between the redistribution layers 11-4 and 11-8 and surrounded by the package material 11-6. The electrical connections 11-41 may be electrically connected to RDL 11-4 and RDL 11-8. That is, the electronic component 11-2 may be electrically connected to the redistribution layer 11-8 through RDL 11-4 and the electrical connections 11-41. In some embodiments of the present disclosure, the electrical connections 11-41 include a solder bump or a copper pillar micro-bump. In some embodiments of the present disclosure, one of the solder bumps or micro-bumps includes a dummy bump.

Given the above, the electronic components 11-1 and 11-2 may be held together by the package materials 11-5 and 11-6.

Referring to FIG. 11, the semiconductor device package 11 may include a plurality of conductive vias 11-75. The conductive vias or TMVs 11-75 may pass through the package material 11-6 and be connected to the redistribution layers 11-7 and 11-8. The conductive vias 11-75 may electrically connect RDL 11-7 and RDL 11-8. That is, the electronic components 11-1 and 11-2 may be electrically connected to each other through the redistribution layers, 11-3, 11-4, 11-7 and 11-8, the electrical connections, 11-31 and 11-41, and the conductive vias 11-75. In some embodiments of the present disclosure, the conductive via 11-75 includes a TMV (Through Mold Via) or a copper pillar.

In addition, the redistribution layers 11-8 (RDL 11-8) may include a plurality of external electrical connections 11-81 disposed on its upper surface. The external electrical connections 11-81 may be electrically connected to an external device. In some embodiments of the present disclosure, the external electrical connections 11-81 include a test/bonding pad. The external electrical connections 11-81 may be configured to transmit the signal from the electronic components 11-1 and/or 11-2 to the external device to which the external electrical connections 11-81 are connected apart from serving the function of power delivery. As shown in FIG. 11, some of the external electrical connections 11-81 may be disposed directly above the portion of the electronic component 11-1 that is not vertically overlapped with the electronic component 11-2.

FIG. 12A is a cross-sectional view of a semiconductor device package 12 in accordance with an embodiment of the present disclosure. As shown in FIG. 12, the semiconductor device package 12 may include an electronic component 12-1, an electronic component 12-2 disposed above the electronic component 12-1, and an electronic component 12-3 disposed on the electronic component 12-2. In some embodiments of the present disclosure, the electronic component 12-1 includes a known-good die (KGD), the electronic component 12-2 includes a known-good die (KGD), and the electronic component 12-3 includes a known-good die (KGD). In some embodiments of the present disclosure, the electronic component 12-1 includes a memory die, the electronic component 12-2 includes a memory die, and the electronic component 12-3 includes a memory die. In some embodiments of the present disclosure, the electronic component 12-1 includes an 8 Gb memory die, the electronic component 12-2 includes a 4 Gb memory die, and the electronic component 12-3 includes a 4 Gb memory die. That is, a size of the electronic component 12-1 may be greater than a size of the electronic component 12-2 or 12-3. The size of the electronic component 12-2 may be substantially identical to the size of the electronic component 12-3. Referring to FIG. 12A, a cross-sectional width of the electronic component 12-1 may be greater than a cross-sectional width of the electronic component 12-2 or 12-3, and thus the electronic component 12-1 has at least one portion that is not vertically covered by the electronic component 12-2 when the electronic component 12-2 is stacked on the electronic component 12-1. Further, the electronic components 12-2 and 12-3 are stacked vertically but are not aligned directly one above the other; instead, there is a lateral offset. The electronic component 12-3 is positioned slightly to the left relative to the electronic component 12-2. Thus, the electronic component 12-2 has at least one portion that is not vertically covered by the electronic component 12-3.

As shown in FIG. 12A, the electronic component 12-2 may be disposed on the electronic component 12-1 through an adhesive 12-111. In some embodiments of the present disclosure, the adhesive 12-111 includes a die attachment film. Moreover, the electronic component 12-3 may be disposed on the electronic component 12-2 through an adhesive 12-211. In some embodiments of the present disclosure, the adhesive 12-211 includes a die attachment film.

Referring to FIG. 12A, the electronic component 12-1 has a surface 12-11 (e.g., an upper surface) facing the electronic component 12-2. The surface 12-11 may include an active surface of the electronic component 12-1. Further, a redistribution layers 12-110 (RDL 12-110) may be disposed on the surface 12-11 of the electronic component 12-1. RDL 12-110 may be electrically connected to the active surface of the electronic component 12-1. The electronic component 12-2 has a surface 12-21 (e.g., an upper surface) facing away from the electronic component 12-1. The surface 12-21 may include an active surface of the electronic component 12-2. Furthermore, a redistribution layers 12-210 (RDL 12-210) may be disposed on the surface 12-21 of the electronic component 12-2. RDL 12-210 may be electrically connected to the active surface of the electronic component 12-2. Moreover, the electronic component 12-3 has a surface 12-31 (e.g., an upper surface) facing away from the electronic component 12-2. The surface 12-31 may include an active surface of the electronic component 12-3. Further, a redistribution layers 12-310 (RDL 12-310) may be disposed on the surface 12-31 of the electronic component 12-3. RDL 12-310 may be electrically connected to the active surface of the electronic component 12-3.

The semiconductor device package 12 may include a spacer 12-8. The spacer 12-8 may be disposed under the electronic component 12-3, adjacent to the electronic component 12-2 and above the electronic component 12-1. Since the electronic components 12-2 and 12-3 are stacked vertically but are not aligned directly one above the other, the spacer 12-8 is configured to support the electronic component 12-3 which is disposed above the electronic component 12-2. As shown in FIG. 12A, the spacer 12-8 is disposed on the adhesive 12-111. Further, an adhesive 12-811 may be disposed between a surface 12-81 (e.g., an upper surface) of the spacer 12-8 and the electronic component 12-3. That is, the spacer 12-8 may be attached to the electronic component 12-1 through the adhesive 12-111 and attached to the electronic component 12-3 through the adhesive 12-811. In some embodiments of the present disclosure, the adhesive 12-811 includes a die attachment film.

Referring to FIG. 12A, the semiconductor device package 12 may include a package material 12-5 encapsulating the electronic component 12-1, the electronic component 12-2, the electronic component 12-3 and the spacer 12-8. The package material 12-5 may cover the redistribution layers 12-110, 12-210 and 12-310. That is, the electronic components 12-1, 12-2 and 12-3 may be held together by the package material 12-5. In some embodiments of the present disclosure, the package material 12-5 includes a molding compound.

Moreover, a redistribution layers 12-7 (RDL 12-7) may be disposed on a surface 12-51 (e.g., an upper surface) of the package material 12-5. A plurality of conductive vias or TMVs 12-55 may pass through the package material 12-5 and be connected to the redistribution layers 12-110 and 12-7. The conductive vias 12-55 may serve to establish electrical connectivity between the redistribution layer 12-110 and the redistribution layer 12-7. That is, the electronic component 12-1 may be electrically connected to RDL 12-7 through RDL 12-110 and the conductive vias 12-55. In some embodiments of the present disclosure, the conductive via 12-55 includes a TMV (Through Mold Via) or a copper pillar. A plurality of conductive vias 12-57 may pass through the package material 12-5 and be connected to the redistribution layers 12-210 and 12-7. The conductive vias 12-57 electrically connect RDL 12-210 and RDL 12-7. That is, the electronic component 12-2 may be electrically connected to RDL 12-7 through RDL 12-210 and the conductive vias 12-57. In some embodiments of the present disclosure, the conductive via 12-57 includes a micro-TMV (Through Mold Via) or a copper pillar. Moreover, a plurality of conductive vias or copper pillars 12-59 may pass through the package material 12-5 and be connected to the redistribution layers 12-310 and 12-7. The conductive vias 12-59 may serve to establish electrical connectivity between RDL 12-310 and RDL 12-7. That is, the electronic component 12-3 may be electrically connected to RDL 12-7 through RDL 12-310 and the conductive vias 12-59. In some embodiments of the present disclosure, the conductive via 12-59 includes a micro-TMV (Through Mold Via) or a copper pillar. Further, the electronic components, 12-1, 12-2 and 12-3, may be electrically connected to each other through the redistribution layers, 12-110, 12-210, 12-310 and 12-7, and the conductive vias 12-55, 12-57 and 12-59.

In addition, RDL 12-7 may include a plurality of external electrical connections 12-71 on its surface. The external electrical connections 12-71 may be electrically connected to an external device. In some embodiments of the present disclosure, the external electrical connection 12-71 includes a test/bonding pad. The external electrical connections 12-71 may be configured to transmit the signal from the electronic components 12-1, 12-2 and/or 12-3 to the external device to which the external electrical connections 12-71 are connected apart from serving the function of power delivery.

FIG. 12B is an enlarged top view of the portion “A” in FIG. 12A, which shows an embodiment of an arrangement of conductive vias 12-55 between RDL 12-110 and RDL 12-7. Referring to FIG. 12B, RDL 12-110 and 12-7, each may include a pad 12-113 wherein the pad 12-113 may be rectangular-shaped. As shown in FIG. 12B, a conductive via 12-55 may include a standard conductive via 12-551 disposed on the pad 12-113 of RDL 12-110 and equivalently on RDL 12-7. In addition, the conductive vias 12-55 may further include a redundant conductive via 12-553 disposed on the pad 12-113 of the redistribution layer 12-110 and equivalently on RDL 12-7 to improve the processing yield.

FIG. 12C is an enlarged top view of the portion “A” in FIG. 12A, which shows another embodiment of an arrangement of conductive vias 12-55 between RDL 12-110 and RDL 12-7. Referring to FIG. 12C, RDL 12-110, for instance, may include a pad 12-114, wherein the pad 12-114 may be cross-shaped. As shown in FIG. 12C, a conductive vias 12-55 may include a standard conductive via 12-552 disposed on the pad 12-114 of RDL 12-110. In addition, the conductive vias 12-55 may further include three more redundant conductive vias 12-554 disposed on the pad 12-114 of RDL 12-110.

The configuration of the conductive vias as shown in FIG. 12B and FIG. 12C can be applied to other embodiments of semiconductor package devices with conductive vias, such as the embodiments illustrated in FIGS. 4, 5, 6, 8, 9, 10 and 11.

FIG. 13 is a cross-sectional view of a semiconductor device package 13 in accordance with an embodiment of the present disclosure. As shown in FIG. 13, the semiconductor device package 13 may include an electronic component 13-1 and an electronic component 13-2 disposed above the electronic component 13-1. In some embodiments of the present disclosure, the electronic component 13-1 includes a known-good die (KGD) and, the electronic component 13-2 includes a known-good die (KGD). In some embodiments of the present disclosure, the electronic component 13-1 includes a memory die, and the electronic component 13-2 includes a memory die. In some embodiments of the present disclosure, the electronic component 13-1 includes an 8 Gb memory die, and the electronic component 13-2 includes an 8 Gb memory die. That is, a size of the electronic component 13-1 may be substantially identical to a size of the electronic component 13-2. Referring to FIG. 13, a cross-sectional width of the electronic component 13-1 is substantially identical to a cross-sectional width of the electronic component 13-2, and the electronic components 13-1 and 13-2 are stacked vertically but are not aligned directly one above the other; instead, there is a lateral offset. The electronic component 13-2 is positioned slightly to the left relative to the electronic component 13-1. Thus, the electronic component 13-1 has at least one portion that is it is not vertically covered by the electronic component 13-2.

As shown in FIG. 13, the electronic component 13-1 has a surface 13-11 (e.g., an upper surface) facing the electronic component 13-2. The surface 13-11 may include an active surface of the electronic component 13-1. Further, a redistribution layers 13-3 (RDL 13-3) may be disposed on the surface 13-11 of the electronic component 13-1. The redistribution layer 13-3 may be electrically connected to the active surface of the electronic component 13-1. Further, the semiconductor device package 13 may include a package material 13-5 encapsulating the electronic component 13-1. In some embodiments of the present disclosure, the package material 13-5 includes a molding compound. The package material 13-5 may cover RDL 13-3 as well. Moreover, a redistribution layers 13-7 (RDL 13-7) may be disposed on a surface 13-51 (e.g., an upper surface) of the package material 13-5. In some embodiments of the present disclosure, RDL 13-7 includes a known-good-redistribution layer (KGR). A plurality of electrical connections 13-31 may be disposed between the redistribution layers 13-3 and 13-7 and surrounded by the package material 13-5. The electrical connections 13-31 may serve to establish electrical connectivity between RDL 13-3 and RDL 13-7. That is, the electronic component 13-1 may be electrically connected to RDL 13-7 through RDL 13-3 and the electrical connections 13-31. In some embodiments of the present disclosure, the electrical connection 13-31 includes a solder bump or a copper pillar micro-bump. In some embodiments of the present disclosure, one of the solder bumps or micro-bumps includes a dummy bump.

Moreover, the electronic component 13-2 is disposed on RDL 13-7 and has a surface 13-21 (e.g., an upper surface) facing away from the electronic component 13-1. The surface 13-21 may include an active surface of the electronic component 13-2. Further, a redistribution layers 13-4 (RDL 13-4) may be disposed on the surface 13-21 of the electronic component 13-2. RDL 13-4 may be electrically connected to the active surface of the electronic component 13-2. Further, the semiconductor device package 13 may include a package material 13-6 disposed on RDL 13-7 and encapsulating the electronic component 13-2. In some embodiments of the present disclosure, the package material 13-6 includes a molding compound. The package material 13-6 may cover RDL 13-4 and RDL 13-7 as well. Moreover, a redistribution layers 13-8 (RDL 13-8) may be disposed on a surface 13-61 (e.g., an upper surface) of the package material 13-6. In some embodiments of the present disclosure, RDL 13-8 includes a known-good-redistribution layer (KGR). A plurality of electrical connections 13-41 may be disposed between the redistribution layers 13-4 and 13-8 and surrounded by the package material 13-6. The electrical connections 13-41 may electrically connect RDL 13-4 and RDL 13-8. That is, the electronic component 13-2 may be electrically connected to RDL 13-8 through RDL 13-4 and the electrical connections 13-41. In some embodiments of the present disclosure, the electrical connections 13-41 includes a solder bump or a copper pillar micro-bump. In some embodiments of the present disclosure, one of the solder bumps or micro-bumps includes a dummy bump.

Given the above, the electronic components 13-1 and 13-2 may be held together by the package materials 13-5 and 13-6.

Referring to FIG. 13 the semiconductor device package 6 may include an electrically conductive spacer 13-9 with electrically conductive through vias and RDLs as needed. In some embodiments of the present disclosure, the conductive spacer 13-9 includes a HDS (High-density-interconnect Spacer). The conductive spacer 13-9 may pass through the package material 13-6 and be connected to the redistribution layers 13-7 and 13-8. The conductive spacer 13-9 may electrically connect RDL 13-7 and RDL 13-8. That is, the electronic components 13-1 and 13-2 may be electrically connected to each other through the redistribution layers, 13-3, 13-4, 13-7 and 13-8, the electrical connections 13-31 and 13-41 and the conductive spacer 13-9.

In some embodiments of the present disclosure, the conductive spacer 13-9 includes a silicon material 13-91 and a plurality of TSVs (Through-Silicon Vias) 13-92 surrounded by the silicon material 13-91. Further, the conductive spacer 13-9 may include a redistribution layers 13-93 (RDL 13-93) disposed on its lower surface and electrically connected to the TSVs 13-92. The conductive spacer 13-9 may include a plurality of micro-bumps or micro-vias 13-94 disposed on the redistribution layer 13-93 and electrically connected to RDL 13-93. Referring to FIG. 13, top portions of the TSVs 13-92 of the conductive spacer 13-9 are electrically connected to the redistribution layers 13-8 (RDL 13-8) and the micro-bumps 13-94 of the conductive spacer 13-9 are electrically connected to RDL 13-7. Thus, the conductive spacer 13-9 is configured to establish electrical connectivity between RDL 13-7 and RDL 13-8.

Based on the above, the conductive spacer 13-9 has a function similar to that of conductive vias. Therefore, the conductive spacer 13-9 may replace the conductive vias in the embodiments illustrated in FIGS. 6, 8, 9, 10, 11, and 12A.

In addition, RDL 13-8 may include a plurality of external electrical connections 13-81 disposed on its upper surface. The external electrical connections 13-81 may be electrically connected to an external device. In some embodiments of the present disclosure, the external electrical connections 13-81 include a test/bonding pad. The external electrical connections 13-81 may be configured to transmit the signal from the electronic components 13-1 and/or 13-2 to the external device to which the external electrical connections 13-81 are connected aside from serving the function of power delivery. As shown in FIG. 13, some of the external electrical connections 13-81 may be disposed directly above the portion of the electronic component 13-1 that is they are not vertically covered by the electronic component 13-2.

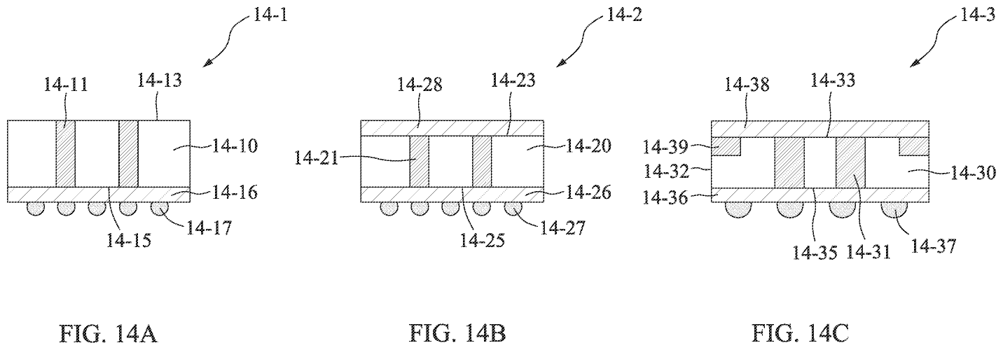

FIG. 14A is a cross-sectional view of a conductive spacer 14-1 in accordance with an embodiment of the present disclosure. As shown in FIG. 14A, the conductive spacer 14-1 may include a silicon material 14-10 and a plurality of TSVs (Through-Silicon Vias) 14-11 surrounded by the silicon material 14-10. A top portion of the TSV 14-11 may be exposed at an upper surface 14-13 of the silicon material 14-10. A redistribution layers 14-16 (RDL 14-16) may be disposed on a lower surface 14-15 of the silicon material 14-10 and electrically connected to the TSVs 14-11. Further, a plurality of micro-bumps 14-17 are disposed on RDL 14-16 and electrically connected to RDL 14-16. Thus, two electronic components may be respectively mounted to an upper side and a lower side of the conductive spacer 14-1 and may be electrically connected to each other through the conductive spacer 14-1.

FIG. 14B is a cross-sectional view of a conductive spacer 14-2 in accordance with an embodiment of the present disclosure. As shown in FIG. 14B, the conductive spacer 14-2 may include a silicon material 14-20 and a plurality of TSVs (Through-Silicon Vias) 14-21 surrounded by the silicon material 14-20. A redistribution layers 14-28 (RDL 14-28) may be disposed on an upper surface 14-23 of the silicon material 14-20 and electrically connected to the TSVs 14-21. A redistribution layers 14-26 (RDL 14-26) may be disposed on a lower surface 14-25 of the silicon material 14-20 and electrically connected to the TSVs 14-21. Further, a plurality of micro-bumps 14-27 are disposed on RDL 14-26 and electrically connected to RDL 14-26. Thus, two electronic components may be respectively mounted to an upper side and a lower side of the conductive spacer 14-2 and may be electrically connected to each other through the conductive spacer 14-2.

FIG. 14C is a cross-sectional view of a conductive spacer 14-3 in accordance with an embodiment of the present disclosure. As shown in FIG. 14C, the conductive spacer 14-3 may include a silicon material 14-30 and a plurality of TSVs (Through-Silicon Vias) 14-31 surrounded by the silicon material 14-30. A redistribution layers 14-38 (RDL 14-38) may be disposed on an upper surface 14-33 of the silicon material 14-30 and electrically connected to the TSVs 14-31. A redistribution layers 14-36 (RDL 14-36) may be disposed on a lower surface 14-35 of the silicon material 14-30 and electrically connected to the TSVs 14-31. Further, a plurality of micro-bumps 14-37 are disposed on the redistribution layer 14-36 and electrically connected to the redistribution layer 14-36. In addition, the conductive spacer 14-3 may further include an edge connector 14-39 at a lateral surface 14-32 of the silicon material 14-30 and electrically connected to RDL 14-38. Thus, two electronic components may be respectively mounted to an upper side and a lower side of the conductive spacer 14-3 and may be electrically connected to each other through the conductive spacer 14-3. Moreover, an electronic component may be mounted to a sidewall (see FIG. 14C) or a lateral wall of the conductive spacer 14-3 with an exposed edge connector 14-39 and be connected to the edge connector there. This electronic component may also be electrically connected to other electronic components mounted on the conductive spacer 14-3.

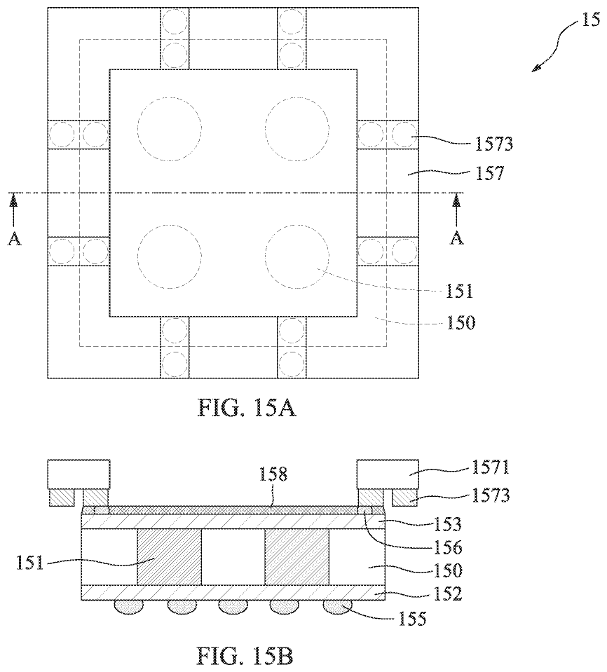

FIG. 15A is a top view of a conductive spacer 15 in accordance with an embodiment of the present disclosure. FIG. 15B is a cross-sectional view of the conductive spacer 15 in accordance with an embodiment of the present disclosure. As shown in FIGS. 15A and 15B, the conductive spacer 15 may include a silicon material 150 and a plurality of TSVs (Through-Silicon Vias) 151 surrounded by the silicon material 150. A redistribution layers 153 (RDL 153) may be disposed on an upper surface of the silicon material 150 and electrically connected to the TSVs 151. A redistribution layers 152 (RDL 152) may be disposed on a lower surface of the silicon material 150 and electrically connected to the TSVs 151. Further, a plurality of micro-bumps 155 are disposed on RDL 152 and electrically connected to RDL 152.

Further, the conductive spacer 15 may include a flexible circuit layer 157 (see FIG. 15A) which is disposed on the upper surface of the silicon material 150 and substantially extends along a periphery of the upper surface of the silicon material 150. The flexible circuit layer 157 may include a polyimide (PI)/metal layer 1571 (see FIG. 15B) and a plurality of pads 1573 disposed underneath the PI/Metal layer 1571. The pads 1573 of the flexible circuit layer may be connected to RDL 153 through conductive joints 156. In some embodiments of the present disclosure, the conductive joint 156 includes gold, solder or anisotropic conductive film (ACF). Moreover, an epoxy encapsulant 158 may be disposed on the upper surface of RDL 153 and surround the conductive joints 156. In some embodiments of the present disclosure, the flexible circuit layer 157 is mounted on the conductive spacer 15 by a thermo-compression bonding process and an encapsulation process.

Moreover, flexible circuit layer 157 may include a plurality of edge connectors 1573. Each of the edge connectors 1573 may include a plurality of conductive pads 1575 on its upper surface.

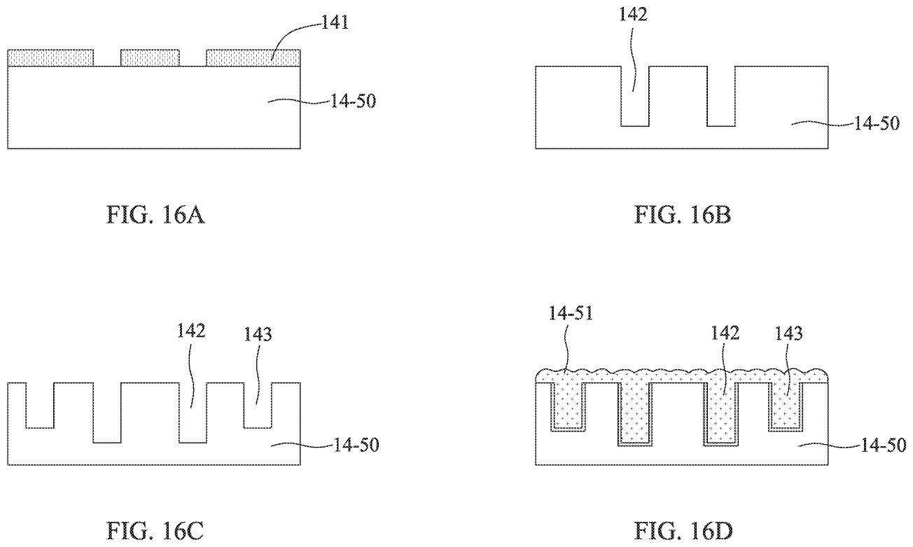

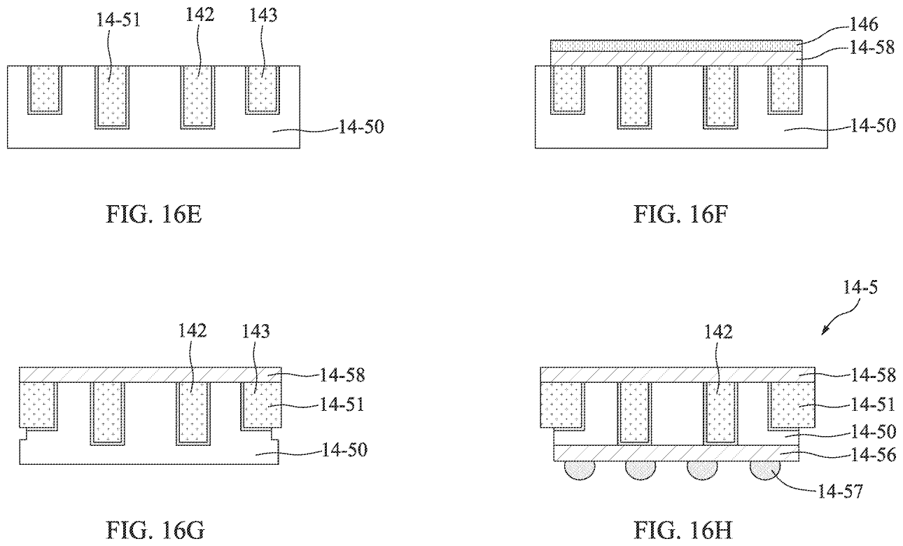

FIGS. 16A to 16H illustrate one or more stages of an example of a method for manufacturing a conductive spacer in accordance with some embodiments of the present disclosure.

Referring to FIG. 16A, a silicon substrate 14-50 is provided. Furthermore, a photoresist or mask layer 141 may be disposed on the silicon substrate 14-50.

Referring to FIG. 16B, an etching process is performed. In some embodiments of the present disclosure, the etching process includes a deep reactive-ion etching (DRIE) process. After performing the etch process, the photoresist layer 141 is removed and a plurality of holes 142 is formed on the silicon substrate 14-50.

Referring to FIG. 16C, a plurality of holes 142 and a plurality of holes 143 are formed on the silicon substrate 14-50 using the processes illustrated in FIGS. 16A and 16B

Referring to FIG. 16D, a copper material 14-51 is provided in the holes 142 and 143 formed on the silicon substrate 14-50. Before providing the copper material, an oxide passivation layer and a barrier/seed layer are formed on the silicon substrate 14-50 and the inner walls of the holes 142 and 143. In some embodiments of the present disclosure, the oxide layer and the seed layer are formed by a plasma enhanced chemical vapor deposition (PECVD) process, and a sputter deposition process, respectively. In some embodiments of the present disclosure, the copper material 14-51 is provided by a plating process.

Referring to FIG. 16E, a planarization process is performed on the upper surface of the silicon substrate 14-50 to remove the overburden copper, exposing the copper materials 14-51 in the holes 142 and 143 of the silicon substrate 14-50.

Referring to FIG. 16F, a redistribution layers 14-58 (RDL 14-58) is provided. RDL 14-58 is disposed on the upper surface of the silicon substrate 14-50 and electrically connected to the copper materials 14-51. After forming RDL 14-58, a photoresist layer is disposed on RDL 14-58.

Referring to FIG. 16G, an etching process is performed. In some embodiments of the present disclosure, the etching process includes a deep reactive-ion etching (DRIE) process. After performing the etch process, the copper materials 14-51 in the holes 143 are exposed at the lateral surface of the silicon substrate 14-50.

Referring to FIG. 16H, a redistribution layers 14-56 (RDL 14-56) and a plurality of micro-bumps 14-57 are provided. Before disposing RDL 14-56 and the micro-bumps 14-57 on the lower surface of the silicon substrate 14-50, a planarization process is performed on the lower surface of the silicon substrate 14-50 so as to expose the copper materials 14-51 in the holes 142 at the lower surface of the silicon substrate 14-50. Subsequently, RDL 14-56 and the micro-bumps 14-57 are disposed on the lower surface of the silicon substrate 14-50, both of which are electrically connected to the copper materials 14-51 filled in the holes 142.

Using the manufacturing process as shown in FIGS. 16A to 16H, the conductive spacer 14-5 is formed (see FIG. 16H).

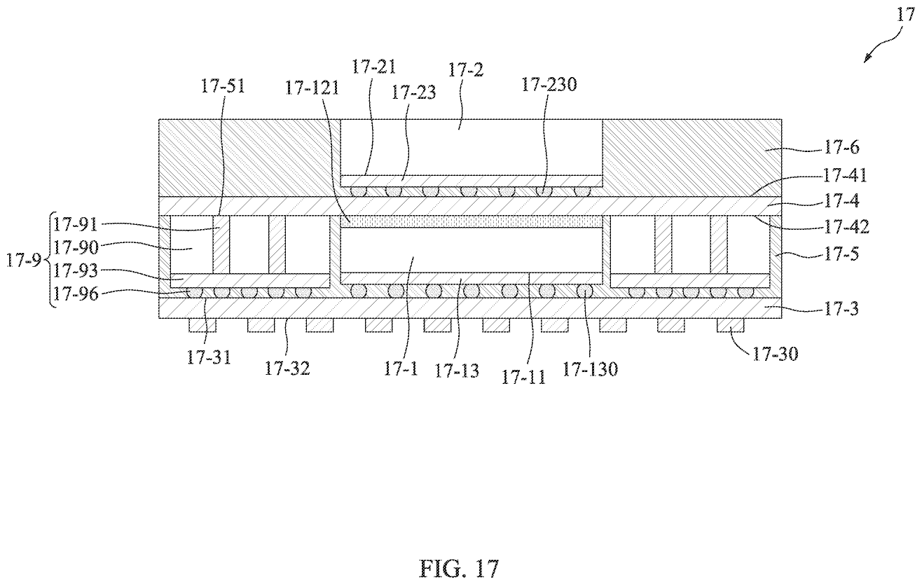

FIG. 17 is a cross-sectional view of a semiconductor device package 17 in accordance with an embodiment of the present disclosure. As shown in FIG. 17, the semiconductor device package 17 may include an electronic component 17-1 and an electronic component 17-2 disposed above the electronic component 17-1. In some embodiments of the present disclosure, the electronic component 17-1 includes a known-good die (KGD) and, the electronic component 17-2 includes a known-good die (KGD). In some embodiments of the present disclosure, the electronic component 17-1 includes a memory die, and the electronic component 17-2 includes a memory die. In some embodiments of the present disclosure, the electronic component 17-1 includes an 8 Gb memory die, and the electronic component 17-2 includes an 8 Gb memory die. In some embodiments of the present disclosure, the electronic component 17-1 includes a 4 Gb memory die, and the electronic component 17-2 includes a 4 Gb memory die.

Referring to FIG. 17, the semiconductor device package 17 may include a redistribution layers 17-3 (RDL 17-3). In some embodiments of the present disclosure, the redistribution layer 17-3 includes a known-good-redistribution layer (KGR). The electronic component 17-1 and at least one conductive spacer 17-9 may be disposed on an upper surface 17-31 of RDL 17-3. Further, a package material 17-5 may be disposed on the upper surface 17-31 of RDL 17-3 as well and configured to encapsulate the upper surface 17-31 of RDL 17-3, the electronic components 17-1 and the conductive spacer 17-9. In some embodiments of the present disclosure, the package material 17-5 includes a molding compound. Moreover, RDL 17-3 may include a plurality of external electrical connections 17-30 disposed on its lower surface 17-32. In some embodiments of the present disclosure, the external electrical connections 17-30 include a test/bonding pad

As shown in FIG. 17, the electronic component 17-1 has a surface 17-11 (e.g., a lower surface) facing the redistribution layer 17-3. The surface 17-11 may include an active surface of the electronic component 17-1. Further, a redistribution layers 17-13 (RDL 17-13) may be disposed on the surface 17-11 of the electronic component 17-1. RDL 17-13 may be electrically connected to the active surface of the electronic component 17-1. A plurality of electrical connections 17-130 may be disposed between the redistribution layers 17-13 and 17-3 and surrounded by the package material 17-5. The electrical connections 17-130 may serve to establish electrical connectivity between RDL 17-130 and RDL 17-3. That is, the electronic component 17-1 may be electrically connected to RDL 17-3 through RDL 17-13 and the electrical connections 17-130. In some embodiments of the present disclosure, the electrical connection 17-130 includes a solder bump or a copper pillar micro-bump.

Moreover, the conductive spacer 17-9 may be disposed on the upper surface 17-31 of RDL 17-3 and may be electrically connected to RDL 17-3. The conductive spacer 17-9 may include a silicon material 17-90 and a plurality TSVs (Through-Silicon Vias) 17-91 surrounded by the silicon material 17-90. Further, the conductive spacer 17-9 may include a redistribution layers 17-93 (RDL 17-93) disposed on its lower surface and electrically connected to the TSVs 17-91. The conductive spacer 17-9 may further include a plurality of micro-bumps 17-96 disposed on RDL 17-3 and electrically connected to RDL 17-3.

Referring to FIG. 17, the semiconductor device package 17 may include a redistribution layers 17-4 (RDL 17-4). In some embodiments of the present disclosure, RDL 17-4 includes a known-good-redistribution layer (KGR). RDL 17-4 may be disposed on an upper surface 17-51 of the package material 17-5. The electronic component 17-1 may be attached to a lower surface 17-42 of the redistribution layer 17-4 through an adhesive 17-121. An upper surface of the conductive spacer 17-9 may abut against the lower surface 17-42 of the redistribution layer 17-4. Since the TSVs 17-91 may be exposed at the upper surface of the conductive spacer 17-9, the conductive spacer 17-9 may be electrically connected to the redistribution layer 17-4.

The electronic component 17-2 may be disposed on an upper surface 17-41 of RDL 17-4. Furthermore, a package material 17-6 may be disposed on the upper surface 17-41 of RDL 17-4 as well and configured to encapsulate the upper surface 17-41 of RDL 17-4 and the electronic component 17-2. In some embodiments of the present disclosure, the package material 17-6 includes a molding compound.

The electronic component 17-2 has a surface 17-21 (e.g., a lower surface) facing RDL 17-4. The surface 17-21 may include an active surface of the electronic component 17-2. Further, a redistribution layers 17-23 (RDL 17-23) may be disposed on the surface 17-21 of the electronic component 17-2. RDL 17-23 may be electrically connected to the active surface of the electronic component 17-2. A plurality of electrical connections 17-230 may be disposed between the redistribution layers 17-23 and 17-4 and surrounded by the package material 17-6. The electrical connections 17-230 may serve to establish electrical connectivity between RDL 17-230 and RDL 17-4. That is, the electronic component 17-2 may be electrically connected to RDL 17-4 through RDL 17-23 and the electrical connections 17-230. In some embodiments of the present disclosure, the electrical connection 17-230 includes a solder bump or a copper pillar micro-bump.

In some embodiments of the present disclosure, the signaling and power delivery functions of the electronic component 17-2 may be connected to the electronic component 17-1 internally through RDL 17-3, the conductive spacer 17-9 and RDL 17-4. In some embodiments of the present disclosure, one set of the signaling and power delivery functions is connected to the bonding pads of an external electronic component such as a SoC.

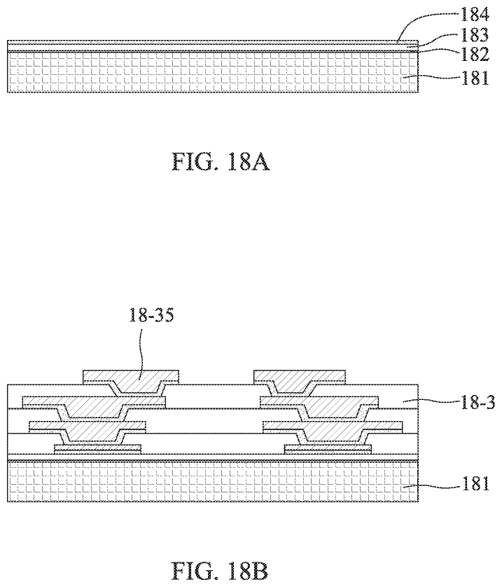

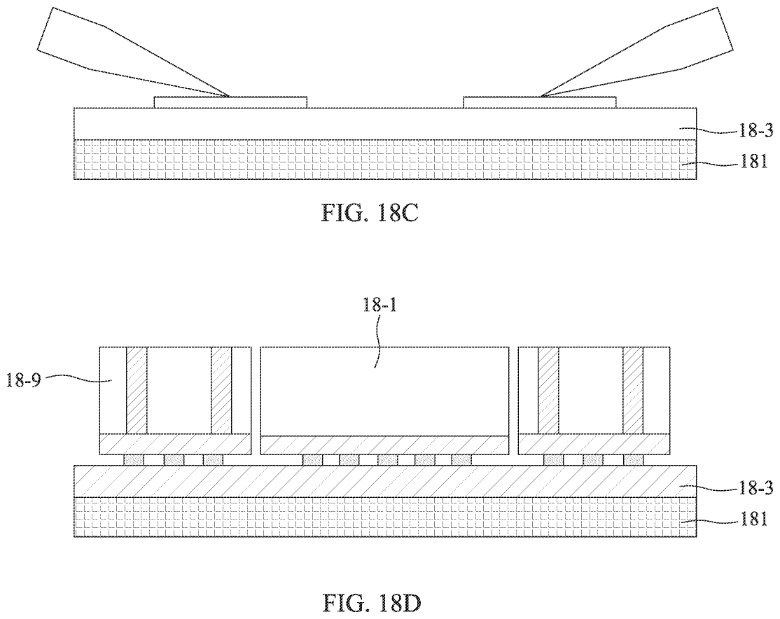

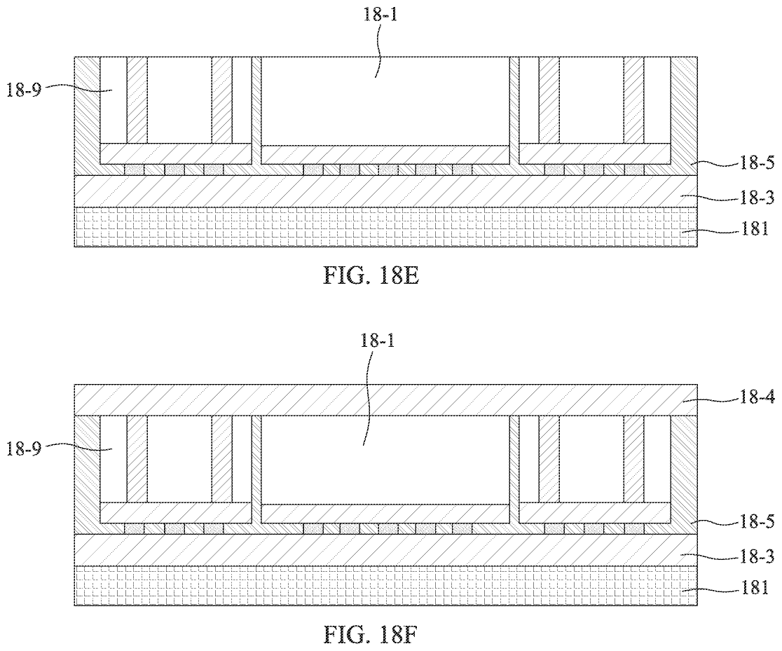

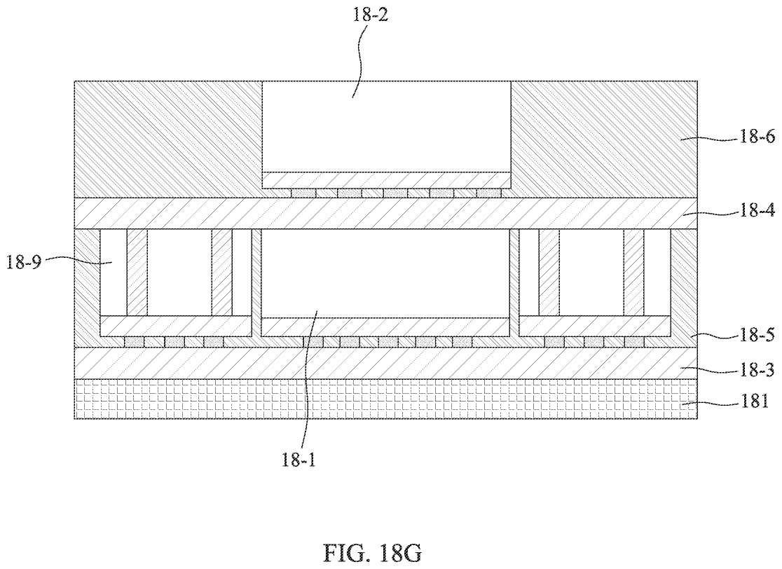

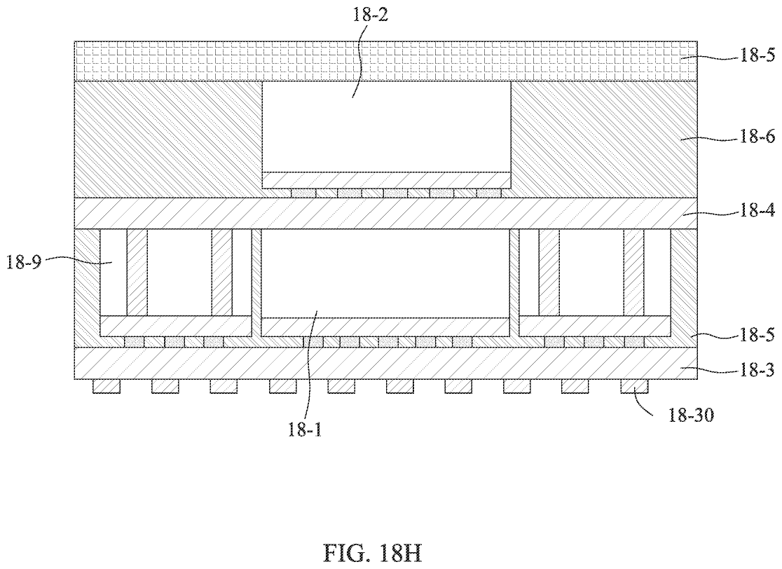

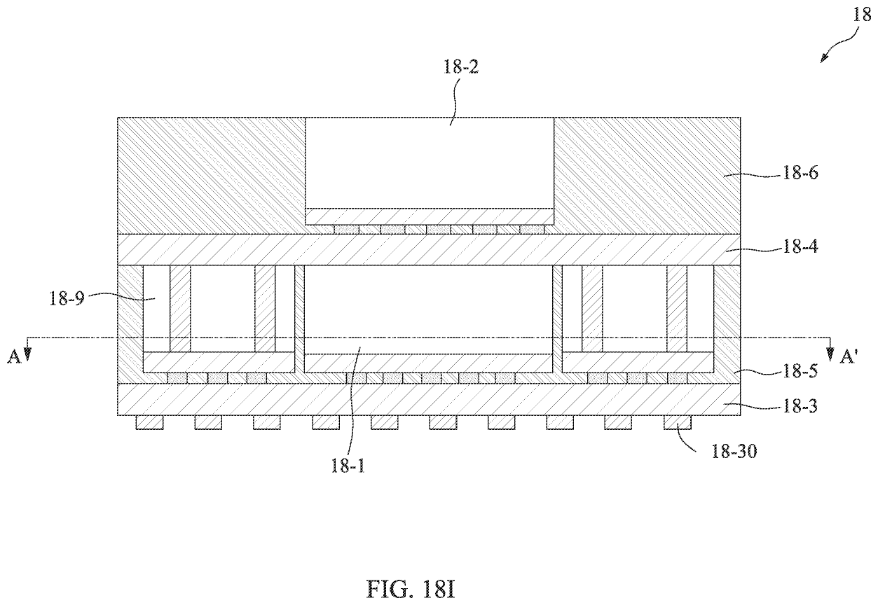

FIGS. 18A to 18I illustrate one or more stages of an example of a method for manufacturing a semiconductor device package in accordance with some embodiments of the present disclosure.

Referring to FIG. 18A, a first glass carrier 181 is provided. Further, a release layer 182, a dielectric layer 183 and a seed layer 184 may be disposed on the upper surface of the first glass carrier 181.

Referring to FIG. 18B, a redistribution layers 18-3 (RDL 18-3) is formed on the first glass carrier 181, wherein RDL 18-3 includes an interconnection 18-35.

Referring to FIG. 18C, a testing process is performed on RDL 18-3 so as to ensure that RDL 18-3 is a Known-Good-Redistribution layer (KGR).

Referring to FIG. 18D, an electronic component 18-1 and at least one conductive spacer 18-9 are provided. The electronic component 18-1 and the conductive spacer 18-9 are disposed on RDL 18-3 and electrically connected to RDL 18-3. The electronic component 18-1 and RDL 18-3 and at least one conductive spacer 18-9 may be formed as a sub-assembly. In some embodiments of the present disclosure, a testing process is performed on the sub-assembly so as to ensure that the sub-assembly is known good.

Referring to FIG. 18E, a package material 18-5 is provided. The package material 18-5 is disposed on RDL 18-3 and encapsulates the upper surface of RDL 18-3, the electronic component 18-1 and the conductive spacer 18-9. After forming the package material 18-5 on the redistribution layer, a planarization process is performed on the upper surface of the package material 18-5.

Referring to FIG. 18F, a redistribution layers 18-4 (RDL 18-4) is provided. The redistribution layer 18-4 (RDL 18-4) is disposed on the package material 18-5 and electrically connected to the conductive spacer 18-9. Following this, a testing process is performed on RDL 18-4 to ensure it is a Known-Good-Redistribution layer (KGR). Alternatively, based on an aforementioned process, RDL 18-4 is separately disposed on a temporary glass carrier containing a release layer and is tested as a Known-Good-Redistribution layer (KGR) prior to disposing RDL 18-4 on the package material 18-5.

Referring to FIG. 18G, an electronic component 18-2 and a package material 18-6 are provided. The electronic component 18-2 is disposed on RDL 18-4 and electrically connected to RDL 18-4. The package material 18-6 is disposed on RDL 18-4 and encapsulates the upper surface of RDL 18-4 and the electronic component 18-2. After forming the package material 18-6 on RDL 18-4, a polarization process is performed on the upper surface of the package material 18-6. In addition, the electronic components 18-1 and 18-2, the redistribution layers 18-3 and 18-4 and at least one conductive spacer 18-9 may be formed as a sub-assembly. In some embodiments of the present disclosure, a testing process is performed on the sub-assembly so as to ensure that the sub-assembly is known good.

Referring to FIG. 18H, a plurality of external electrical connections 18-30 are provided. Before disposing the external electrical connections 18-30 on the lower surface of RDL 18-3, a second glass carrier 18-5 is provided on the upper surface of the package material 18-6 and then the first glass carrier is removed from RDL 18-3 and. Following the provision of the second glass carrier 18-5 on the upper surface of the package material 18-6, a laser drilling process is performed on RDL 18-3 such that metal pads are exposed at the lower surface of 18-3. Then, the external electrical connections 18-30 are disposed on the lower surface of RDL 18-3 on the metal pads and electrically connected to RDL 18-3.

Referring to FIG. 18H, the second glass carrier 185 is removed and the resultant packages are tested and singulated. After the manufacturing process as shown in FIGS. 18A to 18I the semiconductor device package 18 is formed. In some embodiments of the present disclosure, the semiconductor device package 18 is the same as, or similar to, the semiconductor device package 17 shown in FIG. 17.

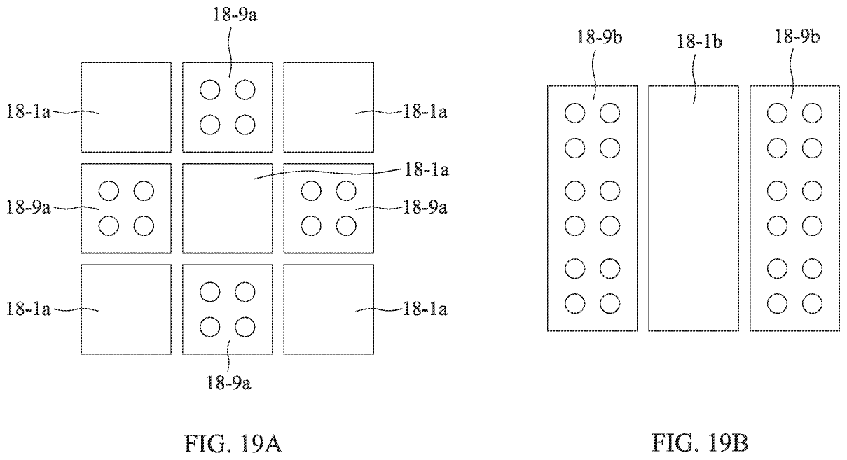

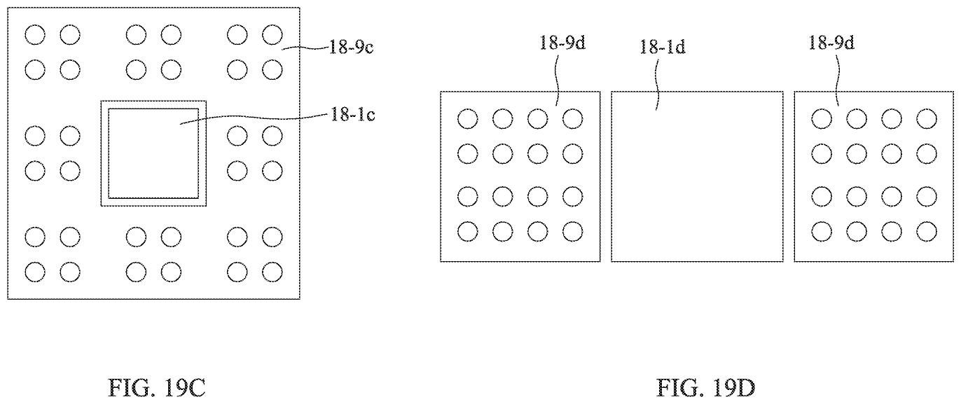

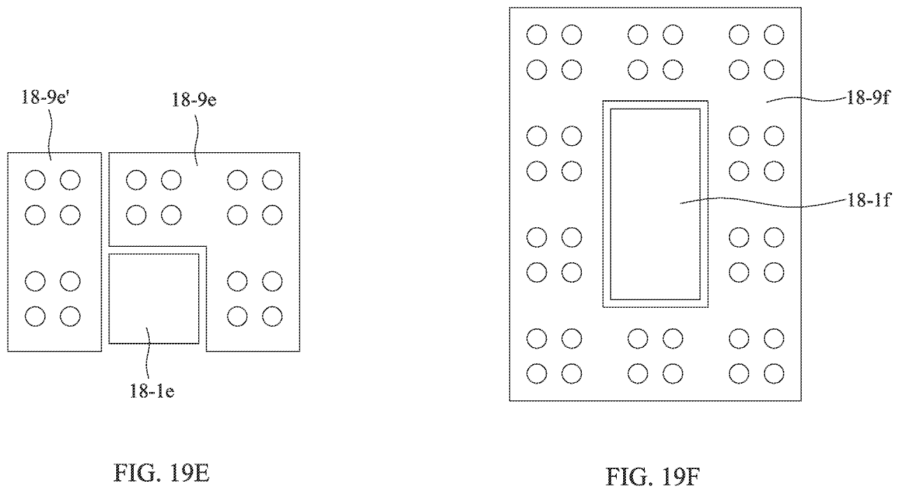

FIG. 19A is a cross-sectional view along line A′-A′ of FIG. 18I, which shows an embodiment of an arrangement of the electronic component(s) 18-1 and the conductive spacer(s) 18-9. Referring to FIG. 19A, five electronic components 18-1a and four conductive spacers 18-9a are arranged in a matrix pattern relative to each other.

FIG. 19B is a cross-sectional view along line A′-A′ of FIG. 18I, which shows another embodiment of an arrangement of the electronic component(s) 18-1 and the conductive spacer(s) 18-9. Referring to FIG. 19B, both the electronic component 18-1b and the conductive spacers 18-9b are rectangular, and they are arranged side-by-side and aligned with each other. The electronic component 18-1b is disposed between the conductive spacers 18-9b.

FIG. 19C is a cross-sectional view along line A′-A′ of FIG. 18I, which shows another embodiment of an arrangement of the electronic component(s) 18-1 and the conductive spacer 18-9. Referring to FIG. 19C, the electronic component 18-1c is substantially square and the conductive spacer 18-9c is substantially square-ring-shaped. The conductive spacer 18-9c substantially surrounds the electronic component 18-1c.

FIG. 19D is a cross-sectional view along line A′-A′ of FIG. 18I, which shows another embodiment of an arrangement of the electronic component(s) 18-1 and the conductive spacer(s) 18-9. Referring to FIG. 19D, both the electronic component 18-1d and the conductive spacers 18-9d are substantially square, and they are arranged side-by-side and aligned with each other. The electronic component 18-1d is disposed between the conductive spacers 18-9d.

FIG. 19E is a cross-sectional view along line A′-A′ of FIG. 18I, which shows another embodiment of an arrangement of the electronic component(s) 18-1 and the conductive spacer(s) 18-9. Referring to FIG. 19E, the electronic component 18-1d is substantially square and conductive spacers 18-9e and 18-9e′ are different shapes with one being substantially L-shaped, while the other substantially square. the electronic component 18-1e is disposed between the conductive spacers 18-9c and 18-9e′ as shown in FIG. 19E.

FIG. 19F is a cross-sectional view along line A′-A′ of FIG. 18I, which shows another embodiment of an arrangement of the electronic component(s) 18-1 and the conductive spacer 18-9. Referring to FIG. 19F, the electronic component 18-If is substantially rectangular and the conductive spacer 18-9f is substantially rectangular-ring shaped. The conductive spacer 18-9f substantially surrounds the electronic component 18-1f.

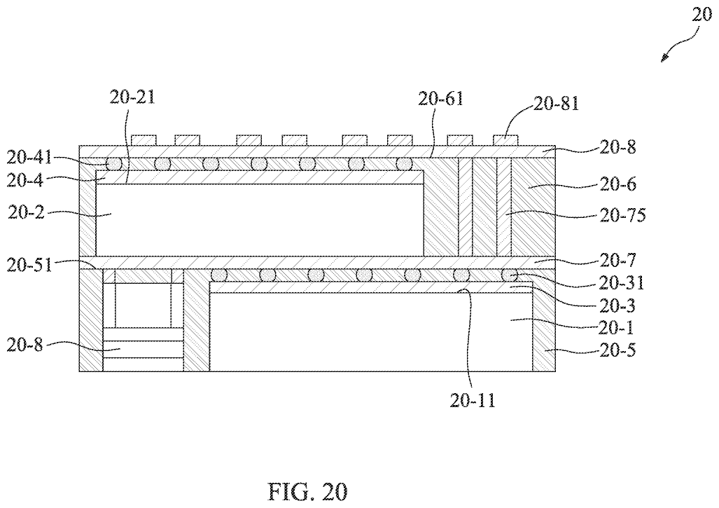

FIG. 20 is a cross-sectional view of a semiconductor device package 20 in accordance with an embodiment of the present disclosure. As shown in FIG. 20, the semiconductor device package 20 may include an electronic component 20-1 and an electronic component 20-2 disposed above the electronic component 20-1. In some embodiments of the present disclosure, the electronic component 20-1 includes a known-good die (KGD) and, the electronic component 20-2 includes a known-good die (KGD). In some embodiments of the present disclosure, the electronic component 20-1 includes a memory die, and the electronic component 20-2 includes a memory die. In some embodiments of the present disclosure, the electronic component 20-1 includes an 8 Gb memory die, and the electronic component 20-2 includes an 8 Gb memory die. That is, a size of the electronic component 20-1 may be substantially identical to a size of the electronic component 20-2. Referring to FIG. 20, a cross-sectional width of the electronic component 20-1 is substantially identical to a cross-sectional width of the electronic component 20-2, and the electronic components 20-1 and 20-2 are stacked vertically but are not aligned directly one above the other; instead, there is a lateral offset. The electronic component 20-2 is positioned slightly to the left relative to the electronic component 20-1. Thus, the electronic component 20-1 has at least one portion that is not vertically covered by the electronic component 20-2.

As shown in FIG. 20, the electronic component 20-1 has a surface 20-11 (e.g., an upper surface) facing the electronic component 20-2. The surface 20-11 may include an active surface of the electronic component 20-1. Further, a redistribution layers 20-3 (RDL 20-3) may be disposed on the surface 20-11 of the electronic component 20-1. RDL 20-3 may be electrically connected to the active surface of the electronic component 20-1. The semiconductor device package 20 may include a capacitor (or an active device or another type of passive device) 20-8 adjacent to the electronic component 20-1. In some embodiments of the present disclosure, the capacitor 20-8 includes a MLCC (Multi-Layer Ceramic Capacitor). Furthermore, the semiconductor device package 20 may include a package material 20-5 encapsulating the electronic component 20-1 and the capacitor 20-8. In some embodiments of the present disclosure, the package material 20-5 includes a molding compound. The package material 20-5 may cover RDL 20-3 as well. Moreover, a redistribution layers 20-7 (RDL 20-7) may be disposed on a surface 20-51 (e.g., an upper surface) of the package material 20-5. In some embodiments of the present disclosure, RDL 20-7 includes a known-good-redistribution layer (KGR). A plurality of electrical connections 20-31 may be disposed between the redistribution layers 20-3 and 20-7 and surrounded by the package material 20-5. The electrical connections 20-31 may serve to establish electrical connectivity between RDL 20-3 and RDL 20-7. That is, the electronic component 20-1 may be electrically connected to RDL 20-7 through RDL 20-3 and the electrical connections 20-31. In some embodiments of the present disclosure, the electrical connection 20-31 includes a solder bump or a copper pillar micro-bump. In some embodiments of the present disclosure, one of the solder bumps or micro-bumps includes a dummy bump. In addition, the capacitor 20-8 may be electrically connected to RDL 20-7.

Moreover, the electronic component 20-2 is disposed on RDL 20-7 and has a surface 20-21 (e.g., an upper surface) facing away from the electronic component 20-1. The surface 20-21 may include an active surface of the electronic component 20-2. Further, a redistribution layers 20-4 (RDL 20-4) may be disposed on the surface 20-21 of the electronic component 20-2. RDL 20-4 may be electrically connected to the active surface of the electronic component 20-2. Further, the semiconductor device package 20 may include a package material 20-6 disposed on RDL 20-7 and encapsulating the electronic component 20-2. In some embodiments of the present disclosure, the package material 20-6 includes a molding compound. The package material 20-6 may cover RDL 20-4 and RDL 20-7 as well. Moreover, a redistribution layers 20-8 (RDL 20-8) may be disposed on a surface 20-61 (e.g., an upper surface) of the package material 20-6. In some embodiments of the present disclosure, RDL 20-8 includes a known-good-redistribution layer (KGR). A plurality of electrical connections 20-41 may be disposed between the redistribution layers 20-4 and 20-8 and surrounded by the package material 20-6. The electrical connections 20-41 may serve to establish electrical connectivity between RDL 20-4 and RDL 20-8. That is, the electronic component 20-2 may be electrically connected to RDL 20-8 through RDL 20-4 and the electrical connections 20-41. In some embodiments of the present disclosure, the electrical connection 20-41 includes a solder bump or a copper pillar micro-bump. In some embodiments of the present disclosure, one of the solder bumps or micro-bumps includes a dummy bump.

Given the above, the electronic components 20-1 and 20-2 may be held together by the package materials 20-5 and 20-6.

Referring to FIG. 20, the semiconductor device package 20 may include a plurality of conductive vias 20-75. The conductive vias 20-75 may pass through the package material 20-6 and be connected to the redistribution layers 20-7 and 20-8. The conductive vias 20-75 may serve to establish electrical connectivity between RDL 20-7 and RDL 20-8. That is, the electronic components 20-1 and 20-2 may be electrically connected to each other through the redistribution layers, 20-3, 20-4, 20-7 and 20-8, the electrical connections 20-31 and 20-41 and the conductive vias 20-75. In some embodiments of the present disclosure, the conductive via 20-75 includes a TMV (Through Mold Via) or a copper pillar.

In addition, RDL 20-8 may include a plurality of external electrical connections 20-81 disposed on its upper surface. The external electrical connections 20-81 may be electrically connected to an external device. In some embodiments of the present disclosure, the external electrical connection 20-81 includes a test/bonding pad The external electrical connections 20-81 may be configured to transmit the signal from the electronic components 20-1 and/or 20-2 to the external device to which the external electrical connections 20-81 are connected aside from serving the function of power delivery. As shown in FIG. 20, some of the external electrical connections 20-81 may be disposed directly above the portion of the electronic component 20-1 that is they are not vertically covered by the electronic component 20-2.

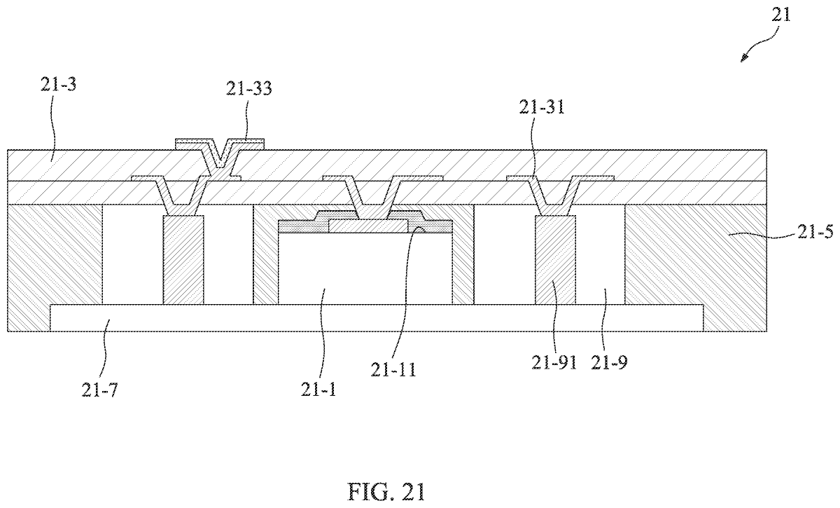

FIG. 21 is a cross-sectional view of a semiconductor device package 21 in accordance with an embodiment of the present disclosure. As shown in FIG. 21, the semiconductor device package 21 may include an electronic component 21-1, a redistribution layer 21-3 (RDL 21-3), a package material 21-5, an inductor 21-7 and at least one conductive spacer 21-9. Referring to FIG. 21, the electronic component 21-1 and the conductive spacers 21-9 are arranged on the inductor 21-7. The electronic component 21-1 has an active surface 21-11 facing away from the inductor 21-7. The conductive spacer 21-9 includes a TSV (Through-Silicon Via) 21-91. The package material 21-5 encapsulates the electronic component 21-1, the inductor 21-7 and the conductive spacers 21-9. In some embodiments of the present disclosure, the package material 21-5 includes a molding compound. Further, RDL 21-3 with interconnections 21-31 may be disposed on an upper surface of the package material 21-5. The interconnections 21-31 of RDL 21-3 may be electrically connected to the active surface 21-11 of the electronic component 21-1 and/or the TSVs 21-91 of the conductive spacer 21-9. In addition, the interconnection 21-31 may include a conductive pad 21-35 exposed at an upper surface of RDL 21-3.

FIG. 22 is a cross-sectional view of a semiconductor device package 22 in accordance with an embodiment of the present disclosure. As shown in FIG. 22, the semiconductor device package 22 may include an electronic component 22-1 and an electronic component 22-2 disposed above the electronic component 22-1. In some embodiments of the present disclosure, the electronic component 22-1 includes a known-good die (KGD) and, the electronic component 22-2 includes a known-good die (KGD). In some embodiments of the present disclosure, the electronic component 22-1 includes a memory die, and the electronic component 22-2 includes a memory die. In some embodiments of the present disclosure, the electronic component 22-1 includes an 8 Gb memory die, and the electronic component 22-2 includes an 8 Gb memory die. In some embodiments of the present disclosure, the electronic component 22-1 includes a 4 Gb memory die, and the electronic component 22-2 includes a 4 Gb memory die.

Referring to FIG. 22, the semiconductor device package 22 may include a redistribution layers 22-3 (RDL 22-3). In some embodiments of the present disclosure, the redistribution layer 22-3 includes a known-good-redistribution layer (KGR). The electronic component 22-1 may be disposed on an upper surface 22-31 of RDL 22-3. Furthermore, a package material 22-5 may be disposed on the upper surface 22-31 of RDL 22-3 as well and configured to encapsulate the upper surface 22-31 of RDL 22-3 and the electronic components 22-1. In some embodiments of the present disclosure, the package material 22-5 includes a molding compound. Moreover, RDL 22-3 may include a plurality of external electrical connections 22-30 disposed on its lower surface 22-32. In some embodiments of the present disclosure, the external electrical connection 23-30 includes a test/bonding pad

As shown in FIG. 22, the electronic component 22-1 has a surface 22-11 (e.g., a lower surface) facing RDL 22-3. The surface 22-11 may include an active surface of the electronic component 22-1. Further, a redistribution layers 22-13 (RDL 22-13) may be disposed on the surface 22-11 of the electronic component 22-1. RDL 22-13 may be electrically connected to the active surface of the electronic component 22-1. A plurality of electrical connections 22-130 may be disposed between the redistribution layers 22-13 and 22-3 and surrounded by the package material 22-5. The electrical connections 22-130 may serve to establish electrical connectivity between RDL 22-13 and RDL 22-3. That is, the electronic component 22-1 may be electrically connected to RDL 22-3 through RDL 22-13 and the electrical connections 22-130. In some embodiments of the present disclosure, the electrical connection 22-130 includes a solder bump or a copper pillar micro-bump.

Moreover, the semiconductor device package 22 may include a plurality of conductive vias 22-55 disposed on the upper surface 22-31 of RDL 22-3 and surrounded by the package material 22-5. The conductive vias 22-55 may be electrically connected to RDL 22-3. In some embodiments of the present disclosure, the conductive via 22-55 includes a TMV (Through Mold Via).

Referring to FIG. 22, the semiconductor device package 22 may include a redistribution layers 22-4 (RDL 22-4). In some embodiments of the present disclosure, RDL 22-4 includes a known-good-redistribution layer (KGR). RDL 22-4 may be disposed on an upper surface 22-51 of the package material 22-5. The electronic component 22-1 may be attached to a lower surface 22-42 of RDL 22-4 through an adhesive 22-121. An upper surface of the conductive vias 22-55 may abut against the lower surface 22-42 of RDL 22-4 and be electrically connected to RDL 22-4.

The electronic component 22-2 may be disposed on an upper surface 22-41 of RDL 22-4. Further, a package material 22-6 may be disposed on the upper surface 22-41 of RDL 22-4 as well and configured to encapsulate the upper surface 22-41 of RDL 22-4 and the electronic components 22-2. In some embodiments of the present disclosure, the package material 22-6 includes a molding compound.

The electronic component 22-2 has a surface 22-21 (e.g., a lower surface) facing RDL 22-4. The surface 22-21 may include an active surface of the electronic component 22-2. Furthermore, a redistribution layer 22-23 (RDL 22-23) may be disposed on the surface 22-21 of the electronic component 22-2. RDL 22-23 may be electrically connected to the active surface of the electronic component 22-2. A plurality of electrical connections 22-230 may be disposed between the redistribution layers 22-23 and 22-4 and surrounded by the package material 22-6. The electrical connections 22-230 may serve to establish electrical connectivity between RDL 22-230 and RDL 22-4. That is, the electronic component 22-2 may be electrically connected to RDL 22-4 through RDL 22-23 and the electrical connections 22-230. In some embodiments of the present disclosure, the electrical connection 22-230 includes a solder bump or a copper pillar micro-bump.

Given the above, the electronic components 22-1 and 22-2 may be electrically connected to each other through the redistribution layers 22-3 and 22-4 and the conductive vias 22-55.

The signaling and power delivery functions of the electronic component 22-1 may be connected to electronic component 22-2 internally through RDL 22-3, conductive vias 22-55 and RDL 22-4. One set of the signaling and power delivery functions may be connected to the bonding pads of an external device such as a SoC. The electronic component 22-1 may be a 4 Gb DRAM or an 8 Gb DRAM, while the electronic component 22-2 may be a 4 Gb DRAM or an 8 Gb DRAM. The dual-die combinations (electronic component 22-1+electronic component 22-2) include 4 Gb+4 Gb, 4 Gb+8 Gb, 8 Gb+4 Gb, 8 Gb+8 Gb and combinations of other memory-capacity DRAMs.

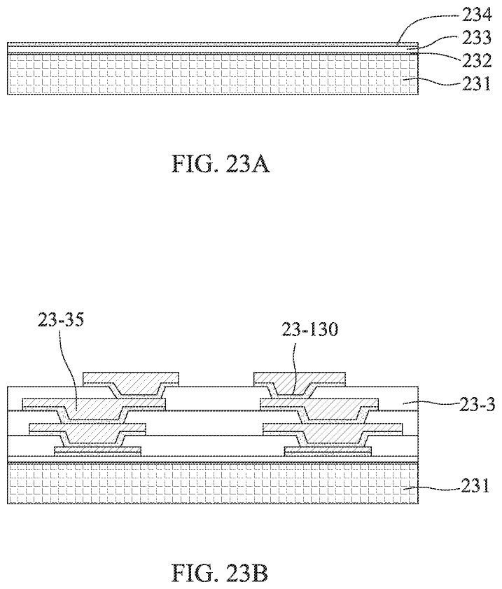

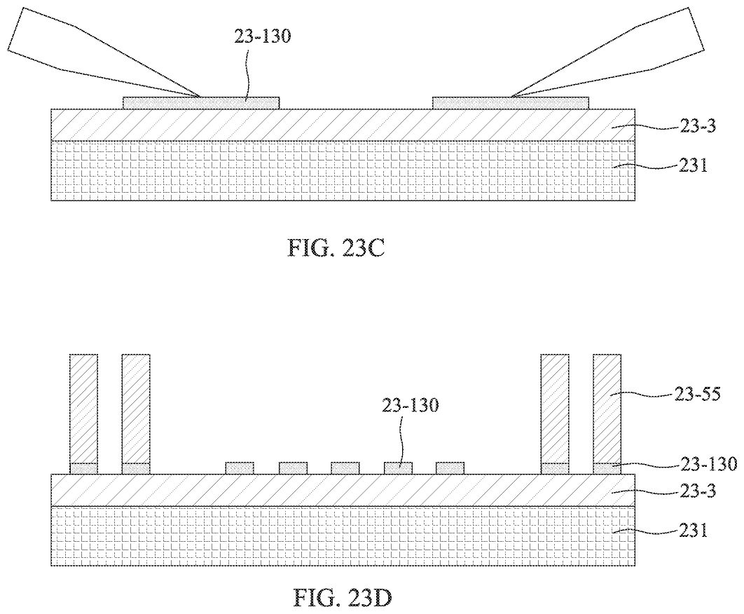

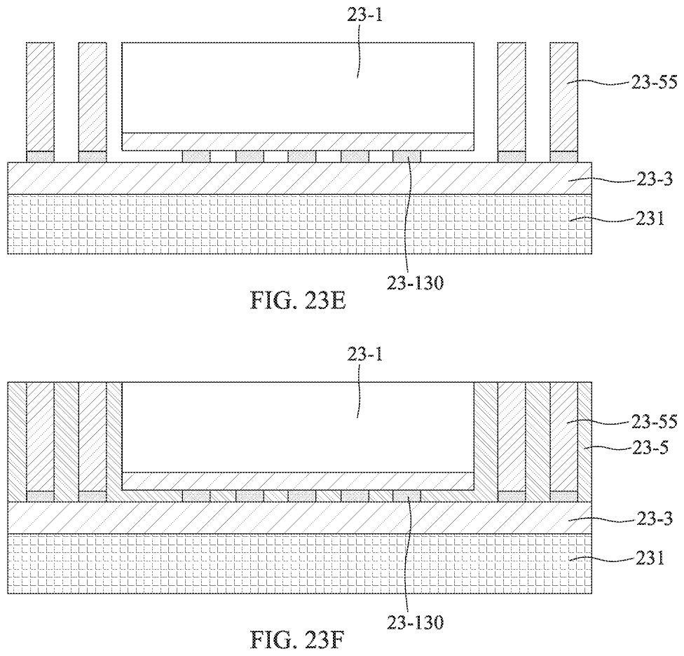

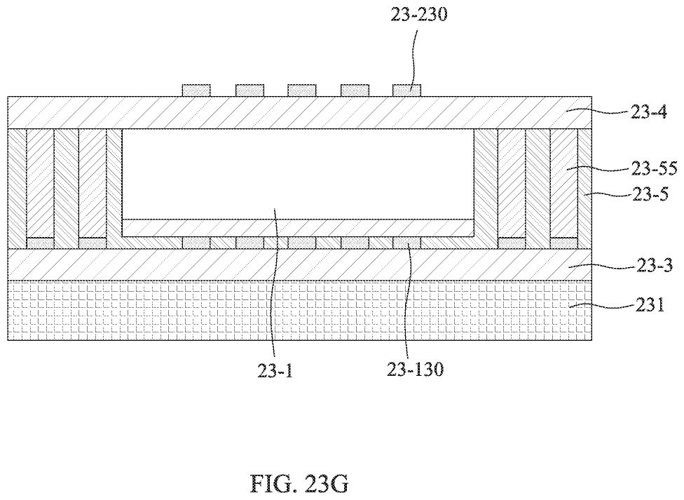

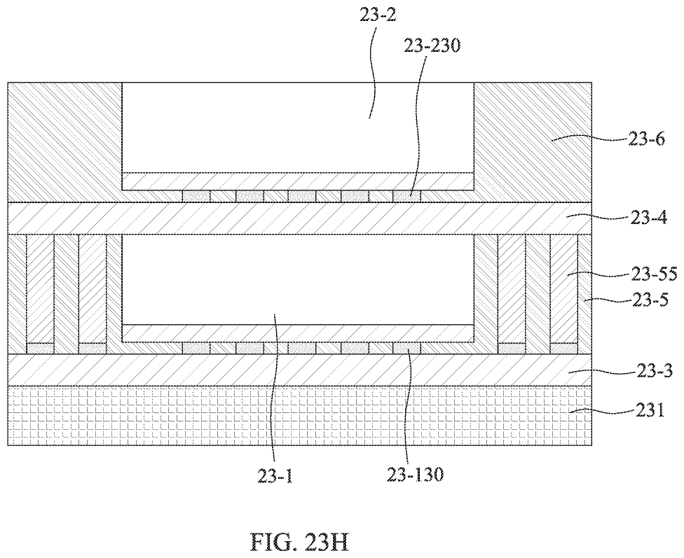

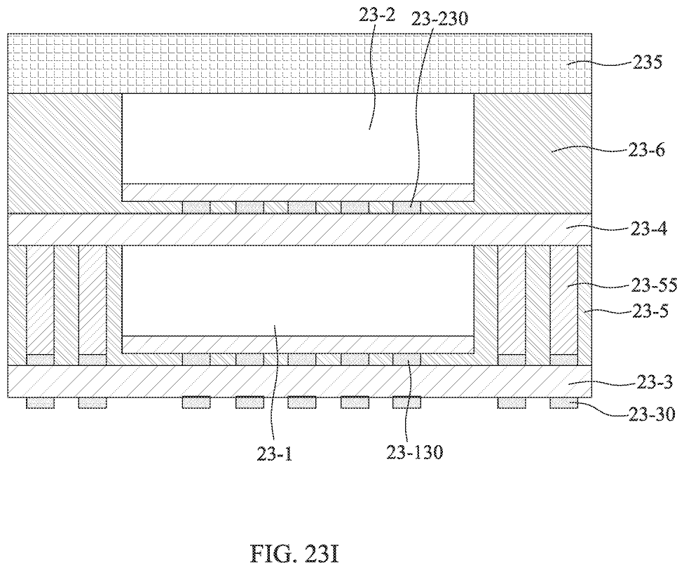

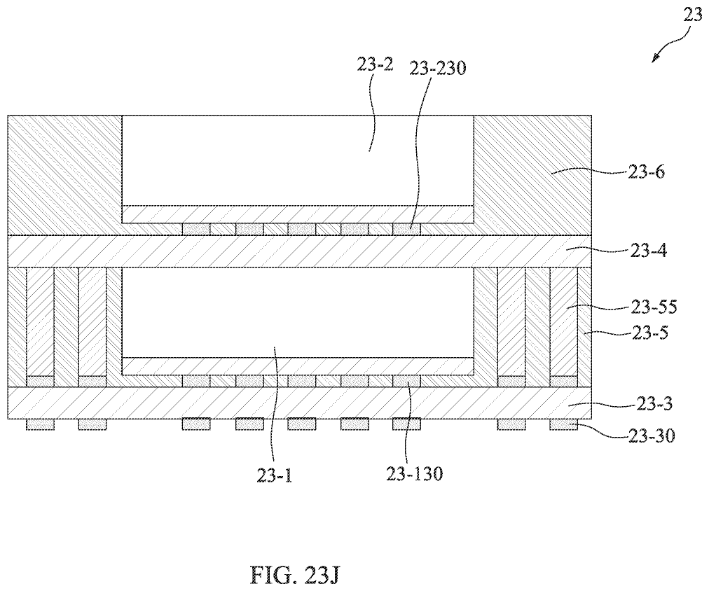

FIGS. 23A to 23J illustrate one or more stages of an example of a method for manufacturing a semiconductor device package in accordance with some embodiments of the present disclosure.

Referring to FIG. 23A, a first glass carrier 231 is provided. Further, a release layer 232, a dielectric layer 233 and a seed layer 234 may be disposed on the upper surface of the first glass carrier 231.

Referring to FIG. 23B, a redistribution layers 23-3 (RDL 23-3 is formed on the first glass carrier 231, wherein RDL 23-3 includes an interconnection 23-35. Moreover, the interconnection 23-35 includes conductive pads 23-130 exposed at an upper surface of RDL 23-3.

Referring to FIG. 23C, a testing process is performed on RDL 23-3 so as to ensure that RDL 23-3 is a Known-Good-Redistribution layer (KGR). The test process is implemented by using a probe to contact the conductive pads 23-130.

Referring to FIG. 23D, a plurality of copper pillars 23-55 is provided. The copper pillars 23-55 are disposed on the conductive pads 23-130 and electrically connected to RDL 23-3 through the conductive pads 23-130. Alternatively, copper pillars 23-55 can be formed following the formation of RDL 23-3 but before its KGR testing.

Referring to FIG. 23E, an electronic component 23-1 is provided. The electronic component 23-1 is disposed on the conductive pads 23-130 and electrically connected to RDL 23-3 through the conductive pads 23-130. In some embodiments of the present disclosure, an underfill (or a NCP) is provided between the electronic component 23-1 and RDL 23-3 and configured to surround the conductive pads 23-130. Alternatively, encapsulation of the conductive pads 23-130 can be done using part of the molding process (see FIG. 23F) using, for instance, a molded underfill. Before the electronic component 23-1 is disposed on RDL 23-3, it undergoes testing to ensure that the electronic component 23-1 is a Known-Good Die (KGD). The electronic component 23-1, RDL 23-3 and the copper pillars 23-55 may be formed as a sub-assembly. In some embodiments of the present disclosure, a testing process is performed on the sub-assembly so as to ensure that the sub-assembly is known good.

Referring to FIG. 23F, a molding compound 23-5 is provided. The molding component 23-5 is disposed on RDL 23-3 and encapsulates the electronic component 23-1, the copper pillars 23-55 and the upper surface of RDL 23-3. After disposing the molding compound, a planarization or a grinding process may be performed on an upper surface of the molding compound 23-5.

Referring to FIG. 23G, a redistribution layers 23-4 (RDL 23-4) is provided. RDL 23-4 is disposed on the package material 23-5 and electrically connected to the copper pillars 23-55. RDL 23-4 includes a plurality of conductive pads 23-230 on its upper surface. Before RDL 23-4 is disposed on the package material 23-5, it undergoes testing to ensure that RDL 23-4 is a Known-Good-Redistribution layer (KGR). The electronic component 23-1, the redistribution layers 23-3 and 23-4 and the copper pillars 23-55 may be formed as a sub-assembly. In some embodiments of the present disclosure, a testing process is performed on the sub-assembly so as to ensure that the sub-assembly is known good.

Referring to FIG. 23H, a known-good electronic component 23-2 and a package material 23-6 are provided. The electronic component 23-2 is disposed on the conductive pads 23-230 of RDL 23-4 and electrically connected to RDL 23-4. The package material 23-6 is disposed on RDL 23-4 and encapsulates the upper surface of RDL 23-4 and the electronic component 23-2. After forming the package material 23-6 on RDL 23-4, a planarization or a grinding process is performed on the upper surface of the package material 23-6.

Referring to FIG. 23I, a plurality of external electrical connections 23-30 are provided. Before disposing the external electrical connections 23-30 on the lower surface of RDL 23-3, a second glass carrier 235 is provided on the upper surface of the package material 23-6 and then the first glass carrier 231 is removed from RDL 23-3. After the second glass carrier 235 is provided on the upper surface of the package material 23-6, a laser drilling process is performed on RDL 23-3 so that metal pads (such as the interconnection 23-35 as shown in FIG. 23B) are exposed at the lower surface of RDL 23-3. Then the external electrical connections 23-130 are disposed on the metal pads of RDL 23-3.

Referring to FIG. 23J, the second glass carrier 235 is removed. Using the manufacturing process shown in FIGS. 23A to 23J, the semiconductor device package 23 is formed as shown in FIG. 23J. In some embodiments of the present disclosure, the semiconductor device package 22 is the same as, or similar to, the semiconductor device package 22 shown in FIG. 22.

FIG. 24 is a cross-sectional view of a semiconductor device package 24 in accordance with an embodiment of the present disclosure. As shown in FIG. 24, the semiconductor device package 24 may include an electronic component 24-1 and an electronic component 24-2 disposed above the electronic component 24-1. In some embodiments of the present disclosure, the electronic component 24-1 includes a known-good die (KGD) and, the electronic component 24-2 includes a known-good die (KGD). In some embodiments of the present disclosure, the electronic component 24-1 includes a memory die, and the electronic component 24-2 includes a memory die. In some embodiments of the present disclosure, the electronic component 24-1 includes an 8 Gb memory die, and the electronic component 24-2 includes an 8 Gb memory die. In some embodiments of the present disclosure, the electronic component 24-1 includes a 4 Gb memory die, and the electronic component 24-2 includes a 4 Gb memory die.

Referring to FIG. 24, the semiconductor device package 24 may include a redistribution layers 24-3 (RDL 24-3). In some embodiments of the present disclosure, RDL 24-3 includes a known-good-redistribution layer (KGR). The electronic component 24-1 may be disposed on an upper surface 24-31 of RDL 24-3. Further, a package material 24-5 may be disposed on the upper surface 24-31 of RDL 24-3 as well and configured to encapsulate the upper surface 24-31 of RDL 24-3 and the electronic components 24-1. In some embodiments of the present disclosure, the package material 24-5 includes a molding compound. Moreover, RDL 24-3 may include a plurality of external electrical connections 24-30 disposed on its lower surface 24-32. In some embodiments of the present disclosure, the external electrical connection 24-30 includes a test/bonding pad.

As shown in FIG. 24, the electronic component 24-1 has a surface 24-11 (e.g., a lower surface) facing RDL 24-3. The surface 24-11 may include an active surface of the electronic component 24-1. Further, a redistribution layer 24-13 (RDL 24-13) may be disposed on the surface 24-11 of the electronic component 24-1. RDL 24-13 may be electrically connected to the active surface of the electronic component 24-1. A plurality of electrical connections 24-130 may be disposed between the redistribution layers 24-13 and 24-3 and surrounded by the package material 24-5. The electrical connections 24-130 may serve to establish electrical connectivity between RDL 24-130 and RDL 24-3. That is, the electronic component 24-1 may be electrically connected to RDL 24-3 through RDL 24-13 and the electrical connections 24-130. In some embodiments of the present disclosure, the electrical connection 24-130 includes a solder bump or a copper pillar micro-bump.

Moreover, the semiconductor device package 24 may include a plurality of conductive vias 24-55 disposed on the upper surface 24-31 of RDL 24-3 and surrounded by the package material 24-5. The conductive vias 24-55 may be electrically connected to RDL 24-3. In some embodiments of the present disclosure, the conductive via 24-55 includes a TMV (Through Mold Via) or a copper pillar.

Referring to FIG. 24, the semiconductor device package 24 may include a redistribution layers 24-7 (RDL 24-7). In some embodiments of the present disclosure, RDL 24-7 includes a known-good-redistribution layer (KGR). RDL 24-7 may be disposed on an upper surface 24-51 of the package material 24-5. The electronic component 24-1 may be attached to a lower surface 24-71 of RDL 24-7 through an adhesive 24-121. An upper surface of the conductive vias 24-55 may abut against the lower surface 24-71 of RDL 24-7 and be electrically connected to RDL 24-7.

Moreover, a redistribution layers 24-4 (RDL 24-4) may be disposed above RDL 24-7. In some embodiments of the present disclosure, RDL 24-4 includes a known-good-redistribution layer (KGR). A plurality of electrical connections 24-70 may be arranged between RDL 24-4 and RDL 24-7, and thus the redistribution layers 24-4 and 24-7 may be electrically connected to each other through the electrical connections 24-70. In some embodiments of the present disclosure, the electrical connections 24-70 include a solder bump or a copper pillar micro-bump. Further, a package material 24-8 is disposed between RDL 24-4 and RDL 24-7 and configured to encapsulate an upper surface 24-72 of RDL 24-7, the electrical connections 24-70 and a lower surface 24-42 of RDL 24-4. In some embodiments of the present disclosure, the package material 24-8 includes an underfill (or a NCP).

The electronic component 24-2 may be disposed on an upper surface 24-41 of RDL 24-4. Further, a package material 24-6 may be disposed on the upper surface 24-41 of RDL 24-4 as well and configured to encapsulate the upper surface 24-41 of RDL 24-4 and the electronic components 24-2. In some embodiments of the present disclosure, the package material 24-6 includes a molding compound.

The electronic component 24-2 has a surface 24-21 (e.g., a lower surface) facing RDL 24-4. The surface 24-21 may include an active surface of the electronic component 24-2. Further, a redistribution layers 24-23 (RDL 24-23) may be disposed on the surface 24-21 of the electronic component 24-2. RDL 24-23 may be electrically connected to the active surface of the electronic component 24-2. A plurality of electrical connections 24-230 may be disposed between the redistribution layers 24-23 and 24-4 and surrounded by the package material 24-6. The electrical connections 24-230 may serve to establish electrical connectivity between RDL 24-23 and RDL 24-4. That is, the electronic component 24-2 may be electrically connected to RDL 24-4 through RDL 24-23 and the electrical connections 24-230. In some embodiments of the present disclosure, the electrical connection 24-230 includes a solder bump or a copper pillar micro-bump.

Given the above, the electronic components 24-1 and 24-2 may be electrically connected to each other through the redistribution layers 24-3, 24-7 and 24-4 and the conductive vias 24-55.

In some embodiments of the present disclosure, the redistribution layers 24-3 and 24-7, the electronic component 24-1, the conductive vias 24-55 and the package material 24-5 are formed as a first sub-assembly, and RDL 24-4, the electronic component 24-2, the package material 24-6 and the electrical connections 24-70 are formed as a second sub-assembly. Before combining the first sub-assembly and the second sub-assembly to form the semiconductor device package 24, the first sub-assembly and the second sub-assembly can be tested separately to ensure that both are known good. This process can be repeated to stack in the vertical direction a multiplicity of known-good structures similar to sub-assembly 1, sub-assembly 2 or a combination of sub-assembly 1 and sub-assembly structural attributes beyond the two packaging layers shown in FIG. 14.

FIG. 25 is a cross-sectional view of a semiconductor device package 25 in accordance with an embodiment of the present disclosure. As shown in FIG. 25, the semiconductor device package 25 may include an electronic component 25-1, an electronic component 25-2 disposed above the electronic component 25-1, an electronic component 25-3 disposed above the electronic component 25-2 and an electronic component 25-4 disposed above the electronic component 25-3. In some embodiments of the present disclosure, the electronic component 25-1 includes a known-good die (KGD), the electronic component 25-2 includes a known-good die (KGD), the electronic component 25-3 includes a known-good die (KGD) and the electronic component 25-4 includes a known-good die (KGD). In some embodiments of the present disclosure, the electronic component 25-1 includes a memory die, the electronic component 25-2 includes a memory die, the electronic component 25-3 includes a memory die and the electronic component 25-4 includes a memory die. In some embodiments of the present disclosure, the electronic component 25-1 includes an 8 Gb memory die, the electronic component 25-2 includes an 8 Gb memory die, the electronic component 25-3 includes an 8 Gb memory die and the electronic component 25-4 includes an 8 Gb memory die.

Referring to FIG. 25, the semiconductor device package 25 may include a redistribution layers 25-6 (RDL 25-6). In some embodiments of the present disclosure, RDL 25-6 includes a known-good-redistribution layer (KGR). The electronic component 25-1 may be disposed on an upper surface of RDL 25-6. Furthermore, a package material 25-13 may be disposed on the upper surface of RDL 25-6 as well and configured to encapsulate the upper surface of RDL 25-6 and the electronic components 25-1. In some embodiments of the present disclosure, the package material 25-13 includes a molding compound. Moreover, RDL 25-6 may include a plurality of external electrical connections 25-60 disposed on its lower surface. In some embodiments of the present disclosure, the external electrical connections 25-60 includes a test/bonding pad

The electronic component 25-1 has a lower surface facing RDL 25-6. The lower surface of the electronic component 25-1 may include an active surface of the electronic component 25-1. Further, a redistribution layers 25-10 (RDL 25-10) may be disposed on the lower surface of the electronic component 25-1. RDL 25-10 may be electrically connected to the active surface of the electronic component 25-1. A plurality of electrical connections 25-11 may be disposed between the redistribution layers 25-10 and 25-6 and surrounded by the package material 25-13. In some embodiments of the present disclosure, a underfill (or a NCP) is disposed between the redistribution layers 25-10 and 25-6 and the electrical connections 25-11 are surrounded by the underfill. The electrical connections 25-11 may serve to establish electrical connectivity between RDL 25-10 and RDL 25-6. That is, the electronic component 25-1 may be electrically connected to RDL 25-6 through RDL 25-10 and the electrical connections 25-11. In some embodiments of the present disclosure, the electrical connection 25-11 includes a solder bump or a copper pillar micro-bump.

Moreover, a plurality of conductive vias 25-15 may be disposed on the upper surface of RDL 25-6 and surrounded by the package material 25-13. The conductive vias 25-15 may be electrically connected to RDL 25-6. In some embodiments of the present disclosure, the conductive via 25-15 includes a TMV (Through Mold Via) or a copper pillar.

Referring to FIG. 25, the semiconductor device package 25 may include a redistribution layers 25-7 (RDL 25-7). In some embodiments of the present disclosure, RDL 25-7 includes a known-good-redistribution layer (KGR). RDL 25-7 may be disposed on an upper surface of the package material 25-13. The electronic component 25-1 may be attached to a lower surface of RDL 25-7 through an adhesive 25-17. An upper surface of the conductive vias 25-15 may abut against the lower surface of RDL 25-7 and thus the conductive vias 25-15 may be electrically connected to RDL 25-7.

The electronic component 25-2 may be disposed on an upper surface of RDL 25-7. Further, a package material 25-23 may be disposed on the upper surface of RDL 25-7 as well and configured to encapsulate the upper surface of RDL 25-7 and the electronic components 25-2. In some embodiments of the present disclosure, the package material 25-23 includes a molding compound.

The electronic component 25-2 has a lower surface facing RDL 25-7. The lower surface of the electronic component 25-2 may include an active surface of the electronic component 25-2. Further, a redistribution layers 25-20 (RDL 25-20) may be disposed on the lower surface of the electronic component 25-2. RDL 25-20 may be electrically connected to the active surface of the electronic component 25-2. A plurality of electrical connections 25-21 may be disposed between the redistribution layers 25-20 and 25-7 and surrounded by the package material 25-23. In some embodiments of the present disclosure, a underfill (or a NCP) is disposed between the redistribution layers 25-20 and 25-7 and the electrical connections 25-21 are surrounded by the underfill. The electrical connections 25-21 may serve to establish electrical connectivity between RDL 25-20 and RDL 25-7. That is, the electronic component 25-2 may be electrically connected to RDL 25-7 through RDL 25-20 and the electrical connections 25-21. In some embodiments of the present disclosure, the electrical connection 25-21 includes a solder bump or a copper pillar micro-bump.

Moreover, a plurality of conductive vias 25-25 may be disposed on the upper surface of RDL 25-7 and surrounded by the package material 25-23. The conductive vias 25-25 may be electrically connected to RDL 25-7. In some embodiments of the present disclosure, the conductive via 25-25 includes a TMV (Through Mold Via) or a copper pillar.

Referring to FIG. 25, the semiconductor device package 25 may include a redistribution layers 25-8 (RDL 25-8). In some embodiments of the present disclosure, RDL 25-8 includes a known-good-redistribution layer (KGR). RDL 25-8 may be disposed on an upper surface of the package material 25-23. The electronic component 25-2 may be attached to a lower surface of RDL 25-8 through an adhesive 25-27. An upper surface of the conductive vias 25-25 may abut against the lower surface of RDL 25-8 and the conductive vias 25-25 may be electrically connected to RDL 25-8.

The electronic component 25-3 may be disposed on an upper surface of RDL 25-8. Further, a package material 25-33 may be disposed on the upper surface of RDL 25-8 as well and configured to encapsulate the upper surface of RDL 25-8 and the electronic components 25-3. In some embodiments of the present disclosure, the package material 25-33 includes a molding compound.

The electronic component 25-3 has a lower surface facing RDL 25-8. The lower surface of the electronic component 25-3 may include an active surface of the electronic component 25-3. Further, a redistribution layers 25-30 (RDL 25-30) may be disposed on the lower surface of the electronic component 25-3. RDL 25-30 may be electrically connected to the active surface of the electronic component 25-3. A plurality of electrical connections 25-31 may be disposed between the redistribution layers 25-30 and 25-8 and surrounded by the package material 25-33. In some embodiments of the present disclosure, a underfill (or a NCP) is disposed between the redistribution layers 25-30 and 25-8 and the electrical connections 25-31 are surrounded by the underfill. The electrical connections 25-31 may serve to establish electrical connectivity between the redistribution layer 25-30 and the redistribution layer 25-8. That is, the electronic component 25-3 may be electrically connected to RDL 25-8 through RDL 25-30 and the electrical connections 25-31. In some embodiments of the present disclosure, the electrical connection 25-31 includes a solder bump or a copper pillar micro-bump.

Moreover, a plurality of conductive vias 25-35 may be disposed on the upper surface of RDL 25-8 and surrounded by the package material 25-33. The conductive vias 25-35 may be electrically connected to RDL 25-8. In some embodiments of the present disclosure, the conductive via 25-35 includes a TMV (Through Mold Via) or a copper pillar.

Referring to FIG. 25, the semiconductor device package 25 may include a redistribution layers 25-9 (RDL 25-9). In some embodiments of the present disclosure, RDL 25-9 includes a known-good-redistribution layer (KGR). RDL 25-9 may be disposed on an upper surface of the package material 25-33. The electronic component 25-3 may be attached to a lower surface of RDL 25-9 through an adhesive 25-37. An upper surface of the conductive vias 25-35 may abut against the lower surface of RDL 25-9 and thus the conductive vias 25-35 may be electrically connected to RDL 25-9.

The electronic component 25-4 may be disposed on an upper surface of RDL 25-9. Further, a package material 25-43 may be disposed on the upper surface of RDL 25-9 as well and configured to encapsulate the upper surface of RDL 25-9 and the electronic components 25-4. In some embodiments of the present disclosure, the package material 25-43 includes a molding compound.

The electronic component 25-4 has a lower surface facing RDL 25-9. The lower surface of the electronic component 25-4 may include an active surface of the electronic component 25-4. Further, a redistribution layers 25-40 (RDL 25-40) may be disposed on the lower surface of the electronic component 25-4. RDL 25-40 may be electrically connected to the active surface of the electronic component 25-4. A plurality of electrical connections 25-41 may be disposed between the redistribution layers 25-40 and 25-9 and surrounded by the package material 25-43. In some embodiments of the present disclosure, an underfill (or a NCP) is disposed between the redistribution layers 25-40 and 25-9 and the electrical connections 25-41 are surrounded by the underfill. The electrical connections 25-41 may serve to establish electrical connectivity between RDL 25-40 and RDL 25-9. That is, the electronic component 25-4 may be electrically connected to RDL 25-9 through RDL 25-40 and the electrical connections 25-41. In some embodiments of the present disclosure, the electrical connection 25-41 includes a solder bump or a copper pillar micro-bump.

In some embodiments of the present disclosure, the semiconductor device package 25 is manufactured by a chip-last/face-down type fan-out packaging process.

FIG. 26 is a cross-sectional view of a semiconductor device package 26 in accordance with an embodiment of the present disclosure. As shown in FIG. 26, the semiconductor device package 26 may include an electronic component 26-1, an electronic component 26-2 disposed above the electronic component 26-1, an electronic component 26-3 disposed above the electronic component 26-2 and an electronic component 26-4 disposed above the electronic component 26-3. In some embodiments of the present disclosure, the electronic component 26-1 includes a known-good die (KGD), the electronic component 26-2 includes a known-good die (KGD), the electronic component 26-3 includes a known-good die (KGD) and the electronic component 26-4 includes a known-good die (KGD). In some embodiments of the present disclosure, the electronic component 26-1 includes a memory die, the electronic component 26-2 includes a memory die, the electronic component 26-3 includes a memory die and the electronic component 26-4 includes a memory die. In some embodiments of the present disclosure, the electronic component 26-1 includes an 8 Gb memory die, the electronic component 26-2 includes an 8 Gb memory die, the electronic component 26-3 includes an 8 Gb memory die and the electronic component 26-4 includes an 8 Gb memory die.

Referring to FIG. 26, the semiconductor device package 26 may include a redistribution layers 26-6 (RDL 26-6). In some embodiments of the present disclosure, the RDL 26-6 includes a known-good-redistribution layer (KGR). The electronic component 26-1 may be disposed on an upper surface of RDL 26-6. In some embodiments of the present disclosure, the electronic component 26-1 is attached to the upper surface of RDL 26-6 through an adhesive 26-17. Further, a package material 26-13 may be disposed on the upper surface of RDL 26-6 as well and configured to encapsulate the upper surface of RDL 26-6 and the electronic components 26-1. In some embodiments of the present disclosure, the package material 26-13 includes a molding compound. Moreover, RDL 26-6 may include a plurality of external electrical connections 26-60 disposed on its lower surface. In some embodiments of the present disclosure, the external electrical connection 26-60 includes a test/bonding pad.

The electronic component 26-1 has an upper surface facing away from RDL 26-6. The upper surface of the electronic component 26-1 may include an active surface of the electronic component 26-1. Further, a redistribution layers 26-10 (RDL 26-10) may be disposed on the upper surface of the electronic component 26-1. RDL 26-10 may be electrically connected to the active surface of the electronic component 26-1.

A plurality of conductive vias 26-11 may be disposed on RDL 26-10 and surrounded by the package material 26-13. The conductive vias 26-11 may be electrically connected to RDL 26-10. In some embodiments of the present disclosure, the conductive via 26-11 includes a TMV (Through Mold Via) or a copper pillar. Moreover, a plurality of conductive vias 26-15 may be disposed on the upper surface of RDL 26-6 and surrounded by the package material 26-13. The conductive vias 26-15 may be electrically connected to RDL 26-6. In some embodiments of the present disclosure, the conductive via 26-15 includes a TMV (Through Mold Via) or a copper pillar.

Referring to FIG. 26, the semiconductor device package 26 may include a redistribution layers 26-7 (RDL 26-7). In some embodiments of the present disclosure, RDL 26-7 includes a known-good-redistribution layer (KGR). RDL 26-7 may be disposed on an upper surface of the package material 26-13. An upper surface of the conductive vias 26-11 may abut against the lower surface of RDL 26-7 and thus the conductive vias 26-11 may be electrically connected to RDL 26-7. Thus, the conductive vias 26-11 may serve to establish electrical connectivity between RDL 26-10 and RDL 26-7. That is, the electronic component 26-1 may be electrically connected to RDL 26-7 through the conductive vias 26-11. In some embodiments of the present disclosure, an underfill (or a NCP) is disposed between the redistribution layers 26-10 and 26-7 and the conductive vias 26-11 are surrounded by the underfill. Moreover, an upper surface of the conductive vias 26-15 may abut against the lower surface of RDL 26-7 and thus the conductive vias 26-15 may be electrically connected to RDL 26-7. Thus, the conductive vias 26-15 may serve to establish electrical connectivity between RDL 26-6 and RDL 26-7.

The electronic component 26-2 may be disposed on an upper surface of RDL 26-7. In some embodiments of the present disclosure, the electronic component 26-2 is attached to the upper surface of RDL 26-7 through an adhesive 26-27. Further, a package material 26-23 may be disposed on the upper surface of RDL 26-7 as well and configured to encapsulate the upper surface of RDL 26-7 and the electronic components 26-2. In some embodiments of the present disclosure, the package material 26-23 includes a molding compound.

The electronic component 26-2 has an upper surface facing away from RDL 26-7. The upper surface of the electronic component 26-2 may include an active surface of the electronic component 26-2. Further, a redistribution layers 26-20 (RDL 26-20) may be disposed on the upper surface of the electronic component 26-2. RDL 26-20 may be electrically connected to the active surface of the electronic component 26-2.

A plurality of conductive vias 26-21 may be disposed on RDL 26-20 and surrounded by the package material 26-23. The conductive vias 26-21 may be electrically connected to RDL 26-20. In some embodiments of the present disclosure, the conductive via 26-21 includes a TMV (Through Mold Via) or a copper pillar. Moreover, a plurality of conductive vias 26-25 may be disposed on the upper surface of RDL 26-7 and surrounded by the package material 26-23. The conductive vias 26-25 may be electrically connected to RDL 26-7. In some embodiments of the present disclosure, the conductive via 26-25 includes a TMV (Through Mold Via) or a copper pillar.

Referring to FIG. 26, the semiconductor device package 26 may include a redistribution layers 26-8 (RDL 26-8). In some embodiments of the present disclosure, the redistribution layer 26-8 includes a known-good-redistribution layer (KGR). RDL 26-8 may be disposed on an upper surface of the package material 26-23. An upper surface of the conductive vias 26-21 may abut against the lower surface of RDL 26-8 and thus the conductive vias 26-21 may be electrically connected to RDL 26-8. Thus, the conductive vias 26-21 may serve to establish electrical connectivity between RDL 26-20 and RDL 26-8. That is, the electronic component 26-2 may be electrically connected to RDL 26-8 through the conductive vias 26-21. In some embodiments of the present disclosure, an underfill (or a NCP) is disposed between the redistribution layers 26-20 and 26-8 and the conductive vias 26-21 are surrounded by the underfill. Moreover, an upper surface of the conductive vias 26-25 may abut against the lower surface of RDL 26-8 and thus the conductive vias 26-25 may be electrically connected to RDL 26-8. Thus, the conductive vias 26-25 may serve to establish electrical connectivity between RDL 26-7 and RDL 26-8.

The electronic component 26-3 may be disposed on an upper surface of RDL 26-8. In some embodiments of the present disclosure, the electronic component 26-3 is attached to the upper surface of the redistribution layer 26-8 through an adhesive 26-37. Furthermore, a package material 26-33 may be disposed on the upper surface of RDL 26-8 as well and configured to encapsulate the upper surface of RDL 26-8 and the electronic components 26-3. In some embodiments of the present disclosure, the package material 26-33 includes a molding compound.

The electronic component 26-3 has an upper surface facing away from RDL 26-8. The upper surface of the electronic component 26-3 may include an active surface of the electronic component 26-3. Further, a redistribution layers 26-30 (RDL 26-30) may be disposed on the upper surface of the electronic component 26-3. RDL 26-30 may be electrically connected to the active surface of the electronic component 26-3.

A plurality of conductive vias 26-31 may be disposed on RDL 26-30 and surrounded by the package material 26-33. The conductive vias 26-31 may be electrically connected to RDL 26-30. In some embodiments of the present disclosure, the conductive via 26-31 includes a TMV (Through Mold Via) or a copper pillar. Moreover, a plurality of conductive vias 26-35 may be disposed on the upper surface of RDL 26-8 and surrounded by the package material 26-33. The conductive vias 26-35 may be electrically connected to RDL 26-8. In some embodiments of the present disclosure, the conductive via 26-35 includes a TMV (Through Mold Via) or a copper pillar.

Referring to FIG. 26, the semiconductor device package 26 may include a redistribution layers 26-9 (RDL 26-9). In some embodiments of the present disclosure, RDL 26-9 includes a known-good-redistribution layer (KGR). RDL 26-9 may be disposed on an upper surface of the package material 26-33. An upper surface of the conductive vias 26-31 may abut against the lower surface of RDL 26-9 and thus the conductive vias 26-31 may be electrically connected to RDL 26-9. Thus, the conductive vias 26-31 may serve to establish electrical connectivity between RDL 26-30 and RDL 26-9. That is, the electronic component 26-3 may be electrically connected to RDL 26-9 through the conductive vias 26-31. In some embodiments of the present disclosure, an underfill (or a NCP) is disposed between the redistribution layers 26-30 and 26-9 and the conductive vias 26-31 are surrounded by the underfill. Moreover, an upper surface of the conductive vias 26-35 may abut against the lower surface of RDL 26-9 and thus the conductive vias 26-35 may be electrically connected to RDL 26-9. Thus, the conductive vias 26-35 may serve to establish electrical connectivity between RDL 26-8 and RDL 26-9.

The electronic component 26-4 may be disposed on an upper surface of RDL 26-9. Further, a package material 26-43 may be disposed on the upper surface of RDL 26-9 as well and configured to encapsulate the upper surface of RDL 26-9 and the electronic component 26-4. In some embodiments of the present disclosure, the package material 26-43 includes a molding compound.

The electronic component 26-4 has a lower surface facing RDL 26-9. The lower surface of the electronic component 26-4 may include an active surface of the electronic component 26-4. Further, a redistribution layers 26-40 (RDL 26-40) may be disposed on the lower surface of the electronic component 26-4. RDL 26-40 may be electrically connected to the active surface of the electronic component 26-4. A plurality of electrical connections 26-41 may be disposed between the redistribution layers 26-40 and 26-9 and surrounded by the package material 26-43. In some embodiments of the present disclosure, an underfill (or a NCP) is disposed between the redistribution layers 26-40 and 26-9 and the electrical connections 26-41 are surrounded by the underfill. The electrical connections 26-41 may serve to establish electrical connectivity between RDL 26-40 and RDL 26-9. That is, the electronic component 26-4 may be electrically connected to RDL 26-9 through RDL 26-40 and the electrical connections 26-41. In some embodiments of the present disclosure, the electrical connection 26-41 includes a solder bump or a copper pillar micro-bump.

In some embodiments of the present disclosure, the semiconductor device package 26 is manufactured by a chip-first/face-up type fan-out packaging process.

FIG. 27 is a cross-sectional view of a semiconductor device package 27 in accordance with an embodiment of the present disclosure. As shown in FIG. 27, the semiconductor device package 27 may include an electronic component 27-1, an electronic component 27-2 disposed above the electronic component 27-1, an electronic component 27-3 disposed above the electronic component 27-2 and an electronic component 27-4 disposed above the electronic component 27-3. In some embodiments of the present disclosure, the electronic component 27-1 includes a known-good die (KGD), the electronic component 27-2 includes a known-good die (KGD), the electronic component 27-3 includes a known-good die (KGD) and the electronic component 27-4 includes a known-good die (KGD). In some embodiments of the present disclosure, the electronic component 27-1 includes a memory die, the electronic component 27-2 includes a memory die, the electronic component 27-3 includes a memory die and the electronic component 27-4 includes a memory die. In some embodiments of the present disclosure, the electronic component 27-1 includes an 8 Gb memory die, the electronic component 27-2 includes an 8 Gb memory die, the electronic component 27-3 includes an 8 Gb memory die and the electronic component 27-4 includes an 8 Gb memory die.

Referring to FIG. 27, the semiconductor device package 27 may include a redistribution layers 27-6 (RDL 27-6). In some embodiments of the present disclosure, the redistribution layer 27-6 includes a known-good-redistribution layer (KGR). The electronic component 27-1 may be disposed on an upper surface of RDL 27-6. Further, a package material 27-13 may be disposed on the upper surface of RDL 27-6 as well and configured to encapsulate the upper surface of RDL 27-6 and the electronic component 27-1. In some embodiments of the present disclosure, the package material 27-13 includes a molding compound. Moreover, RDL 27-6 may include a plurality of external electrical connections 27-60 disposed on its lower surface. In some embodiments of the present disclosure, the external electrical connections 27-60 include a test/bonding pad.

The electronic component 27-1 has a lower surface facing RDL 27-6. The lower surface of the electronic component 27-1 may include an active surface of the electronic component 27-1. Further, a redistribution layers 27-10 (RDL 27-10) may be disposed on the lower surface of the electronic component 27-1. RDL 27-10 may be electrically connected to the active surface of the electronic component 27-1. A plurality of conductive vias 27-11 may be disposed between the redistribution layers 27-10 and 27-6 and surrounded by the package material 27-13. In some embodiments of the present disclosure, an underfill (or a NCP) is disposed between the redistribution layers 27-10 and 27-6 and the conductive vias 27-11 are surrounded by the underfill. The conductive vias 27-11 may serve to establish electrical connectivity between RDL 27-10 and RDL 27-6. That is, the electronic component 27-1 may be electrically connected to RDL 27-6 through RDL 27-10 and the conductive vias 27-11. In some embodiments of the present disclosure, the conductive via 27-11 includes a TMV (Through Mold Via), a solder bump or a copper pillar micro-bump.

Moreover, a plurality of conductive vias 27-15 may be disposed on the upper surface of RDL 27-6 and surrounded by the package material 27-13. The conductive vias 27-15 may be electrically connected to RDL 27-6. In some embodiments of the present disclosure, the conductive via 27-15 includes a TMV (Through Mold Via) or a copper pillar.

Referring to FIG. 27, the semiconductor device package 27 may include a redistribution layers 27-7 (RDL 27-7). In some embodiments of the present disclosure, RDL 27-7 includes a known-good-redistribution layer (KGR). RDL 27-7 may be disposed on an upper surface of the package material 27-13. The electronic component 27-1 may be attached to a lower surface of RDL 27-7 through an adhesive 27-17. An upper surface of the conductive vias 27-15 may abut against the lower surface of RDL 27-7 and thus the conductive vias 27-15 may be electrically connected to RDL 27-7.

The electronic component 27-2 may be disposed on an upper surface of the redistribution layers 27-7 (RDL 27-7). Further, a package material 27-23 may be disposed on the upper surface of RDL 27-7 as well and configured to encapsulate the upper surface of RDL 27-7 and the electronic component 27-2. In some embodiments of the present disclosure, the package material 27-23 includes a molding compound.

The electronic component 27-2 has a lower surface facing RDL 27-7. The lower surface of the electronic component 27-2 may include an active surface of the electronic component 27-2. Further, a redistribution layers 27-20 (RDL 27-20) may be disposed on the lower surface of the electronic component 27-2. RDL 27-20 may be electrically connected to the active surface of the electronic component 27-2. A plurality of conductive vias 27-21 may be disposed between the redistribution layers 27-20 and 27-7 and surrounded by the package material 27-23. In some embodiments of the present disclosure, an underfill (or a NCP) is disposed between the redistribution layers 27-20 and 27-7 and the conductive vias 27-21 are surrounded by the underfill. The electrical connections 27-21 may serve to establish electrical connectivity between RDL 27-20 and RDL 27-7. That is, the electronic component 27-2 may be electrically connected to RDL 27-7 through RDL 27-20 and the electrical connections 27-21. In some embodiments of the present disclosure, the electrical connection 27-21 includes a TMV (Through Mold Via), a solder bump or a copper pillar micro-bump.

Moreover, a plurality of conductive vias 27-25 may be disposed on the upper surface of RDL 27-7 and surrounded by the package material 27-23. The conductive vias 27-25 may be electrically connected to RDL 27-7. In some embodiments of the present disclosure, the conductive via 27-25 includes a TMV (Through Mold Via) or a copper pillar.

Referring to FIG. 27, the semiconductor device package 27 may include a redistribution layers 27-8 (RDL 27-8). In some embodiments of the present disclosure, RDL 27-8 includes a known-good-redistribution layer (KGR). RDL 27-8 may be disposed on an upper surface of the package material 27-23. The electronic component 27-2 may be attached to a lower surface of RDL 27-8 through an adhesive 27-27. An upper surface of the conductive vias 27-25 may abut against the lower surface of RDL 27-8 and thus the conductive vias 27-25 may be electrically connected to RDL 27-8.

The electronic component 27-3 may be disposed on an upper surface of RDL 27-8. Further, a package material 27-33 may be disposed on the upper surface of RDL 27-8 as well and configured to encapsulate the upper surface of RDL 27-8 and the electronic component 27-3. In some embodiments of the present disclosure, the package material 27-33 includes a molding compound.

The electronic component 27-3 has a lower surface facing RDL 27-8. The lower surface of the electronic component 27-3 may include an active surface of the electronic component 27-3. Further, a redistribution layers 27-30 (RDL 27-30) may be disposed on the lower surface of the electronic component 27-3. RDL 27-30 may be electrically connected to the active surface of the electronic component 27-3. A plurality of conductive vias 27-31 may be disposed between the redistribution layers 27-30 and 27-8 and surrounded by the package material 27-33. In some embodiments of the present disclosure, an underfill (or a NCP) is disposed between the redistribution layers 27-30 and 27-8 and the conductive vias 27-31 are surrounded by the underfill. The conductive vias 27-31 may serve to establish electrical connectivity between RDL 27-30 and RDL 27-8. That is, the electronic component 27-3 may be electrically connected to RDL 27-8 through RDL 27-30 and conductive vias 27-31. In some embodiments of the present disclosure, the conductive via 27-31 includes a TMV (Through Mold Via) or a copper pillar.

Moreover, a plurality of conductive vias 27-35 may be disposed on the upper surface of RDL 27-8 and surrounded by the package material 27-33. The conductive vias 27-35 may be electrically connected to RDL 27-8. In some embodiments of the present disclosure, the conductive via 27-35 includes a TMV (Through Mold Via) or a copper pillar.

Referring to FIG. 27, the semiconductor device package 27 may include a redistribution layers 27-9 (RDL 27-9). In some embodiments of the present disclosure, the redistribution layer 27-9 includes a known-good-redistribution layer (KGR). RDL 27-9 may be disposed on an upper surface of the package material 27-33. The electronic component 27-3 may be attached to a lower surface of RDL 27-9 through an adhesive 27-37. An upper surface of the conductive vias 27-35 may abut against the lower surface of RDL 27-9 and thus the conductive vias 27-35 may be electrically connected to RDL 27-9.

The electronic component 27-4 may be disposed on an upper surface of the redistribution layers 27-9 (RDL 27-9). Further, a package material 27-43 may be disposed on the upper surface of RDL 27-9 as well and configured to encapsulate the upper surface of RDL 27-9 and the electronic component 27-4. In some embodiments of the present disclosure, the package material 27-43 includes a molding compound.

The electronic component 27-4 has a lower surface facing RDL 27-9. The lower surface of the electronic component 27-4 may include an active surface of the electronic component 27-4. Further, a redistribution layers 27-40 (RDL 27-40) may be disposed on the lower surface of the electronic component 27-4. RDL 27-40 may be electrically connected to the active surface of the electronic component 27-4. A plurality of electrical connections 27-41 may be disposed between the redistribution layers 27-40 and 27-9 and surrounded by the package material 27-43. In some embodiments of the present disclosure, an underfill (or a NCP) is disposed between the redistribution layers 27-40 and 27-9 and the electrical connections 27-41 are surrounded by the underfill. The electrical connections 27-41 may serve to establish electrical connectivity between RDL 27-40 and RDL 27-9. That is, the electronic component 27-4 may be electrically connected to RDL 27-9 through RDL 27-40 and the electrical connections 27-41. In some embodiments of the present disclosure, the electrical connection 27-41 includes a solder bump.

In some embodiments of the present disclosure, the semiconductor device package 27 is manufactured by a chip-first/face-down type packaging process.

FIG. 28 is a cross-sectional view of a semiconductor device package 28 in accordance with an embodiment of the present disclosure. As shown in FIG. 28, the semiconductor device package 28 may include an electronic component 28-1, an electronic component 28-2 disposed above the electronic component 28-1, an electronic component 28-3 disposed above the electronic component 28-2 and an electronic component 28-4 disposed above the electronic component 28-3. In some embodiments of the present disclosure, the electronic component 28-1 includes a known-good die (KGD), the electronic component 28-2 includes a known-good die (KGD), the electronic component 28-3 includes a known-good die (KGD) and the electronic component 28-4 includes a known-good die (KGD). In some embodiments of the present disclosure, the electronic component 28-1 includes a memory die, the electronic component 28-2 includes a memory die, the electronic component 28-3 includes a memory die and the electronic component 28-4 includes a memory die. In some embodiments of the present disclosure, the electronic component 28-1 includes an 8 Gb memory die, the electronic component 28-2 includes an 8 Gb memory die, the electronic component 28-3 includes an 8 Gb memory die and the electronic component 28-4 includes an 8 Gb memory die.

Referring to FIG. 28, the semiconductor device package 28 may include a redistribution layers 28-6 (RDL 28-6). In some embodiments of the present disclosure, RDL 28-6 includes a known-good-redistribution layer (KGR). The electronic component 28-1 may be disposed on an upper surface of RDL 28-6. Furthermore, a package material 28-13 may be disposed on the upper surface of RDL 28-6 as well and configured to encapsulate the upper surface of RDL 28-6 and the electronic component 28-1. In some embodiments of the present disclosure, the package material 28-13 includes an IC substrate material. Moreover, RDL 28-6 may include a plurality of external electrical connections 28-60 disposed on its lower surface. In some embodiments of the present disclosure, the external electrical connection 28-60 include a test/bonding pad

The electronic component 28-1 has a lower surface facing RDL 28-6. The lower surface of the electronic component 28-1 may include an active surface of the electronic component 28-1. Further, a redistribution layers 28-10 (RDL 28-10) may be disposed on the lower surface of the electronic component 28-1. RDL 28-10 may be electrically connected to the active surface of the electronic component 28-1. A plurality of electrical connections 28-11 may be disposed between the redistribution layers 28-10 and 28-6 and surrounded by the package material 28-13. In some embodiments of the present disclosure, an underfill (or a NCP) is disposed between the redistribution layers 28-10 and 28-6 and the electrical connections 28-11 are surrounded by the underfill. The electrical connections 28-11 may serve to establish electrical connectivity between RDL 28-10 and RDL 28-6. That is, the electronic component 28-1 may be electrically connected to RDL 28-6 through RDL 28-10 and the electrical connections 28-11. In some embodiments of the present disclosure, the electrical connection 28-11 includes a solder bump or a copper pillar micro-bump.

Moreover, a plurality of conductive vias 28-15 may be disposed on the upper surface of RDL 28-6 and surrounded by the package material 28-13. The conductive vias 28-15 may be electrically connected to RDL 28-6. In some embodiments of the present disclosure, the conductive via 28-15 includes a TMV (Through Mold Via) or a copper pillar.

Referring to FIG. 28, the semiconductor device package 28 may include a redistribution layers 28-7 (RDL 28-7). In some embodiments of the present disclosure, RDL 28-7 includes a known-good-redistribution layer (KGR). RDL 28-7 may be disposed on an upper surface of the package material 28-13. The electronic component 28-1 may be attached to a lower surface of RDL 28-7 through an adhesive 28-17. An upper surface of the conductive vias 28-15 may abut against the lower surface of RDL 28-7 and thus the conductive vias 28-15 may be electrically connected to RDL 28-7.

The electronic component 28-2 may be disposed on an upper surface of RDL 28-7. Further, a package material 28-23 may be disposed on the upper surface of RDL 28-7 as well and configured to encapsulate the upper surface of RDL 28-7 and the electronic component 28-2. In some embodiments of the present disclosure, the package material 28-23 includes an IC substrate material.

The electronic component 28-2 has a lower surface facing RDL 28-7. The lower surface of the electronic component 28-2 may include an active surface of the electronic component 28-2. Further, a redistribution layers 28-20 (RDL 28-20) may be disposed on the lower surface of the electronic component 28-2. RDL 28-20 may be electrically connected to the active surface of the electronic component 28-2. A plurality of electrical connections 28-21 may be disposed between the redistribution layers 28-20 and 28-7 and surrounded by the package material 28-23. In some embodiments of the present disclosure, an underfill (or a NCP) is disposed between the redistribution layers 28-20 and 28-7 and the electrical connections 28-21 are surrounded by the underfill. The electrical connections 28-21 may serve to establish electrical connectivity between RDL 28-20 and RDL 28-7. That is, the electronic component 28-2 may be electrically connected to the redistribution layer 28-7 through RDL 28-20 and the electrical connections 28-21. In some embodiments of the present disclosure, the electrical connection 28-21 includes a solder bump or a copper pillar micro-bump.

Moreover, a plurality of conductive vias 28-25 may be disposed on the upper surface of RDL 28-7 and surrounded by the package material 28-23. The conductive vias 28-25 may be electrically connected to RDL 28-7. In some embodiments of the present disclosure, the conductive via 28-25 includes a TMV (Through Mold Via) or a copper pillar.

Referring to FIG. 28, the semiconductor device package 28 may include a redistribution layers 28-8 (RDL 28-8). In some embodiments of the present disclosure, RDL 28-8 includes a known-good-redistribution layer (KGR). RDL 28-8 may be disposed on an upper surface of the package material 28-23. The electronic component 28-2 may be attached to a lower surface of RDL 28-8 through an adhesive 28-27. An upper surface of the conductive vias 28-25 may abut against the lower surface of RDL 28-8 and thus the conductive vias 28-25 may be electrically connected to RDL 28-8.

The electronic component 28-3 may be disposed on an upper surface of RDL 28-8. Further, a package material 28-33 may be disposed on the upper surface of RDL 28-8 as well and configured to encapsulate the upper surface of RDL 28-8 and the electronic component 28-3. In some embodiments of the present disclosure, the package material 28-33 includes an IC substrate material.

The electronic component 28-3 has a lower surface facing RDL 28-8. The lower surface of the electronic component 28-3 may include an active surface of the electronic component 28-3. Further, a redistribution layers 28-30 (RDL 28-30) may be disposed on the lower surface of the electronic component 28-3. RDL 28-30 may be electrically connected to the active surface of the electronic component 28-3. A plurality of electrical connections 28-31 may be disposed between the redistribution layers 28-30 and 28-8 and surrounded by the package material 28-33. In some embodiments of the present disclosure, an underfill (or a NCP) is disposed between the redistribution layers 28-30 and 28-8 and the electrical connections 28-31 are surrounded by the underfill. The electrical connections 28-31 may serve to establish electrical connectivity between RDL 28-30 and RDL 28-8. That is, the electronic component 28-3 may be electrically connected to RDL 28-8 through RDL 28-30 and the electrical connections 28-31. In some embodiments of the present disclosure, the electrical connection 28-31 includes a solder bump or a copper pillar micro-bump.

Moreover, a plurality of conductive vias 28-35 may be disposed on the upper surface of RDL 28-8 and surrounded by the package material 28-33. The conductive vias 28-35 may be electrically connected to RDL 28-8. In some embodiments of the present disclosure, the conductive via 28-35 includes a TMV (Through Mold Via) or a copper pillar.

Referring to FIG. 28, the semiconductor device package 28 may include a redistribution layers 28-9 (RDL 28-9). In some embodiments of the present disclosure, RDL 28-9 includes a known-good-redistribution layer (KGR). RDL 28-9 may be disposed on an upper surface of the package material 28-33. The electronic component 28-3 may be attached to a lower surface of RDL 28-9 through an adhesive 28-37. An upper surface of the conductive vias 28-35 may abut against the lower surface of RDL 28-9 and thus the conductive vias 28-35 may be electrically connected to RDL 28-9.

The electronic component 28-4 may be disposed on an upper surface of RDL 28-9. Further, a package material 28-43 may be disposed on the upper surface of the redistribution layer 28-9 as well and configured to encapsulate the upper surface of RDL 28-9 and the electronic component 28-4. In some embodiments of the present disclosure, the package material 28-43 includes a molding compound.

The electronic component 28-4 has a lower surface facing RDL 28-9. The lower surface of the electronic component 28-4 may include an active surface of the electronic component 28-4. Further, a redistribution layers 28-40 (RDL 28-40) may be disposed on the lower surface of the electronic component 28-4. RDL 28-40 may be electrically connected to the active surface of the electronic component 28-4. A plurality of electrical connections 28-41 may be disposed between the redistribution layers 28-40 and 28-9 and surrounded by the package material 28-43. In some embodiments of the present disclosure, an underfill (or a NCP) is disposed between the redistribution layers 28-40 and 28-9 and the electrical connections 28-41 are surrounded by the underfill. The electrical connections 28-41 may serve to establish electrical connectivity between RDL 28-40 and RDL 28-9. That is, the electronic component 28-4 may be electrically connected to RDL 28-9 through RDL 28-40 and the electrical connections 28-41. In some embodiments of the present disclosure, the electrical connection 28-41 includes a solder bump or a copper pillar micro-bump.

FIG. 29 is a cross-sectional view of a semiconductor device package structure 29 in accordance with an embodiment of the present disclosure. As shown in FIG. 29, the semiconductor device package structure 29 may include a semiconductor device package 290 and a substrate 29-1 configured to support and connect the semiconductor device package 290. In some embodiments of the present disclosure, the semiconductor device package 290 is the same as, or similar to, the semiconductor device packages shown in FIGS. 4-6, 8-10, 11, 12A, 13, 17, 20, 22, and 24-28 and other relevant follow-on figures in this invention. In some embodiments of the present disclosure, the embedded substrate 29-1 includes an organic laminate substrate, a fan-out substrate, a silicon substrate, a glass substrate or a metal substrate. The same statement also applies to the structures in FIGS. 30 and 31.

The substrate 29-1 may include a redistribution layers 29-11 (RDL 29-11) on its upper surface and a redistribution layers 29-12 (RDL 29-12) on its lower surface. Further, the substrate 29-1 may include a plurality of conductive vias 29-15 passing through it, and these conductive vias 29-15 are configured to electrically connect RDL 29-11 to RDL 29-12. In some embodiments of the present disclosure, the conductive via includes a plated through-hole (PTH). Referring to FIG. 29, the semiconductor device package 290 may be disposed on the upper surface of the substrate 29-1. The semiconductor device package 290 may be electrically connected to RDL 29-11 of the substrate 29-1 through the electrical connections 2900. Moreover, an underfill (or a NCP) 29-01 may be disposed between the semiconductor device package 290 and the substrate 29-1 and configured to surround the electrical connections 2900.

Furthermore, at least one electronic component 29-3 may be disposed on the upper surface of the substrate 29-1 and adjacent to the semiconductor device package 290. The electronic component 29-3 may be electrically connected to RDL 29-11 of the substrate 29-1 through the electrical connections 29-30. Moreover, an underfill 29-31 (or a NCP) may be disposed between the electronic component 29-3 and the substrate 29-1 and configured to surround the electrical connections 29-30. In some embodiments of the present disclosure, the electrical connection 29-30 includes a solder bump or a copper pillar micro-bump.

As shown in FIG. 29, the semiconductor device package structure 29 may include a plurality of electrical connections 29-5 and an electronic component 29-7 disposed on the lower surface of the substrate 29-1. The electrical connections 29-5 may be electrically connected to RDL 29-12 of the substrate 29-1. In some embodiments of the present disclosure, the electrical connection 29-5 includes a BGA ball. The electronic component 29-7 may be electrically connected to RDL 29-12 of the substrate 29-1 through the electrical connections 29-70. Further, an underfill 29-71 may be disposed between the electronic component 29-7 and the substrate 29-1 and configured to surround the electrical connections 29-70. In some embodiments of the present disclosure, the electronic component 29-7 includes a processor. Alternatively, each of the electronic component 29-7 and the semiconductor device package 290 can be mounted on either the upper side or the lower side of the substrate 29-1.

FIG. 30 is a cross-sectional view of a semiconductor device package structure 30 in accordance with an embodiment of the present disclosure. As shown in FIG. 30, the semiconductor device package structure 30 may include a semiconductor device package 300 and a semiconductor device package 301, and the semiconductor device package 300 and the semiconductor device package 301 may be stacked in the vertical direction.

Referring to FIG. 30, the semiconductor device package 300 is disposed above the semiconductor device package 301. In some embodiments of the present disclosure, the semiconductor device package 300 is the same as, or similar to, the semiconductor device packages shown in FIGS. 4-6, 8-10, 11, 12A, 13, 17, 20, 22, and 24-28, and other relevant follow-on figures in this invention.

The semiconductor device package 301 may include the redistribution layers 30-1 and 30-2 (RDL 30-1 and RDL 30-2), the embedded electronic component 30-4 and 30-6 and a package material 30-3. The electronic component 30-4 may be disposed on an upper surface of RDL 30-1 and electrically connected to RDL 30-1 through the electrical connections 30-40. In some embodiments of the present disclosure, an underfill (or a NCP) is disposed between the electronic component 30-4 and RDL 30-1 and configured to surround the electrical connections 30-40. Furthermore, the electronic component 30-4 may be attached to the lower surface of RDL 30-2 through an adhesive 30-41. In some embodiments of the present disclosure, the electronic component 30-4 includes a processor. In some embodiments of the present disclosure, the electronic component 30-4 is located directly below the semiconductor device package 300 and above RDL 30-2.

Moreover, at least one electronic component 30-6 may be disposed on an upper surface of RDL 30-1 and electrically connected to RDL 30-1 through the electrical connections 30-60. In some embodiments of the present disclosure, an underfill (or a NCP) is disposed between the electronic component 30-6 and RDL 30-1 and configured to surround the electrical connections 30-60. Furthermore, a cross-sectional width of the electronic component 30-6 may be less than a cross-sectional width of the electronic component 30-4.

Moreover, the package material 30-3—may be disposed between RDL 30-1 and RDL 30-2 and configured to encapsulate the electronic components 30-4 and 30-6, the upper surface of RDL 30-1 and the lower surface of RDL 30-2. A plurality of conductive vias 30-35 may pass through the package material 30-3 and electrically connect RDL 30-1 to RDL 30-2.

The semiconductor device package 301 may include a plurality of the electrical connections 30-7 on a lower surface of RDL 30-1. The electrical connections 30-7 may be electrically connected to RDL 30-1. In some embodiments of the present disclosure, the electrical connection 30-7 includes a BGA ball.

As shown in FIG. 30, the semiconductor device package 300 may be disposed on an upper surface of RDL 30-2 of the semiconductor device package 301. The semiconductor device package 300 may be electrically connected to RDL 30-2 of the semiconductor device package 301 through the electrical connections 3001. In some embodiments of the present disclosure, an underfill or a NCP is arranged between the semiconductor device package 300 and the semiconductor device package 301 and configured to surround the electrical connections 3001.

FIG. 31 is a cross-sectional view of a semiconductor device package structure 31 in accordance with an embodiment of the present disclosure. As shown in FIG. 31, the semiconductor device package structure 31 may include a semiconductor device package 310 and a semiconductor device package 311, and the semiconductor device package 310 and the semiconductor device package 311 may be stacked in the vertical direction.

In some embodiments of the present disclosure, the semiconductor device package structure 31 is the same as, or similar to, the semiconductor device package structure 30 shown in FIG. 30, the semiconductor device package 310 is the same as, or similar to, the semiconductor device package 300 shown in FIG. 30, and the semiconductor device package 311 is the same as, or similar to, the semiconductor device package 301 shown in FIG. 30. The difference between the semiconductor device package structure 31 and the semiconductor device package structure 30 is that the adhesives in the semiconductor device package 310 are replaced by heat spreaders 31-2, 31-3 and 31-4 and corresponding thermal interface materials (TIMs), and the adhesive in the semiconductor device package 301 is replaced by heat spreader 31-1 and a TIM. In addition, the semiconductor device package 310 may further have a heat spreader 31-5, and the heat spreader 31-5 may be disposed on an upper of the semiconductor device package 310 using a TIM.

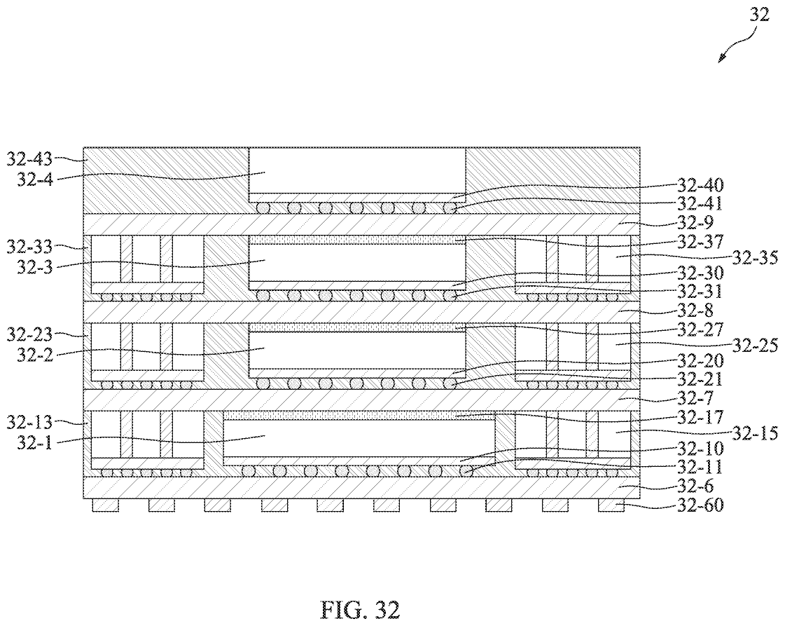

FIG. 32 is a cross-sectional view of a semiconductor device package 32 in accordance with an embodiment of the present disclosure. As shown in FIG. 32, the semiconductor device package 32 may include an electronic component 32-1, an electronic component 32-2 disposed above the electronic component 32-1, an electronic component 32-3 disposed above the electronic component 32-2 and an electronic component 32-4 disposed above the electronic component 32-3. In some embodiments of the present disclosure, the electronic component 32-1 includes a known-good die (KGD), the electronic component 32-2 includes a known-good die (KGD), the electronic component 32-3 includes a known-good die (KGD) and the electronic component 32-4 includes a known-good die (KGD). In some embodiments of the present disclosure, the electronic component 32-1 includes a control die or a memory die, the electronic component 32-2 may include a memory die, the electronic component 32-3 may include a memory die and the electronic component 32-4 may include a memory die.

Referring to FIG. 32, the semiconductor device package 32 may include a redistribution layer 32-6 (RDL 32-6). In some embodiments of the present disclosure, the redistribution layer 32-6 includes a known-good-redistribution layer (KGR). The electronic component 32-1 may be disposed on an upper surface of RDL 32-6. Furthermore, a package material 32-13 may be disposed on the upper surface of RDL 32-6 as well and configured to encapsulate the upper surface of RDL 32-6 and the electronic component 32-1. In some embodiments of the present disclosure, the package material 32-13 includes a molding compound. Moreover, RDL 32-6 may include a plurality of external electrical connections 32-60 disposed on its lower surface. In some embodiments of the present disclosure, the external electrical connections 32-60 include a test/bonding pad.

The electronic component 32-1 has a lower surface facing RDL 32-6. The lower surface of the electronic component 32-1 may include an active surface of the electronic component 32-1. Further, a redistribution layers 32-10 (RDL 32-10) may be disposed on the lower surface of the electronic component 32-1. RDL 32-10 may be electrically connected to the active surface of the electronic component 32-1. A plurality of electrical connections 32-11 may be disposed between the redistribution layers 32-10 and 32-6 and surrounded by the package material 32-13. In some embodiments of the present disclosure, an underfill (or a NCP) is disposed between the redistribution layers 32-10 and 32-6 and the electrical connections 32-11 are surrounded by the underfill. The electrical connections 32-11 may serve to establish electrical connectivity between RDL 32-10 and RDL 32-6. That is, the electronic component 32-1 may be electrically connected to RDL 32-6 through RDL 32-10 and the electrical connections 32-11. In some embodiments of the present disclosure, the electrical connection 32-11 includes a solder bump or a copper pillar micro-bump.

Moreover, a plurality of conductive spacers 32-15 may be disposed on the upper surface of RDL 32-6 and encapsulated by the package material 32-13. The conductive spacers 32-15 may be electrically connected to RDL 32-6. In some embodiments of the present disclosure, the conductive spacer 32-15 is the same as, or similar to, the conductive spacer 14-1 shown in FIG. 14A, the same as, or similar to, the conductive spacer 14-2 shown in FIG. 14B, or the same as, or similar to, the conductive spacer 14-3 shown in FIG. 14C.

The electronic component 32-1, RDL 32-6 and the plurality of conductive spacers 32-15 may be formed as a first sub-assembly. In some embodiments of the present disclosure, a testing process is performed on the first sub-assembly so as to ensure that the sub-assembly is known good.

Referring to FIG. 32, the semiconductor device package 32 may include a redistribution layers 32-7 (RDL 32-7). In some embodiments of the present disclosure, RDL 32-7 includes a known-good-redistribution layer (KGR). RDL 32-7 may be disposed on an upper surface of the package material 32-13. The electronic component 32-1 may be attached to a lower surface of RDL 32-7 through an adhesive 32-17. An upper surface of the conductive spacers 32-15 may abut against the lower surface of RDL 32-7 and thus the conductive spacers 32-15 may be electrically connected to RDL 32-7.

The electronic component 32-2 may be disposed on an upper surface of RDL 32-7. Further, a package material 32-23 may be disposed on the upper surface of RDL 32-7 as well and configured to encapsulate the upper surface of RDL 32-7 and the electronic component 32-2. In some embodiments of the present disclosure, the package material 32-23 includes a molding compound.

The electronic component 32-2 has a lower surface facing RDL layer 32-7. The lower surface of the electronic component 32-2 may include an active surface of the electronic component 32-2. Further, a redistribution layers 32-20 (RDL 32-20) may be disposed on the lower surface of the electronic component 32-2. RDL 32-20 may be electrically connected to the active surface of the electronic component 32-2. A plurality of electrical connections 32-21 may be disposed between the redistribution layers 32-20 and 32-7 and surrounded by the package material 32-23. In some embodiments of the present disclosure, an underfill (or a NCP) is disposed between the redistribution layers 32-20 and 32-7 and the electrical connections 32-21 are surrounded by the underfill. The electrical connections 32-21 may serve to establish electrical connectivity between RDL 32-20 and RDL 32-7. That is, the electronic component 32-2 may be electrically connected to RDL 32-7 through RDL 32-20 and the electrical connections 32-21. In some embodiments of the present disclosure, the electrical connection 32-21 includes a solder bump or a copper pillar micro-bump.

Moreover, a plurality of conductive spacers 32-25 may be disposed on the upper surface of RDL 32-7 and encapsulated by the package material 32-23. The conductive spacers 32-25 may be electrically connected to RDL 32-7. In some embodiments of the present disclosure, the conductive spacer 32-25 is the same as, or similar to, the conductive spacer 14-1 shown in FIG. 14A, the same as, or similar to, the conductive spacer 14-2 shown in FIG. 14B, or the same as, or similar to, the conductive spacer 14-3 shown in FIG. 14C.

The electronic component 32-2, RDL 32-7 and the plurality of conductive spacers 32-25 may be formed as a second sub-assembly. In some embodiments of the present disclosure, a testing process is performed on the second sub-assembly so as to ensure that the sub-assembly is known good.

Referring to FIG. 32, the semiconductor device package 32 may include a redistribution layers 32-8 (RDL 32-8). In some embodiments of the present disclosure, RDL 32-8 includes a known-good-redistribution layer (KGR). RDL 32-8 may be disposed on an upper surface of the package material 32-23. The electronic component 32-2 may be attached to a lower surface of RDL 32-8 through an adhesive 32-27. An upper surface of the conductive spacers 32-25 may abut against the lower surface of RDL 32-8 and thus the conductive spacers 32-25 may be electrically connected to RDL 32-8.

The electronic component 32-3 may be disposed on an upper surface of RDL 32-8. Further, a package material 32-33 may be disposed on the upper surface of RDL 32-8 as well and configured to encapsulate the upper surface of RDL 32-8 and the electronic component 32-3. In some embodiments of the present disclosure, the package material 32-33 includes a molding compound.

The electronic component 32-3 has a lower surface facing RDL 32-8. The lower surface of the electronic component 32-3 may include an active surface of the electronic component 32-3. Further, a redistribution layers 32-30 (RDL 32-30) may be disposed on the lower surface of the electronic component 32-3. RDL 32-30 may be electrically connected to the active surface of the electronic component 32-3. A plurality of electrical connections 32-31 may be disposed between the redistribution layers 32-30 and 32-8 and surrounded by the package material 32-33. In some embodiments of the present disclosure, an underfill (or a NCP) is disposed between the redistribution layers 32-30 and 32-8 and the electrical connections 32-31 are surrounded by the underfill. The electrical connections 32-31 may serve to establish electrical connectivity between RDL 32-30 and RDL 32-8. That is, the electronic component 32-3 may be electrically connected to RDL 32-8 through RDL 32-30 and the electrical connections 32-31. In some embodiments of the present disclosure, the electrical connection 32-31 includes a solder bump or a copper pillar micro-bump.

Moreover, a plurality of conductive spacers 32-35 may be disposed on the upper surface of RDL 32-8 and encapsulated by the package material 32-33. The conductive spacers 32-35 may be electrically connected to RDL 32-8. In some embodiments of the present disclosure, the conductive spacer 32-35 is the same as, or similar to, the conductive spacer 14-1 shown in FIG. 14A, the same as, or similar to, the conductive spacer 14-2 shown in FIG. 14B, or the same as, or similar to, the conductive spacer 14-3 shown in FIG. 14C.

The electronic component 32-3, RDL 32-8 and the plurality of conductive spacers 32-35 may be formed as a third sub-assembly. In some embodiments of the present disclosure, a testing process is performed on the third sub-assembly so as to ensure that the sub-assembly is known good.

Referring to FIG. 32, the semiconductor device package 32 may include a redistribution layers 32-9 (32-9). In some embodiments of the present disclosure, RDL 32-9 includes a known-good-redistribution layer (KGR). RDL 32-9 may be disposed on an upper surface of the package material 32-33. The electronic component 32-3 may be attached to a lower surface of RDL 32-9 through an adhesive 32-37. An upper surface of the conductive spacers 32-35 may abut against the lower surface 32-9 and thus the conductive spacers 32-35 may be electrically connected to RDL 32-9.

The electronic component 32-4 may be disposed on an upper surface of RDL 32-9. Further, a package material 32-43 may be disposed on the upper surface of RDL 32-9 as well and configured to encapsulate the upper surface of RDL 32-9 and the electronic component 32-4. In some embodiments of the present disclosure, the package material 32-43 includes a molding compound or a thick photoresist.

The electronic component 32-4 has a lower surface facing RDL 32-9. The lower surface of the electronic component 32-4 may include an active surface of the electronic component 32-4. Further, a redistribution layers 32-40 (RDL 32-40) may be disposed on the lower surface of the electronic component 32-4. RDL 32-40 may be electrically connected to the active surface of the electronic component 32-4. A plurality of electrical connections 32-41 may be disposed between the redistribution layers 32-40 and 32-9 and surrounded by the package material 32-43. In some embodiments of the present disclosure, an underfill (or a NCP) is disposed between the redistribution layers 32-40 and 32-9 and the electrical connections 32-41 are surrounded by the underfill. The electrical connections 32-41 may serve to establish electrical connectivity between RDL 32-40 and RDL 32-9. That is, the electronic component 32-4 may be electrically connected to RDL 32-9 through RDL 32-40 and the electrical connections 32-41. In some embodiments of the present disclosure, the electrical connection 32-41 includes a solder bump or a copper pillar micro-bump.

The electronic component 32-4 may be pre-tested prior to mounting to ensure it is known good.

In some embodiments of the present disclosure, the semiconductor device package 32 is manufactured by a chip-last/face-down type packaging process.

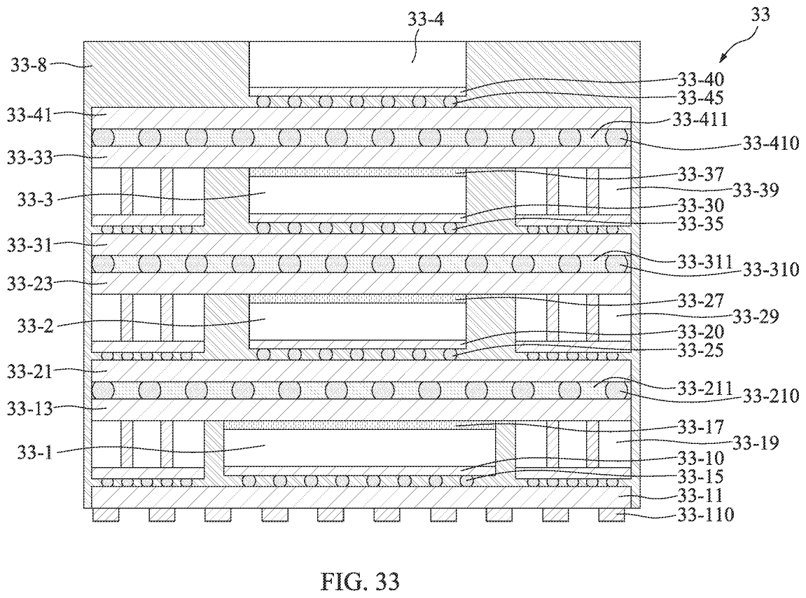

FIG. 33 is a cross-sectional view of a semiconductor device package 33 in accordance with an embodiment of the present disclosure. As shown in FIG. 33, the semiconductor device package 33 may include an electronic component 33-1, an electronic component 33-2 disposed above the electronic component 33-1, an electronic component 33-3 disposed above the electronic component 33-2 and an electronic component 33-4 disposed above the electronic component 33-3. In some embodiments of the present disclosure, the electronic component 33-1 includes a known-good die (KGD), the electronic component 33-2 includes a known-good die (KGD), the electronic component 33-3 includes a known-good die (KGD) and the electronic component 33-4 includes a known-good die (KGD). In some embodiments of the present disclosure, the electronic component 33-1 includes a control die or a memory die, the electronic component 33-2 may include a memory die, the electronic component 33-3 may include a memory die and the electronic component 33-4 may include a memory die.

Referring to FIG. 33, the semiconductor device package 33 may include a redistribution layers 33-11 (RDL 33-11). In some embodiments of the present disclosure, RDL 33-11 includes a known-good-redistribution layer (KGR). The electronic component 33-1 may be disposed on an upper surface of RDL 33-11. Moreover, RDL 33-11 may include a plurality of external electrical connections 33-110 disposed on its lower surface. In some embodiments of the present disclosure, the external electrical connections 33-110 include a test/bonding pad

The electronic component 33-1 has a lower surface facing RDL 33-11. The lower surface of the electronic component 33-1 may include an active surface of the electronic component 33-1. Further, a redistribution layers 33-10 (RDL 33-10) may be disposed on the lower surface of the electronic component 33-1. RDL 33-10 may be electrically connected to the active surface of the electronic component 33-1. A plurality of electrical connections 33-15 may be disposed between the redistribution layers 33-10 and 33-11. In some embodiments of the present disclosure, an underfill or a NCP is disposed between the redistribution layers 33-10 and 33-11 and the electrical connections 33-15 are surrounded by the underfill. The electrical connections 33-15 may serve to establish electrical connectivity between RDL 33-10 and RDL 33-11. That is, the electronic component 33-1 may be electrically connected to RDL 33-11 through RDL 33-10 and the electrical connections 33-15. In some embodiments of the present disclosure, the electrical connection 33-11 includes a solder bump or a copper pillar micro-bump.

Moreover, a plurality of conductive spacers 33-19 may be disposed on the upper surface of RDL 33-11. The conductive spacers 33-19 may be electrically connected to RDL 33-11. In some embodiments of the present disclosure, the conductive spacer 33-19 is the same as, or similar to, the conductive spacer 14-1 shown in FIG. 14A, the same as, or similar to, the conductive spacer 14-2 shown in FIG. 14B, or the same as, or similar to, the conductive spacer 14-3 shown in FIG. 14C.

Moreover, the semiconductor device package 33 may include a redistribution layer 33-13 (RDL 33-13). In some embodiments of the present disclosure, RDL 33-13 includes a known-good-redistribution layer (KGR). RDL 33-13 may be disposed above the electronic component 33-1 and the conductive spacers 33-19. The electronic component 33-1 may be attached to a lower surface of RDL 33-13 through an adhesive 33-17. An upper surface of the conductive spacers 33-19 may abut against the lower surface of RDL 33-13 and thus the conductive spacers 33-19 may be electrically connected to RDL 33-13.

The electronic component 33-1, the redistribution layers 33-11 and 33-13 and the plurality of conductive spacers 33-19 may be formed as a first sub-assembly. In some embodiments of the present disclosure, a testing process is performed on the first sub-assembly so as to ensure that the sub-assembly is known good.

Referring to FIG. 33, the semiconductor device package 33 may include a redistribution layers 33-21 (RDL 33-21), which is disposed above RDL 33-13. In some embodiments of the present disclosure, RDL 33-21 includes a known-good-redistribution layer (KGR). The electronic component 33-2 may be disposed on an upper surface of RDL 33-21. Moreover, a plurality of external electrical connections 33-210 may be disposed between RDL 33-21 and RDL 33-13. The electrical connections 33-210 may electrically connect RDL 33-21 to RDL 33-13. In some embodiments of the present disclosure, the external electrical connection 33-210 includes a solder bump or a copper pillar micro-bump. Moreover, a package material 33-211 may be disposed between the redistribution layer 33-21 and the redistribution layer 33-13 and configured to encapsulate the electrical connections 33-210. In some embodiments of the present disclosure, the package material 33-211 may include an underfill or a NCP.

The electronic component 33-2 has a lower surface facing RDL 33-21. The lower surface of the electronic component 33-2 may include an active surface of the electronic component 33-2. Further, a redistribution layers 33-20 (RDL 33-20) may be disposed on the lower surface of the electronic component 33-2. RDL 33-20 may be electrically connected to the active surface of the electronic component 33-2. A plurality of electrical connections 33-25 may be disposed between the redistribution layers 33-20 and 33-21. In some embodiments of the present disclosure, an underfill (or a NCP) is disposed between the redistribution layers 33-20 and 33-21 and the electrical connections 33-25 are surrounded by the underfill. The electrical connections 33-25 may serve to establish electrical connectivity between RDL 33-20 and RDL 33-21. That is, the electronic component 33-2 may be electrically connected to RDL 33-21 through RDL 33-20 and the electrical connections 33-25. In some embodiments of the present disclosure, the electrical connection 33-25 includes a solder bump or a copper pillar micro-bump.

Moreover, a plurality of conductive spacers 33-29 may be disposed on the upper surface of RDL 33-21. The conductive spacers 33-29 may be electrically connected to RDL 33-21. In some embodiments of the present disclosure, the conductive spacers 33-29 is the same as, or similar to, the conductive spacer 14-1 shown in FIG. 14A, the same as, or similar to, the conductive spacer 14-2 shown in FIG. 14B, or the same as, or similar to, the conductive spacer 14-3 shown in FIG. 14C.

Moreover, the semiconductor device package 33 may include a redistribution layers 33-23 (RDL 33-23). In some embodiments of the present disclosure, RDL 33-23 includes a known-good-redistribution layer (KGR). RDL 33-23 may be disposed above the electronic component 33-2 and the conductive spacers 33-29. The electronic component 33-2 may be attached to a lower surface of RDL 33-23 through an adhesive 33-27. An upper surface of the conductive spacers 33-29 may abut against the lower surface of RDL 33-23 and thus the conductive spacers 33-29 may be electrically connected to RDL 33-23.

The electronic component 33-2, the redistribution layers 33-21 and 33-23 and the plurality of conductive spacers 33-29 may be formed as a second sub-assembly. In some embodiments of the present disclosure, a testing process is performed on the second sub-assembly so as to ensure that the sub-assembly is good.

Referring to FIG. 33, the semiconductor device package 33 may include a redistribution layers 33-31 (RDL 33-31), which is disposed above RDL 33-23. In some embodiments of the present disclosure, RDL 33-31 includes a known-good-redistribution layer (KGR). The electronic component 33-3 may be disposed on an upper surface of RDL 33-31. Moreover, a plurality of external electrical connections 33-310 may be disposed between RDL 33-31 and RDL 33-23. The electrical connections 33-310 may electrically connect RDL 33-31 to RDL 33-23. In some embodiments of the present disclosure, the external electrical connection 33-310 includes a solder bump or a copper pillar micro-bump. Moreover, a package material 33-311 may be between RDL 33-31 and RDL 33-23 and configured to encapsulate the electrical connections 33-310. In some embodiments of the present disclosure, the package material 33-311 may include an underfill or a NCP.

The electronic component 33-3 has a lower surface facing RDL 33-31. The lower surface of the electronic component 33-3 may include an active surface of the electronic component 33-3. Further, a redistribution layers 33-30 (RDL 33-30) may be disposed on the lower surface of the electronic component 33-3. RDL 33-30 may be electrically connected to the active surface of the electronic component 33-3. A plurality of electrical connections 33-35 may be disposed between the redistribution layers 33-30 and 33-31. In some embodiments of the present disclosure, an underfill (or a NCP) is disposed between the redistribution layers 33-30 and 33-31 and the electrical connections 33-35 are surrounded by the underfill. The electrical connections 33-35 may serve to establish electrical connectivity between RDL 33-30 and RDL 33-31. That is, the electronic component 33-3 may be electrically connected to RDL 33-31 through RDL 33-30 and the electrical connections 33-35. In some embodiments of the present disclosure, the electrical connection 33-35 includes a solder bump.

Moreover, a plurality of conductive spacers 33-39 may be disposed on the upper surface of RDL 33-31. The conductive spacers 33-39 may be electrically connected to RDL 33-31. In some embodiments of the present disclosure, the conductive spacers 33-39 is the same as, or similar to, the conductive spacer 14-1 shown in FIG. 14A, the same as, or similar to, the conductive spacer 14-2 shown in FIG. 14B, or the same as, or similar to, the conductive spacer 14-3 shown in FIG. 14C.

Moreover, the semiconductor device package 33 may include a redistribution layers 33-33 (RDL 33-33). In some embodiments of the present disclosure, RDL 33-33 includes a known-good-redistribution layer (KGR). RDL 33-33 may be disposed above the electronic component 33-3 and the conductive spacers 33-39. The electronic component 33-3 may be attached to a lower surface of RDL 33-33 through an adhesive 33-37. An upper surface of the conductive spacers 33-39 may abut against the lower surface of RDL 33-33 and thus the conductive spacers 33-39 may be electrically connected to the redistribution layer 33-33.

The electronic component 33-3, the redistribution layers 33-31 and 33-33 and the plurality of conductive spacers 33-39 may be formed as a third sub-assembly. In some embodiments of the present disclosure, a testing process is performed on the third sub-assembly so as to ensure that the sub-assembly is good.

Referring to FIG. 33, the semiconductor device package 33 may include a redistribution layers 33-41 (RDL 33-41), which is disposed above RDL 33-33. In some embodiments of the present disclosure, RDL 33-41 includes a known-good-redistribution layer (KGR). The electronic component 33-4 may be disposed on an upper surface of RDL 33-41. Moreover, a plurality of external electrical connections 33-410 may be disposed between RDL 33-41 and RDL 33-33. The electrical connections 33-410 may electrically connect RDL 33-41 to RDL 33-33. In some embodiments of the present disclosure, the external electrical connection 33-410 includes a solder bump or a copper pillar micro-bump. Moreover, a package material 33-411 may be between RDL 33-41 and RDL 33-33 and configured to encapsulate the electrical connections 33-410. In some embodiments of the present disclosure, the package material 33-411 may include an underfill or a NCP.

The electronic component 33-4 has a lower surface facing RDL 33-41. The lower surface of the electronic component 33-4 may include an active surface of the electronic component 33-4. Further, a redistribution layers 33-40 (RDL 33-40) may be disposed on the lower surface of the electronic component 33-4. RDL 33-40 may be electrically connected to the active surface of the electronic component 33-4. A plurality of electrical connections 33-45 may be disposed between the redistribution layers 33-40 and 33-41. In some embodiments of the present disclosure, an underfill (or a NCP) is disposed between the redistribution layers 33-40 and 33-41 and the electrical connections 33-45 are surrounded by the underfill. The electrical connections 33-45 may serve to establish electrical connectivity between RDL 33-40 and RDL 33-41. That is, the electronic component 33-4 may be electrically connected to RDL 33-41 through RDL 33-40 and the electrical connections 33-45. In some embodiments of the present disclosure, the electrical connection 33-41 includes a solder bump or a copper pillar micro-bump.

The electronic component 33-4 and RDL 33-41 may be formed as a fourth sub-assembly. In some embodiments of the present disclosure, a testing process is performed on the fourth sub-assembly so as to ensure that the sub-assembly is good.

Further, the semiconductor device package 33 may include a package material 33-8. The package material 33-8 is configured to encapsulate the electronic components 33-1, 33-2, 33-3 and 33-4, the redistribution layers 33-11, 33-13, 33-21, 33-23, 33-31, 33-33 and 33-41 and the conductive spacers 33-19, 33-29 and 33-39. In some embodiments of the present disclosure, the package material 33-8 includes a molding compound or a thick photoresist.

In some embodiments of the present disclosure, the semiconductor device package 33 is manufactured by a chip-last/face-down type packaging process. It is worth noting that the process described above to form the semiconductor device package 33 allows each fan-out package layer to be separately processed and tested to ensure know-good layers prior to their assembly to form the final device package.

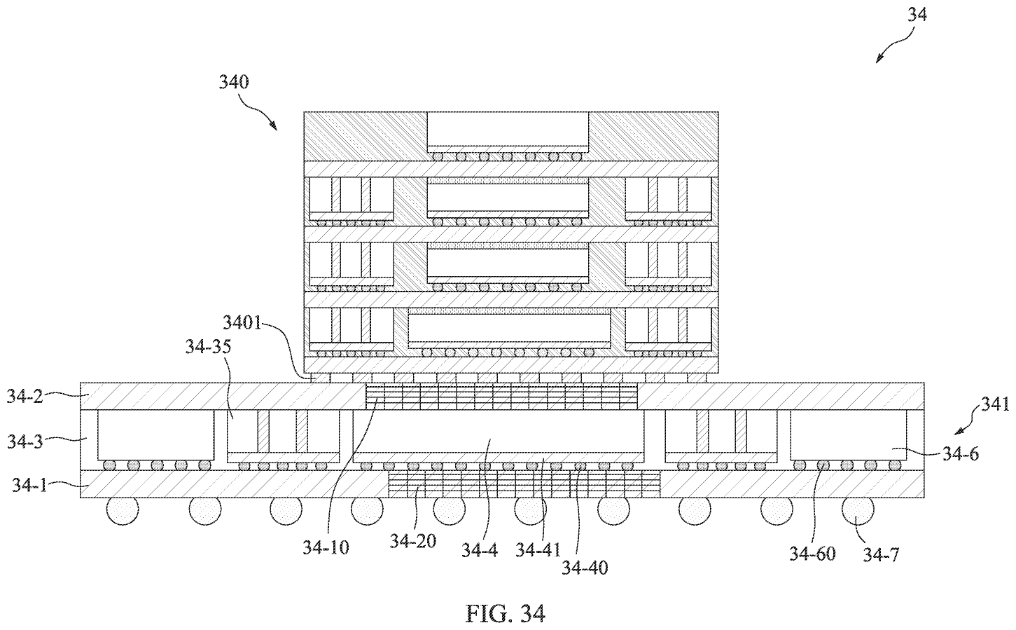

FIG. 34 is a cross-sectional view of a semiconductor device package structure 34 in accordance with an embodiment of the present disclosure. As shown in FIG. 34, the semiconductor device package structure 34 may include a semiconductor device package 340 and a semiconductor device package 341, and the semiconductor device package 340 and the semiconductor device package 341 may be stacked in the vertical direction.

Referring to FIG. 34, the semiconductor device package 340 is disposed above the semiconductor device package 341. In some embodiments of the present disclosure, the semiconductor device package 340 is the same as, or similar to, the semiconductor device package 32 shown in FIG. 32.

The semiconductor device package 341 may include redistribution layers 34-1 and 34-2 (RDL 34-1 and RDL 34-2), electronic components 34-4 and 34-6 and a package material 34-3. The electronic component 34-4 may be disposed on an upper surface of the redistribution layer 34-1. The electronic component 34-4 may have an active surface facing RDL 34-1. Further, a redistribution layer 34-41 (RDL 34-41) may be disposed on the lower surface of the electronic component 34-4 and electrically connected to the active surface of the electronic component 34-4. A plurality of electrical connections 34-40 may be disposed between the redistribution layers 34-41 and 34-1. In some embodiments of the present disclosure, an underfill (or a NCP) is disposed between the redistribution layers 34-41 and 34-1 and the electrical connections 34-40 are surrounded by the underfill. The electrical connections 34-40 may serve to establish electrical connectivity between RDL 34-41 and RDL 34-1. That is, the electronic component 34-4 may be electrically connected to RDL 34-1 through RDL 34-41 and the electrical connections 33-40. In some embodiments of the present disclosure, the electrical connection 33-40 includes a solder bump or a copper pillar micro-bump. Further, the electronic component 34-4 may be attached to the lower surface of RDL 34-2. In some embodiments of the present disclosure, the electronic component 34-4 includes a processor, a control IC or a memory device. In some embodiments of the present disclosure, the electronic component 34-4 is located directly below the semiconductor device package 340.

Moreover, at least one electronic component 34-6 may be disposed on an upper surface of RDL 34-1 and electrically connected to RDL 34-1 through the electrical connections 34-60. In some embodiments of the present disclosure, an underfill (or a NCP) is disposed between the electronic component 34-6 and the redistribution layer 34-1 and configured to surround the electrical connections 34-60. Further, a cross-sectional width of the electronic component 34-6 may be less than a cross-sectional width of the electronic component 34-4.

Further, the package material 34-3 may be disposed between RDL 34-1 and RDL 34-2 and configured to encapsulate the electronic components 34-4 and 34-6, the upper surface of RDL 34-1 and the lower surface of RDL 34-2. A plurality of conductive spacers 34-35 may be encapsulated by the package material 34-3 and configured to electrically connect RDL 34-1 to RDL 34-2. In some embodiments of the present disclosure, the conductive spacer 34-35 is the same as, or similar to, the conductive spacer 14-1 shown in FIG. 14A, the same as, or similar to, the conductive spacer 14-2 shown in FIG. 14B, or the same as, or similar to, the conductive spacer 14-3 shown in FIG. 14C.

The semiconductor device package 341 may include a plurality of the electrical connections 34-7 on a lower surface of the redistribution layer 34-1. The electrical connections 34-7 may be electrically connected to the redistribution layer 34-1. In some embodiments of the present disclosure, the electrical connection 34-7 includes a BGA ball.

As shown in FIG. 34, the semiconductor device package 340 may be disposed on an upper surface of RDL 34-2 of the semiconductor device package 341. The semiconductor device package 340 may be electrically connected to RDL 34-2 of the semiconductor device package 341 through the electrical connections 3401. In some embodiments of the present disclosure, an underfill or a NCP is arranged between the semiconductor device package 340 and the semiconductor device package 341 and configured to surround the electrical connections 3401. In addition, RDL 34-1 and/or RDL 34-2 may contain thermal vias and/or planes 34-10 to facilitate heat dissipation.

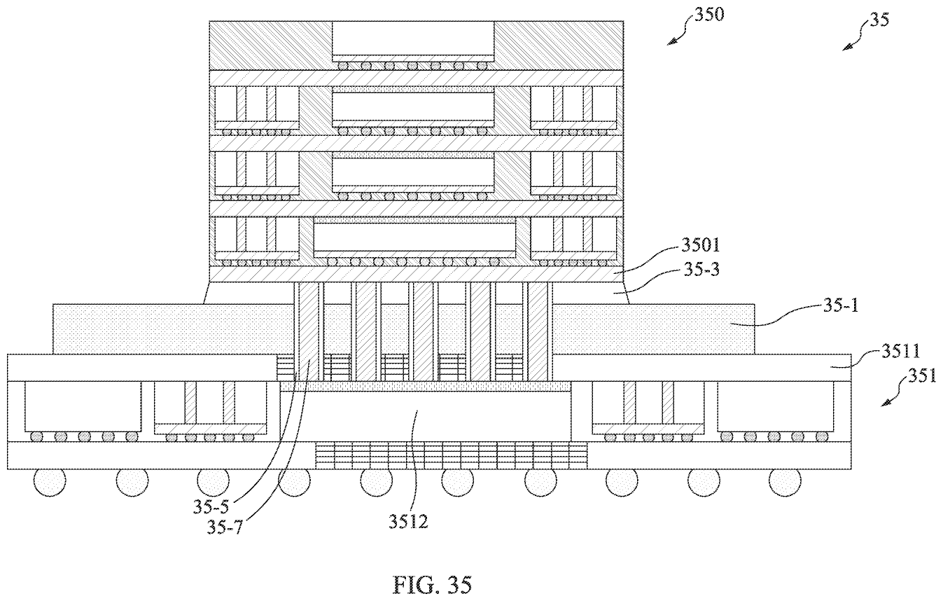

FIG. 35 is a cross-sectional view of a semiconductor device package structure 35 in accordance with an embodiment of the present disclosure. As shown in FIG. 35, the semiconductor device package structure 35 may include a semiconductor device package 350 and a semiconductor device package 351, and the semiconductor device package 350 and the semiconductor device package 351 may be stacked in the vertical direction.

In some embodiments of the present disclosure, the semiconductor device package 350 is the same as, or similar to, the semiconductor device package 340 shown in FIG. 34, and the semiconductor device package 351 is similar to, the semiconductor device package 341 shown in FIG. 34.

As shown in FIG. 35, the semiconductor device package structure 35 may include a heat spreader 35-1 disposed between the semiconductor device package 350 and the semiconductor device package 351. In some embodiments of the present disclosure, the heat spreader 35-1 includes a High-TC heat spreader. The heat spreader 35-1 may be disposed on a redistribution layer 3511 (RDL 3511) of the semiconductor device package 351. Further, a package material 35-3 may be disposed between the heat spreader 35-1 and the semiconductor device package 350. In some embodiments of the present disclosure, the package material 35-3 includes an underfill or a NCP.

The semiconductor device package structure 35 may include a plurality of through holes 35-5. The through holes 35-5 may extend from a redistribution layer 3501 (RDL 3501) of the semiconductor device package 350 to an electronic component 3512 of the semiconductor device package 351 and pass through the package material 35-3, the heat spreader 35-1 and RDL 3511 of the semiconductor device package 351. In some embodiments of the present disclosure, the electronic component 3512 includes a processor, a control IC or a memory device. Moreover, each of the through holes 35-5 may include an electrical connection 35-7. The electrical connections 35-7 may electrically connect RDL 3501 of the semiconductor device package 350 to the semiconductor device package 351. In some embodiments of the present disclosure, the electrical connection 35-7 includes a tall metal pillar bump.

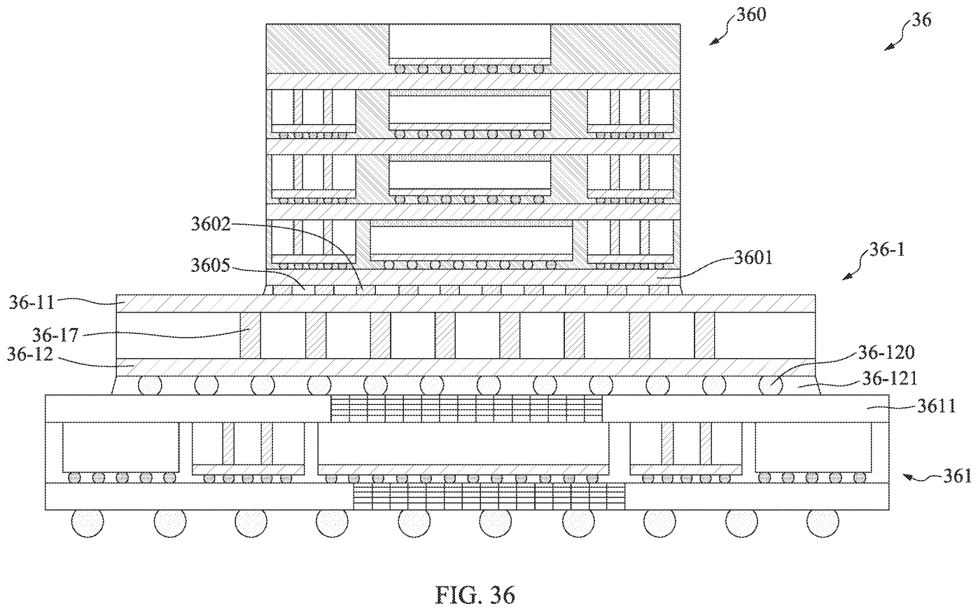

FIG. 36 is a cross-sectional view of a semiconductor device package structure 36 in accordance with an embodiment of the present disclosure. As shown in FIG. 36, the semiconductor device package structure 36 may include a semiconductor device package 360 and a semiconductor device package 361, and the semiconductor device package 360 and the semiconductor device package 361 may be stacked with each other.

In some embodiments of the present disclosure, the semiconductor device package 360 is the same as, or similar to, the semiconductor device package 340 shown in FIG. 34, and the semiconductor device package 361 is the same as, or similar to, the semiconductor device package 341 shown in FIG. 34.

As shown in FIG. 36, the semiconductor device package structure 36 may include an interposer 36-1 disposed between the semiconductor device package 360 and the semiconductor device package 361. In some embodiments of the present disclosure, the interposer 36-1 includes a High-TC, Low-CTE interposer. The interposer 36-1 may include a redistribution layer 36-11 (RDL 36-11) disposed at its upper surface, a redistribution layer 36-12 (RDL 36-12) disposed at its lower surface and a plurality of TSVs 36-17 electrically connecting RDL 36-11 to RDL 36-12.

The interposer 36-1 may be disposed on RDL 3611 of the semiconductor device package 361. RDL 36-12 of the interposer 36-1 may be electrically connected to RDL 3611 of the semiconductor device package 361 through a plurality of electrical connections 36-120. In some embodiments of the present disclosure, the electrical connection 36-120 includes a solder bump or a copper pillar micro-bump. Further, a package material 36-121 may be disposed between the interposer 36-1 and the semiconductor device package 361 and configured to surround the electrical connections 36-120. In some embodiments of the present disclosure, the package material 36-121 includes an underfill or a NCP.

Moreover, the interposer 36-1 may be disposed under a redistribution layer 3601 (RDL 3601) of the semiconductor device package 360. The redistribution layer 36-11 (RDL 36-11) of the interposer 36-1 may be electrically connected to RDL 3601 of the semiconductor device package 360 through the electrical connections 3602. Further, a package material 3605 may be disposed between the interposer 36-1 and the semiconductor device package 360 and configured to surround the electrical connections 3602. In some embodiments of the present disclosure, the package material 3605 includes an underfill or a NCP.

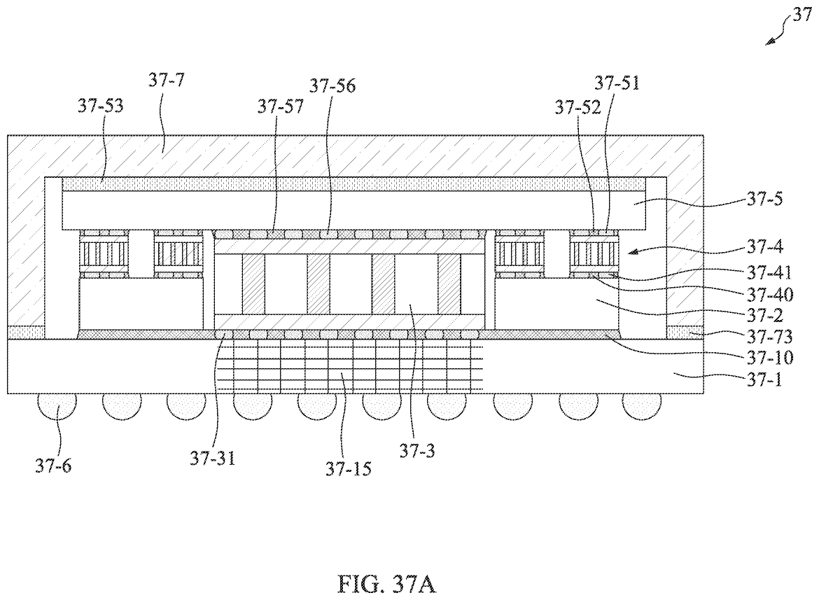

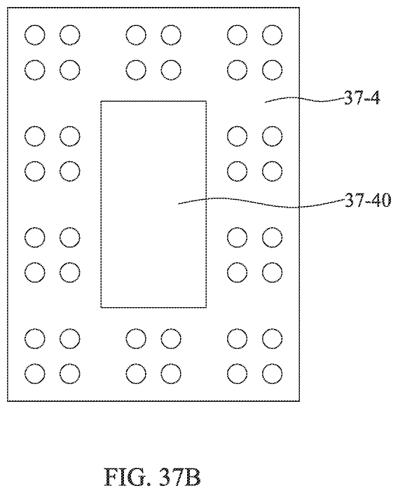

FIG. 37A is a cross-sectional view of a semiconductor device package 37 in accordance with an embodiment of the present disclosure. As shown in FIG. 37A, the semiconductor device package 37 may include a substrate 37-1, electronic components 37-2, and 37-5, conductive spacers 37-3 and 37-4, a heat spreader 37-7 and a TIM 37-53. As shown in FIG. 37A, an air gap exists between adjacent conductive spacers 37-4 to help block the heat from the electronic component 37-2 which can be a processor from reaching the electronic component 37-2 which can be a memory device. Referring to FIG. 37A, the substrate 37-1 may include a plurality of electrical connections 37-6 at its lower surface. The electrical connections 37-6 may be electrically connected to the substrate 37-1. In some embodiments of the present disclosure, the electrical connection 37-6 includes a solder bump or a copper pillar micro-bump. Moreover, the substrate 37-1 may include thermal vias and planes 37-15 to help dissipate the heat from the electronic component 37-5. In some embodiments of the present disclosure, the substrate 37-1 includes a High-TC, Low-CTE substrate.

Moreover, the conductive spacers 37-3 and 37-4 are stacked above the substrate 37-1 and the electronic component 37-2, respectively. In some embodiments of the present disclosure, each of the conductive spacers 37-3 and 37-4 is the same as, or similar to, the conductive spacer 14-1 shown in FIG. 14A, the same as, or similar to, the conductive spacer 14-2 shown in FIG. 14B, or the same as, or similar to, the conductive spacer 14-3 shown in FIG. 14C. The conductive spacers 37-3 may be electrically connected to the substrate through the electrical connections 37-31. In some embodiments of the present disclosure, the electrical connection 37-31 includes a solder bump or a copper pillar micro-bump. Furthermore, a package material 37-10 is disposed between the conductive spacers 37-3 and the upper surface of the substrate 37-1 and configured to surround the electrical connections 37-31. In some embodiments of the present disclosure, the package material 37-10 includes an underfill or a NCP. Conductive spacers 37-4 are stacked atop the electronic components 37-2 in a way similar to stacking conductive spacers 37-3 on top of the substrate.

The electronic component 37-5 may be disposed above the conductive spacers 37-3 and 37-4. The electronic component 37-5 may be electrically connected to the conductive spacers 37-3 through the electrical connections 37-56. Further, a package material 37-57 may be disposed between the conductive spacers 37-3 and the electronic component 37-5 and configured to surround the electrical connections 37-56. The electronic component 37-5 may be electrically connected to the conductive spacers 37-4 through the electrical connections 37-51. Further, a package material 37-52 may be disposed between the conductive spacers 37-4 and the electronic component 37-5 and configured to surround the electrical connections 37-51. In some embodiments of the present disclosure, the electronic component 37-5 includes a processor and the electronic component 37-2 includes a memory device.

The heat spreader 37-7 may be disposed on the substrate 37-1 using a TIM and configured to be thermally coupled to the electronic components 37-2 and 37-5, the conductive spacers 37-3 and 37-4 and the substrate 37-1 containing the thermal vias and planes 37-15. In some embodiments of the present disclosure, the heat spreader 37-7 includes a High-TC heat spreader. In some embodiments of the present disclosure, the heat spreader 37-7 includes a heat spreader, a vapor chamber, a combination of a heat spreader and a vapor chamber or a cold plate for liquid cooling. The heat spreader 37-7 may be attached to the upper surface of the substrate 37-1 through an adhesive 37-73. Moreover, the electronic component 37-5 may be attached to the heat spreader 37-7 through a TIM 37-53.

FIG. 37B is a top view of a conductive spacer 37-4 in accordance with an embodiment of the present disclosure. As shown in FIG. 37B, the conductive spacer may be square-ring-shaped with a large opening 37-40 to accommodate the conductive spacer 37-3 (as shown in FIG. 37A) wherein the circular holes can be enlarged as needed to provide larger air gaps.

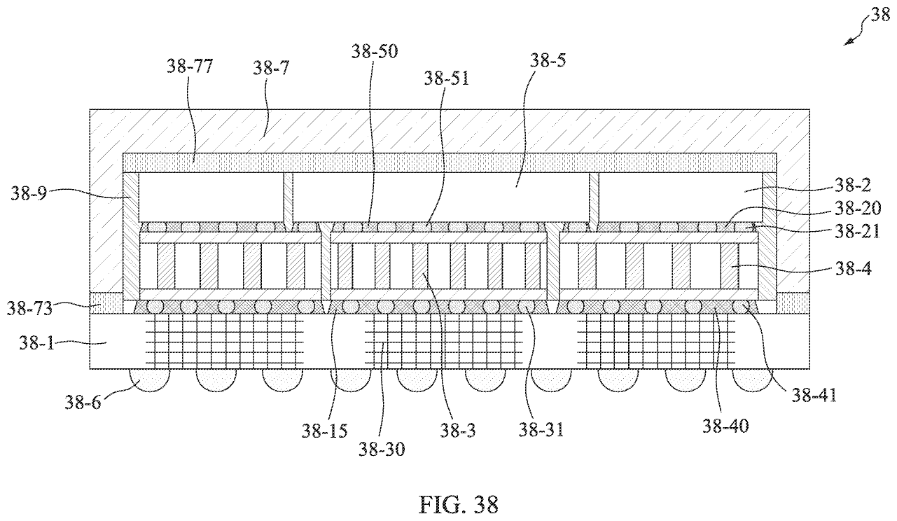

FIG. 38 is a cross-sectional view of a semiconductor device package 38 in accordance with an embodiment of the present disclosure. As shown in FIG. 38, the semiconductor device package 38 may include a substrate 38-1, electronic components 38-2 and 38-5, conductive spacers 38-3 and 38-4, a heat spreader 38-7 and a TIM 38-77. Referring to FIG. 38, the substrate 38-1 may include a plurality of electrical connections 38-6 at its lower surface. The electrical connections 38-6 may be electrically connected to the substrate 38-1 In some embodiments of the present disclosure, the electrical connections 38-6 includes a BGA ball. Moreover, the substrate 38-1 may include thermal vias and planes 38-30. In some embodiments of the present disclosure, the substrate 38-1 includes a High-TC, Low-CTE substrate.

Moreover, the conductive spacers 38-3 and 38-4 are disposed on an upper surface of the substrate 38-1. In some embodiments of the present disclosure, each of the conductive spacer 38-3 and 38-4 is the same as, or similar to, the conductive spacer 14-1 shown in FIG. 14A, the same as, or similar to, the conductive spacer 14-2 shown in FIG. 14B, or the same as, or similar to, the conductive spacer 14-3 shown in FIG. 14C. The conductive spacers 38-3 and 38-4 may be electrically connected to the substrate through the electrical connections 38-41. In some embodiments of the present disclosure, the electrical connection 38-41 includes a solder bump or a copper pillar micro-bump. Further, a package material 38-40 is disposed between the conductive spacers 38-3 and 38-4, and the upper surface of the substrate 38-1 and configured to surround the electrical connections 38-31.

In some embodiments of the present disclosure, the conductive spacers 38-3 have high-I/O count and the conductive spacers 38-4 have lower I/O counts. That is, the I/O counts of the conductive spacers 38-3 may be greater than the I/O counts of the conductive spacers 38-4.

The electronic component 38-5 may be disposed above the conductive spacers 38-3 and 38-4. The electronic component 38-5 may be electrically connected to the conductive spacers 38-3 and 38-4 through the electrical connections 38-51. In some embodiments of the present disclosure, the electronic component 38-5 includes a processor. Further, a package material 38-50 may be disposed between the conductive spacers 38-3 and 38-4, and the electronic component 38-5 and configured to surround the electrical connections 38-51. In some embodiments of the present disclosure, the package material 38-50 includes an underfill or a NCP.

The electronic component 38-2 may be disposed above the conductive spacers 38-4. The electronic component 38-2 may be electrically connected to the conductive spacers 38-4 through the electrical connections 38-21. In some embodiments of the present disclosure, the electronic component 38-2 includes a memory die. Further, a package material 38-20 may be disposed between the conductive spacers 38-4 and the electronic component 38-2 and configured to surround the electrical connections 38-21. In some embodiments of the present disclosure, the package material 38-20 includes an underfill or a NCP.

The heat spreader 38-7 may be disposed on the substrate 38-1 and configured to be thermally coupled to the electronic components 38-2 and 38-5, the conductive spacers 38-3 and 38-4 and the substrate 38-1. In some embodiments of the present disclosure, the heat spreader 38-7 includes a High-TC spreader. In some embodiments of the present disclosure, the heat spreader 38-7 includes a heat spreader, a vapor chamber, a combination of a heat spreader and a vapor chamber or a cold plate for liquid cooling. The heat spreader 38-7 may be attached to the upper surface of the substrate 38-1 through an adhesive 38-73. Moreover, the electronic components 38-2 and 38-5 may be attached to the heat spreader 38-7 through a TIM 38-77.

Moreover, a package material 38-9 is disposed on the upper surface of the substrate 38-1 and arranged within the heat spreader 38-7. The package material 38-9 may encapsulate the upper surface of the substrate 38-1, the electronic components 38-2 and 38-5 and the conductive spacers 38-3 and 38-4. In some embodiments of the present disclosure, the package material 38-9 includes a molding compound or a thick photoresist.

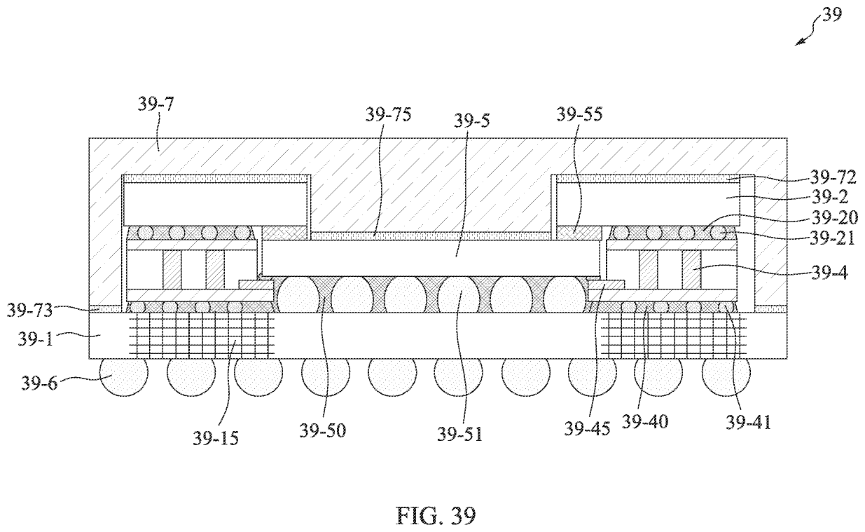

FIG. 39 is a cross-sectional view of a semiconductor device package 39 in accordance with an embodiment of the present disclosure. As shown in FIG. 39, the semiconductor device package 39 may include a substrate 39-1, electronic components 39-2 and 39-5, conductive spacers 39-4, a heat spreader 39-7 and a TIM 39-75. Referring to FIG. 39, the substrate 39-1 may include a plurality of electrical connections 39-6 at its lower surface. The electrical connections 39-6 may be electrically connected to the substrate 39-1. In some embodiments of the present disclosure, the electrical connection 39-6 includes a BGA ball. Moreover, the substrate 39-1 may include thermal vias and planes 39-15. In some embodiments of the present disclosure, the substrate 39-1 includes a High-TC, Low-CTE substrate.

The electronic component 39-5 may be disposed on the upper surface of the substrate 39-1. In some embodiments of the present disclosure, the electronic component 39-5 includes a processor. The electronic component 39-5 may be electrically connected to the substrate 39-1 through the electrical connections 39-51. In some embodiments of the present disclosure, the electrical connection 39-51 includes a solder bump or a copper pillar micro-bump. Further, a package material 39-50 is disposed between the electronic component 39-5 and the upper surface of the substrate 39-1 and configured to surround the electrical connections 39-51.

The conductive spacers 39-4 are disposed on an upper surface of the substrate 39-1 and adjacent and side-by-side to the electronic component 39-5. In some embodiments of the present disclosure, the conductive spacer 39-4 is the same as, or similar to, the conductive spacer 14-3 shown in FIG. 14C. The conductive spacers 39-4 may be electrically connected to the substrate 39-1 through the electrical connections 39-41. In some embodiments of the present disclosure, the electrical connection 39-41 includes a solder bump or a copper pillar micro-bump. Further, a package material 39-40 is disposed between the conductive spacers 39-4 and the upper surface of the substrate 39-1 and configured to surround the electrical connections 39-41. Moreover, the conductive spacer 39-4 may be electrically connected to the electronic component 39-5 through an edge connector 39-45.

The electronic component 39-2 may be disposed above the conductive spacers 39-4 and the electronic component 39-5. The electronic components 39-2 may be electrically connected to the conductive spacer 39-4 through the electrical connections 39-21. In some embodiments of the present disclosure, the electronic component 39-2 includes a memory die. Further, a package material 39-20 may be disposed between the conductive spacers 39-4 and the electronic components 39-2 and configured to surround the electrical connections 39-21. In some embodiments of the present disclosure, the package material 39-20 includes an underfill or a NCP. Moreover, an adhesive 39-55 may be disposed between the electronic component 39-2 and the electronic component 39-5.

The heat spreader 39-7 may be disposed on the substrate 39-1 and configured to be thermally coupled with the electronic components 39-2 and 39-5, the conductive spacers 39-3 and 39-4 and the substrate 39-1. In some embodiments of the present disclosure, the heat spreader 39-7 includes a High-TC, heat spreader. In some embodiments of the present disclosure, the heat spreader 39-7 includes a heat spreader, a vapor chamber, a combination of a heat spreader and a vapor chamber or a cold plate for liquid cooling. The heat spreader 39-7 may be attached to the upper surface of the substrate 39-1 through a HTC (High-Thermal-Conductivity) adhesive 39-73. Moreover, the electronic components 39-2 may be attached to the heat spreader 39-7 through a TIM 39-72 and the electronic component 39-5 may be attached to the heat spreader 39-7 through a TIM 39-75.

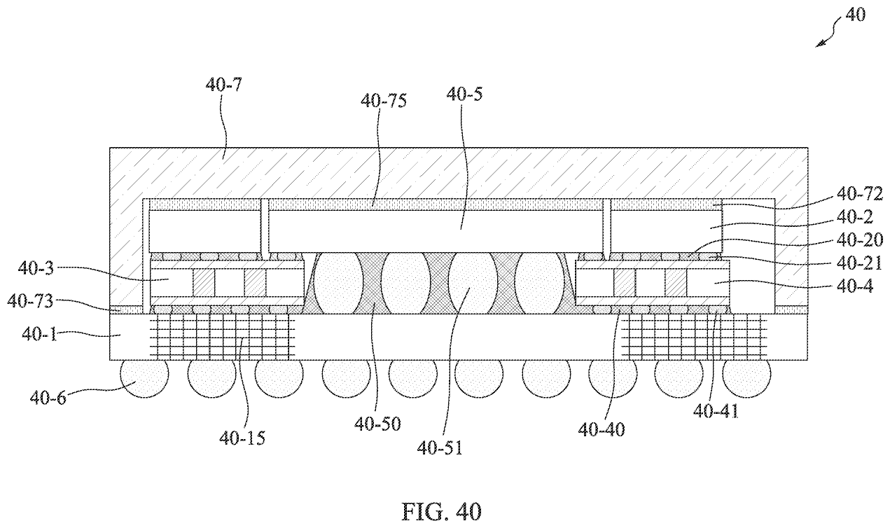

FIG. 40 is a cross-sectional view of a semiconductor device package 40 in accordance with an embodiment of the present disclosure. As shown in FIG. 40, the semiconductor device package 40 may include a substrate 40-1, electronic components 40-2 and 40-5, conductive spacers 40-4, a heat spreader 40-7 and a TIM 40-75. Referring to FIG. 40, the substrate 40-1 may include a plurality of electrical connections 40-6 at its lower surface. The electrical connections 40-6 may be electrically connected to the substrate 40-1. In some embodiments of the present disclosure, the electrical connection 40-6 includes a BGA ball. Moreover, the substrate 40-1 may include thermal vias and planes 40-15. In some embodiments of the present disclosure, the substrate 40-1 includes a HTC, LTC substrate.

The electronic component 40-5 may be disposed on the upper surface of the substrate 40-1. In some embodiments of the present disclosure, the electronic component 40-5 includes a processor. The electronic component 40-5 may be electrically connected to the substrate 40-1 through the electrical connections 40-51. In some embodiments of the present disclosure, the electrical connection 40-51 includes a solder bump or copper pillar micro-bump. Furthermore, a package material 40-50 is disposed between the electronic component 40-5 and the upper surface of the substrate 40-1 and configured to surround the electrical connections 40-51.

The conductive spacers 40-4 are disposed on an upper surface of the substrate 40-1 and adjacent to the package material 40-50. In some embodiments of the present disclosure, the conductive spacer 40-4 is the same as, or similar to, the conductive spacer 14-1 shown in FIG. 14A, the same as, or similar to, the conductive spacer 14-2 shown in FIG. 14B, or the same as, or similar to, the conductive spacer 14-3 shown in FIG. 14C. The conductive spacers 40-4 may be electrically connected to the substrate 40-1 through the electrical connections 40-41. In some embodiments of the present disclosure, the electrical connection 40-41 includes a solder bump or a copper pillar micro-bump. Further, a package material 40-40 is disposed between the conductive spacers 40-4 and the upper surface of the substrate 40-1 and configured to surround the electrical connections 40-41.

The electronic components 40-2 may be disposed above the conductive spacers 40-4 and adjacent to the electronic component 40-5. The electronic components 40-2 may be electrically connected to the conductive spacers 40-4 through the electrical connections 40-21. In some embodiments of the present disclosure, the electronic component 40-2 includes a memory die. Further, a package material 40-20 may be disposed between the conductive spacers 40-4 and the electronic components 40-2 and configured to surround the electrical connections 40-21. In some embodiments of the present disclosure, the package material 40-20 includes an underfill or a NCP.

The heat spreader 40-7 may be disposed on the substrate 40-1 and configured to be thermally coupled to the electronic components 40-2 and 40-5, the conductive spacers 40-3 and 40-4 and the substrate 40-1. In some embodiments of the present disclosure, the heat spreader 40-7 includes a HTC heat spreader. In some embodiments of the present disclosure, the heat spreader 40-7 includes a heat spreader, a vapor chamber, a combination of a heat spreader and a vapor chamber or a cold plate for liquid cooling. The heat spreader 40-7 may be attached to the upper surface of the substrate 40-1 through an adhesive 40-73. Moreover, the electronic component 40-2 may be attached to the heat spreader 40-7 through an adhesive 40-72 and the electronic component 40-5 may be attached to the heat spreader 40-7 through an adhesive 40-75.

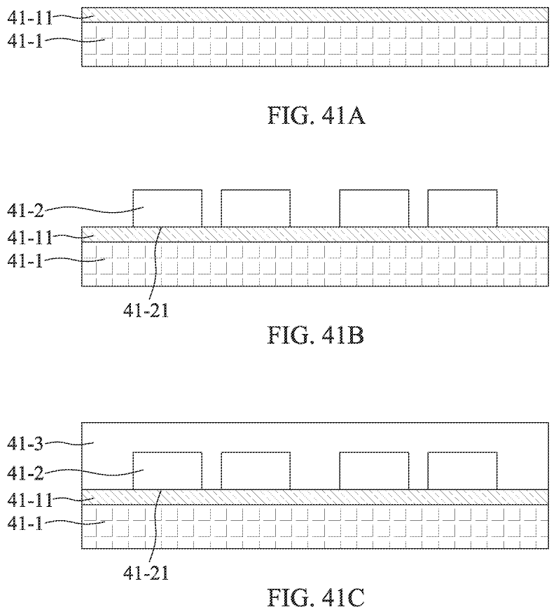

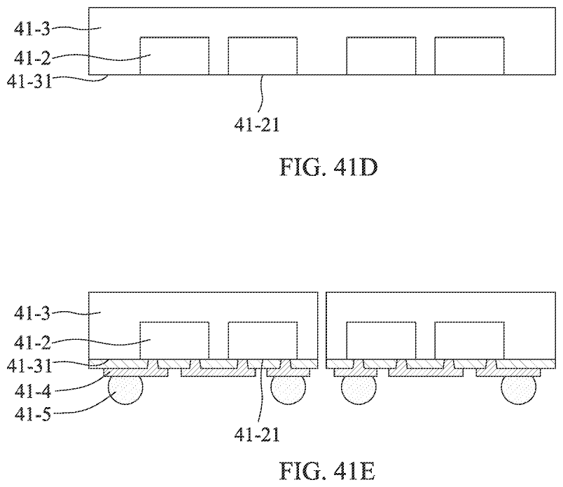

FIGS. 41A to 41E illustrate one or more stages of an example of a method for manufacturing a semiconductor device package in accordance with some embodiments of the present disclosure.

Referring to FIG. 41A, a carrier 41-1 is provided. Further, a temporary layer 41-11 may be disposed on the upper surface of the carrier 41-1. In some embodiments of the present disclosure, the temporary layer 41-11 includes a release layer and/or a release/adhesive layer.

Referring to FIG. 41B, a plurality of electronic components 41-2 are provided. In some embodiments of the present disclosure, the electronic component 41-2 includes a known-good-die (KGD). The electronic components 41-2 may be disposed on the upper surface of the carrier 41-1. Further, the electronic component 41-2 may include an active surface 41-21 facing the upper surface of the carrier 41-1 and abut the temporary layer 41-11.

Referring to FIG. 41C, a package material 41-3 is provided. The package material 41-3 may be disposed on the upper surface of the carrier 41-1 and configured to encapsulate the electronic components 41-2. In some embodiments of the present disclosure, the package material 41-3 includes a molding compound or a thick photoresist.

Referring to FIG. 41D, the carrier 41-1 with the temporary layer 41-11 is removed. The active surfaces 41-21 of the electronic components 41-2 may be exposed at a lower surface 41-31 of the package material 41-3.

Referring to FIG. 41E, a redistribution layer 41-4 (RDL 41-4) with electrical connections 41-5 is provided. RDL 41-4 with the electrical connections 41-5 may be disposed on the lower surface 41-31 of the package material 41-3. The active surfaces 41-21 of the electronic components 41-2 may be electrically connected to RDL 41-4 and the electrical connections 41-5.

The method as shown in FIGS. 41A to 41E may be related to a chip-first/face-down type fan-out packaging process. In some embodiments of the present disclosure, such method may be applied to the embodiment shown in FIG. 27 and other related packaging structures.

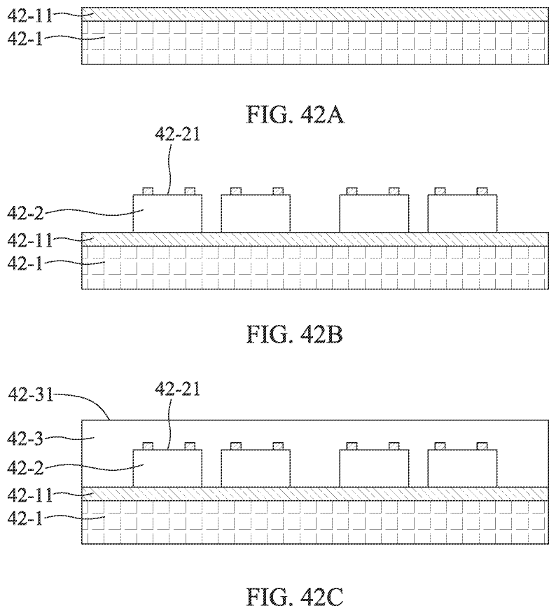

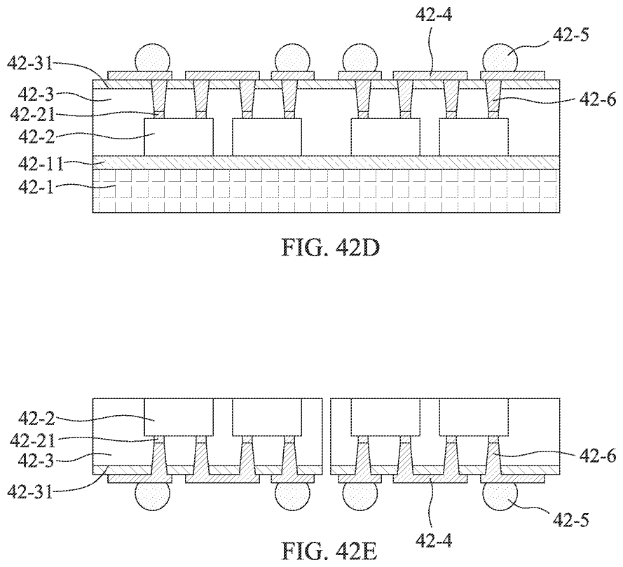

FIGS. 42A to 42E illustrate one or more stages of an example of a method for manufacturing a semiconductor device package in accordance with some embodiments of the present disclosure.

Referring to FIG. 42A, a temporary carrier 42-1 is provided. Further, a temporary layer 42-11 may be disposed on the upper surface of the carrier 42-1. In some embodiments of the present disclosure, the temporary layer 42-11 includes a release layer or a release/adhesive layer.

Referring to FIG. 42B, a plurality of electronic components 42-2 are provided. In some embodiments of the present disclosure, the electronic component 42-2 includes a known-good-die (KGD). The electronic components 42-2 may be disposed on the upper surface of the carrier 42-1. Further, the electronic component 42-2 may include an active surface 42-21 facing away from the upper surface of the carrier 41-1.

Referring to FIG. 42C, a package material 42-3 is provided. The package material 42-3 may be disposed on the upper surface of the carrier 42-1 and configured to encapsulate the electronic components 42-2. An upper surface 42-31 of the package material 42-3 may cover the active surfaces 42-21 of the electronic components 42-2. In some embodiments of the present disclosure, the package material 42-3 includes a molding compound or a thick photoresist.

Referring to FIG. 42D, a redistribution layer 42-4 (RDL 42-4) with electrical connections 42-5 is provided. RDL 42-4 with the electrical connections 42-5 may be disposed on the upper surface 42-31 of the package material 42-3. Moreover, a plurality TMVs (Through Mold Via) or copper pillars 42-6 may be arranged in the package material 42-3 and configured to electrically connect the active surfaces 42-21 of the electronic components 42-2 to RDL 42-4 with the electrical connections 42-5.

Referring to FIG. 42E, the carrier 42-1 with the temporary layer 42-11 are removed.

The method as shown in FIGS. 42A to 42E may be related to a chip-first/face-up type fan-out packaging process. In some embodiments of the present disclosure, such method may be applied to the embodiment shown in FIG. 4, the embodiment shown in FIG. 5, the embodiment shown in FIG. 8, the embodiment shown in FIG. 9, the embodiment shown in FIG. 10, the embodiment shown in FIG. 26 and other related packaging structures.

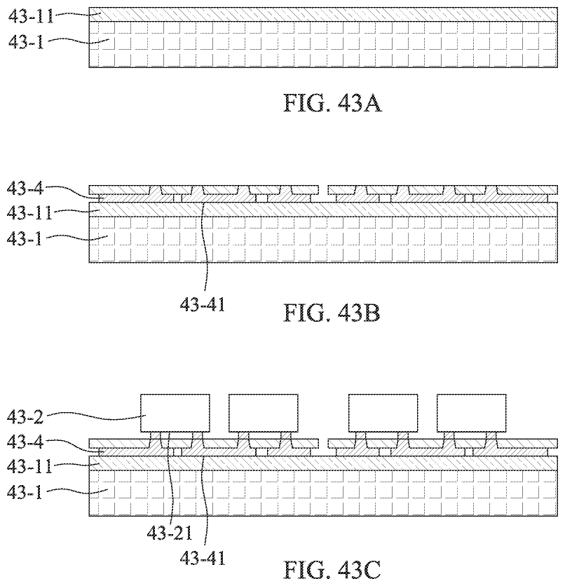

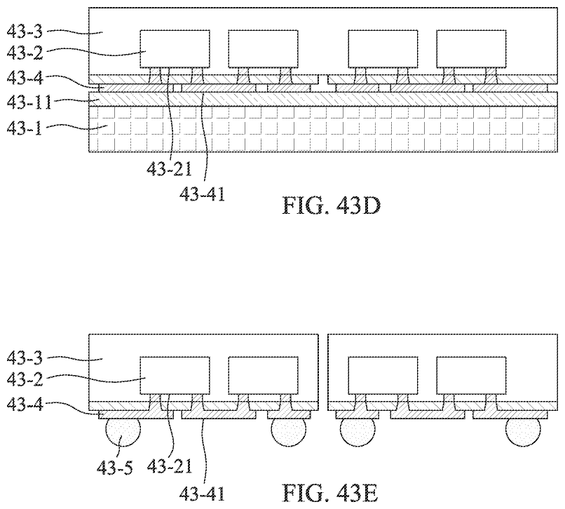

FIGS. 43A to 43E illustrate one or more stages of an example of a method for manufacturing a semiconductor device package in accordance with some embodiments of the present disclosure.

Referring to FIG. 43A, a temporary carrier 43-1 is provided. Further, a temporary layer 43-11 may be disposed on the upper surface of the carrier 43-1. In some embodiments of the present disclosure, the temporary layer 43-11 includes a release layer or a release/adhesive layer.

Referring to FIG. 43B, a redistribution layer 43-4 (RDL 43-4) is provided. The redistribution layer may be disposed on the upper surface of the carrier 43-1.

Referring to FIG. 43C, a plurality of electronic components 43-2 are provided. In some embodiments of the present disclosure, the electronic component 43-2 includes a known-good-die (KGD). The electronic components 43-2 may be disposed on the upper surface of the carrier 43-1. Further, the electronic component 43-2 may include an active surface 43-21 facing the upper surface of the carrier 43-1 and electrically connected to RDL 43-4.

Referring to FIG. 43D, a package material 43-3 is provided. The package material 43-3 may be disposed on the upper surface of the carrier 43-1 and configured to encapsulate the electronic components 43-2 and RDL 43-4. In some embodiments of the present disclosure, the package material 43-3 includes a molding compound or a thick photoresist.

Referring to FIG. 43E, the carrier 43-1 with the temporary layer 43-11 is removed, and a plurality of electrical connections 43-5 are disposed on a lower surface 43-41 of RDL 43-4 and electrically connected to RDL 43-4.

The method as shown in FIGS. 43A to 43E may be related to a chip-last/face-down type packaging process. In some embodiments of the present disclosure, such method may be applied to the embodiment shown in FIG. 6, the embodiment shown in FIG. 11, the embodiment shown in FIG. 17, the embodiment shown in FIG. 22, the embodiment shown in FIG. 24, the embodiment shown in FIG. 25, the embodiment shown in FIG. 32, the embodiment shown in FIG. 33 and other related packaging structures.

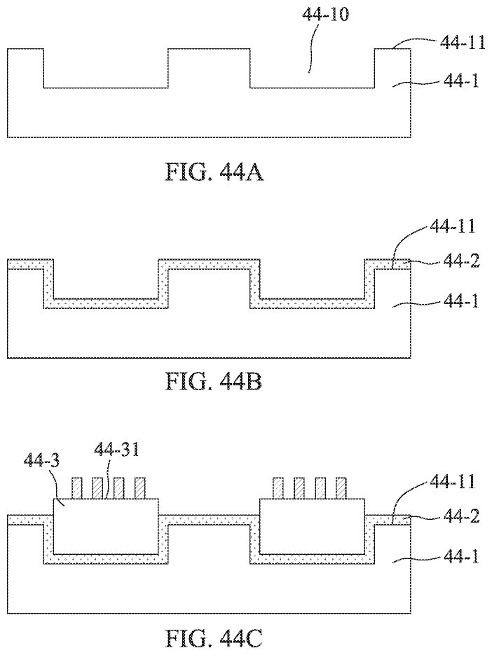

FIGS. 44A to 44C illustrate one or more stages of an example of a method for manufacturing a semiconductor device package in accordance with some embodiments of the present disclosure.

Referring to FIG. 44A, a carrier 44-1 is provided. In some embodiments of the present disclosure, the carrier 44-1 includes a glass carrier. The carrier 44-1 may include a plurality of recesses 44-10 formed on its upper surface 44-11.

Referring to FIG. 44B, a temporary layer 44-2 is provided with recesses 44-10 with dimensions slightly larger than the sizes of the dies to be processed through fan-out packaging. The temporary layer 44-2 may be disposed on the upper surface 44-11 and the recesses 44-10 of the carrier 44-1. In some embodiments of the present disclosure, the temporary layer 44-2 includes a release layer or a release/adhesive layer.

Referring to FIG. 44C, a plurality of electronic components 44-3 are provided. In some embodiments of the present disclosure, the electronic component 44-3 includes a known-good-die (KGD). The electronic components 44-3 may be disposed on the temporary layer 44-2. The electronic components 44-3 may be respectively placed in the recesses 44-10 of the carrier 44-1. In some embodiments of the present disclosure, the electronic component 44-3 may include an active surface 44-31 facing away from the carrier 44-3.

The carrier 44-1 with the recesses 44-10 may be applied to minimize die shifts using the chip-first/face-up type fan-out packaging process as an example (see FIGS. 42A to 42E) It can also find utilities in other types of fan-out processes.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device package, comprising:
a first electronic component;
a second electronic component above the first electronic component;
an interconnection structure disposed external to both the first electronic component and the second electronic component, wherein the interconnection structure is configured to electrically connect the first electronic component to the second electronic component;
a package material configured to hold the first electronic component and the second electronic component together; and
an external connector configured to electrically connect the first and second electronic components to an external device;
wherein the first electronic component has a portion free from being covered by the second electronic component;
wherein the external connector is positioned directly above the portion of the first electronic component.

2. The semiconductor device package of claim 1, wherein a size of the first electronic component is substantially identical to a size of the second electronic component, and wherein a spacer is disposed adjacent to the first electronic component and under the second electronic component.

3. The semiconductor device package of claim 1, wherein the interconnection structure comprises a solder connector.

4. The semiconductor device package of claim 3, further comprising a first support adjacent to a first side of the second electronic component and a second support adjacent to a second side of the second electronic component, the second side being opposite the first side.

5. The semiconductor device package of claim 4, further comprising a first encapsulant disposed between the first support and the first side of the second electronic component and a second encapsulant disposed between the second support and the second side of the second electronic, wherein the package structure includes an underfill material disposed between the first electronic component and the second electronic component and surrounding the solder connector.

6. The semiconductor device package of claim 5, wherein the interconnection structure comprises a redistribution layer, wherein the redistribution layer is disposed above of the first electronic component and faces the second electronic component, and wherein the external connector is in abutment with the redistribution layer.

7. The semiconductor device package of claim 1, wherein the external connector is disposed above the package material, and wherein the interconnection structure comprises a first conductive via passing through the package material and disposed directly above the portion of the first electronic component.

8. The semiconductor device package of claim 7, wherein the package material comprises a first molding compound surrounding the first electronic component and a second molding compound surrounding the second electronic component, and wherein a first redistribution layer is disposed between the first molding compound and the second molding compound and a second redistribution layer is disposed above the second molding compound, and wherein the first conductive via is configured to electrically connect the first redistribution layer to the second redistribution layer.

9. The semiconductor device package of claim 7, wherein the package material comprises a molding compound surrounding the first electronic component, the second electronic component and the first conductive via, and wherein the interconnection structure comprises a redistribution layer is disposed above the molding compound and below the external connector, and wherein the first conductive via is configured to electrically connect the first electronic component to the redistribution layer.

10. The semiconductor device package of claim 1, wherein the external connector is disposed above the package material, and wherein the interconnection structure comprises an interconnect spacer, and wherein the interconnect spacer is surrounded by the package material and disposed directly above the portion of the first electronic component.

11. A semiconductor device package, comprising:
a first electronic component;
a second electronic component disposed above the first electronic component,
an interconnection structure configured to electrically connect the first electronic component to the second electronic component;
a package material configured to encapsulate the first electronic component, the second electronic component and the interconnection structure;
wherein the interconnection structure is arranged outside the first electronic component and the second electronic component and surrounded by the package material.

12. The semiconductor device package of claim 11, wherein the interconnection structure comprises a first redistribution layer between the first electronic component and the second electronic component and a first conductive element connected to the first redistribution layer, and wherein the first electronic component and the second electronic component are electrically connected to each other through the first redistribution layer and the first conductive element.

13. The semiconductor device package of claim 12, wherein the first conductive element comprises a first through mold via.

14. The semiconductor device of package of claim 12, wherein the first conductive element comprises a silicon material and a through conductive via passing through the silicon material.

15. The semiconductor device package of claim 13, wherein the first electronic component or the second electronic component is connected to the first redistribution layer through a second through mold via.

16. The semiconductor device package of claim 11, further comprising a third electronic component disposed above the second electronic component and electrically connected to the first and second electronic components through the interconnection structure and encapsulated by the package material.

17. A method of manufacturing a semiconductor device package comprising:
providing a first redistribution layer on a first carrier, wherein the first redistribution layer has been under test;
providing an interconnection on the first redistribution layer;
providing a first electronic component on the first redistribution layer, wherein the first electronic component has been under test;
providing a first package material to encapsulate the first redistribution layer, the interconnection and the first electronic component, so as to form a sub-assembly;
providing a second redistribution layer on the sub-assembly, wherein the second redistribution layer has been test;
providing a second electronic component on the second redistribution layer, wherein the second electronic component comprises a portion overlapping the interconnection in a vertical direction;
providing a second package material to encapsulate the second redistribution layer and the second electronic component; and
removing the first carrier from the first redistribution layer.

18. The method of claim 17, further comprising:
testing the first electronic component before providing the first electronic component on the first redistribution layer; and
testing the second electronic component before providing the second electronic component on the second redistribution layer.

19. The method of claim 17, further comprising: testing the sub-assembly before providing the second redistribution layer on the sub-assembly.

20. The method of claim 17, further comprising: removing a second carrier from the second redistribution layer before providing the second redistribution layer on the sub-assembly, wherein the second redistribution layer is tested on the second carrier.
